(19) United States
(12) Patent Application Publication
(10) Pub. No.: US 2023/0143281 A1
(43) Pub. Date: May 11, 2023

(54) COMPOSITION FOR LIGHT-EMITTING DEVICE, LIGHT-EMITTING DEVICE, LIGHT-EMITTING APPARATUS, ELECTRONIC DEVICE, AND LIGHTING DEVICE

(71) Applicant: SEMICONDUCTOR ENERGY LABORATORY CO., LTD., Atsugi-shi, Kanagawa-ken (JP)

(72) Inventors: Yui YOSHIYASU, Atsugi, Kanagawa (JP); Akira NAGASAKA, Atsugi, Kanagawa (JP); Hideko YOSHIZUMI, Atsugi, Kanagawa (JP); Toshiki SASAKI, Isehara, Kanagawa (JP); Satoshi SEO, Sagamihara, Kanagawa (JP)

(21) Appl. No.: 17/910,103

(22) PCT Filed: Mar. 15, 2021
(86) PCT No.: PCT/IB2021/052111

§ 371 Date: Sep. 8, 2022

(30) Foreign Application Priority Data
Mar. 27, 2020 (JP) 2020-057122

(51) Int. Cl. H10K 85/60; H10K 50/11

(52) U.S. Cl. CPC H01L 51/0074; H01L 51/0071; H01L 51/0073; H01L 51/0072; H01L 51/0054; H01L 51/5012

(57) ABSTRACT

A composition for a light-emitting device is provided. The composition is formed by mixing a first organic compound having a benzofuropyrimidine skeleton, and a second organic compound represented by General Formula (Q1):

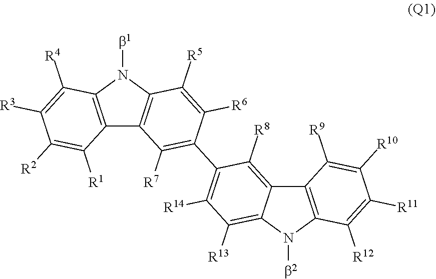

R1 to R14 each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group, and at least one of β¹ and β² is an unsubstituted β-naphthyl group.

### TECHNICAL FIELD

One embodiment of the present invention relates to a composition for a light-emitting device, a light-emitting device, a light-emitting apparatus, an electronic device, and a lighting device. However, embodiments of the present invention are not limited thereto. That is, one embodiment of the present invention relates to an object, a method, a manufacturing method, or a driving method. Alternatively, one embodiment of the present invention relates to a process, a machine, manufacture, or a composition of matter.

### BACKGROUND ART

A light-emitting device including an EL layer between a pair of electrodes (also referred to as an organic EL device) has characteristics such as thinness, light weight, high-speed response to input signals, and low power consumption; thus, the development of displays including such a light-emitting device has been widely promoted.

In a light-emitting device, voltage application between a pair of electrodes causes, in an EL layer, recombination of electrons and holes injected from the electrodes, which brings a light-emitting substance (an organic compound) contained in the EL layer into an excited state. Light is emitted when the light-emitting substance returns to the ground state from the excited state. The excited state can be a singlet excited state (S*) and a triplet excited state (T*). Light emission from a singlet excited state is referred to as fluorescence, and light emission from a triplet excited state is referred to as phosphorescence. The statistical generation ratio thereof in the light-emitting device is considered to be S*:T*=1:3. Since the emission spectrum obtained from a light-emitting substance depends on the light-emitting substance, the use of different types of organic compounds as light-emitting substances offers light-emitting devices exhibiting various emission colors.

In order to improve device characteristics and reliability of such a light-emitting device, improvement of a device structure, development of a material, and the like have been actively carried out (see Patent Document 1, for example).

In addition, from the perspective of mass production, it is desired to improve the productivity of light-emitting devices in order to reduce cost in the manufacturing line.

### REFERENCE

### [Patent Document]

[Patent Document 1] Japanese Published Patent Application No. 2010-182699

### SUMMARY OF THE INVENTION

### Problems to be Solved by the Invention

A material used for an EL layer of a light-emitting device is extremely important for improvement of device characteristics and reliability of the light-emitting device. The EL layer is formed by stacking a plurality of functional layers in many cases, and each functional layer includes a plurality of compounds in some cases. For example, a host material and a guest material are often used in combination in a light-emitting layer, and sometimes used in combination with another material.

When a lot of layers are stacked or a plurality of materials need to be used in a layer as described above, a reduction in productivity is concerned due to an increase in the number of steps and need for an apparatus that can be used in such a case. However, in order to maintain excellent device characteristics of a light-emitting device to be manufactured, for example, the process cannot be easily simplified. For example, in the case where a light-emitting layer is formed by an evaporation method using a plurality of materials, a light-emitting device with excellent element characteristics cannot be easily obtained when the plurality of materials are put in one evaporation source to be evaporated for simplification of the process.

Note that the description of these objects does not preclude the existence of other objects. One embodiment of the present invention does not have to achieve all these objects. Other objects are apparent from the description of the specification, the drawings, the claims, and the like, and other objects can be derived from the description of the specification, the drawings, the claims, and the like.

### Means for Solving the Problems

In view of the above, one embodiment of the present invention provides a composition for a light-emitting device, which enables manufacture of a highly productive light-emitting device while device characteristics and reliability of the light-emitting device are maintained.

One embodiment of the present invention is a composition for a light-emitting device formed by mixing a plurality of organic compounds. Note that the composition for a light-emitting device can be used as a material for forming an EL layer of a light-emitting device. It is particularly preferable to use the composition for a light-emitting device as a material for forming an EL layer by an evaporation method. The composition for a light-emitting device is preferably used as a material for forming a light-emitting layer included in an EL layer of a light-emitting device by an evaporation method. Note that in the case where a light-emitting layer is formed by an evaporation method, the light-emitting layer can be formed by co-evaporation of a guest material and the composition for a light-emitting device including at least one kind of host material and another material which are mixed in advance (premixed).

One embodiment of the present invention is a composition for a light-emitting device formed by mixing a first organic compound having a benzofuropyrimidine skeleton, and a second organic compound having a bicarbazole skeleton represented by General Formula (Q1).

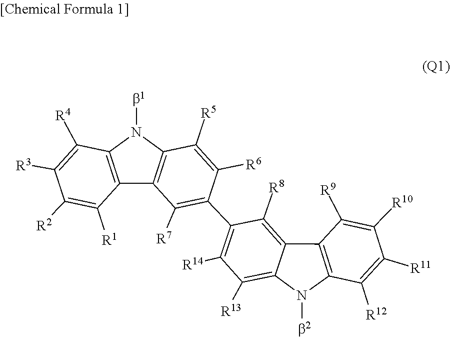

In General Formula (Q1) above, R¹ to R¹⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

Another embodiment of the present invention is a composition for a light-emitting device formed by mixing a first organic compound having a benzofuropyrimidine skeleton, and a second organic compound having a bicarbazole skeleton represented by General Formula (Q2).

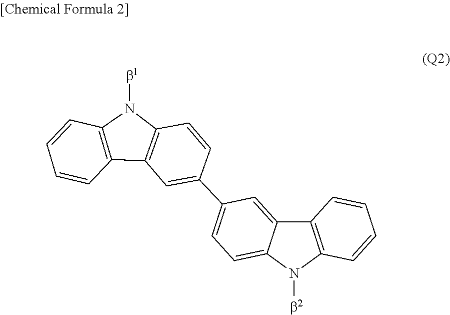

In General Formula (Q2) above, β¹ and β² each represent any of an unsubstituted 3-naphthyl group, an unsubstituted biphenyl group, and an unsubstituted terphenyl group. At least one of β¹ and β² is an unsubstituted β-naphthyl group.

Another embodiment of the present invention is a composition for a light-emitting device formed by mixing a first organic compound having a benzofuropyrimidine skeleton represented by General Formula (G1), and a second organic compound having a bicarbazole skeleton represented by General Formula (Q1).

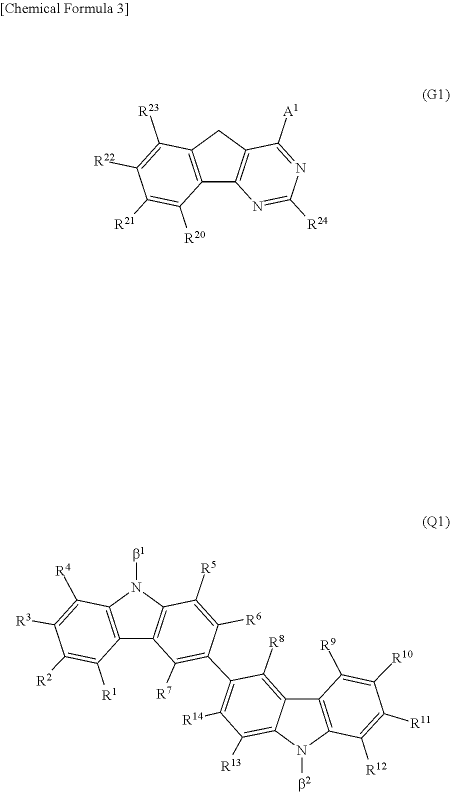

In General Formula (G1) or General Formula (Q1) above, A¹ represents an aryl group having 6 to 100 carbon atoms. Note that A¹ may include a heteroaromatic ring. R¹ to R¹⁴ and R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

Another embodiment of the present invention is a composition for a light-emitting device formed by mixing a first organic compound having a benzofuropyrimidine skeleton represented by General Formula (G1), and a second organic compound having a bicarbazole skeleton represented by General Formula (Q2).

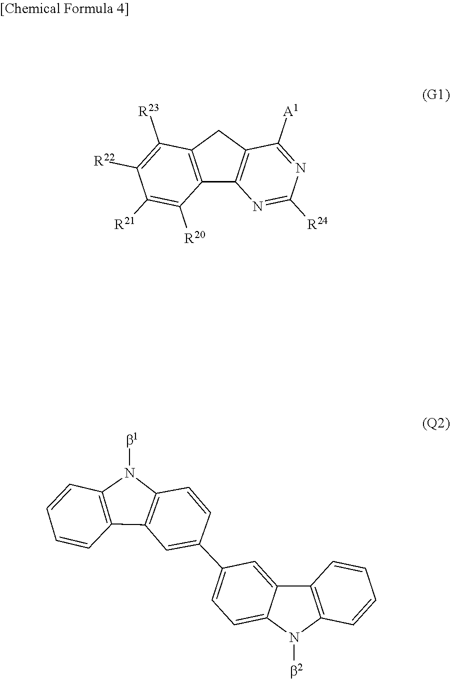

In General Formula (G1) or General Formula (Q2) above, A¹ represents an aryl group having 6 to 100 carbon atoms. Note that A¹ may include a heteroaromatic ring. R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

Another embodiment of the present invention is a composition for a light-emitting device formed by mixing a first organic compound having a benzofuropyrimidine skeleton represented by General Formula (G2), and a second organic compound having a bicarbazole skeleton represented by General Formula (Q1).

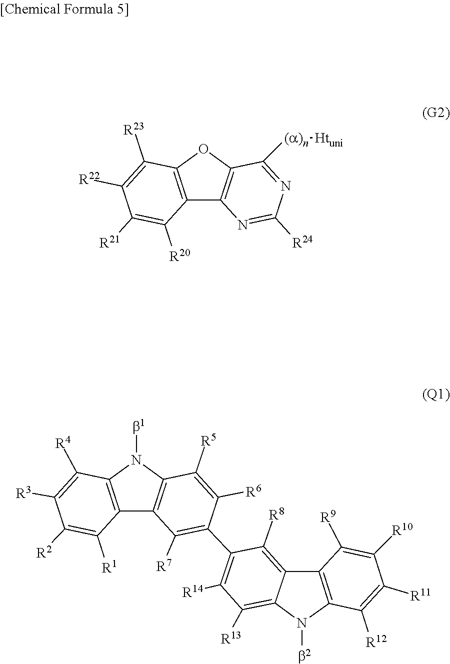

In General Formula (G2) or General Formula (Q1) above, α represents a substituted or unsubstituted phenylene group, and n is an integer of 0 to 4. Htᵤₙᵢ represents any one of a substituted or unsubstituted dibenzothiophenyl group, a substituted or unsubstituted dibenzofuranyl group, and a substituted or unsubstituted carbazolyl group. R¹ to R¹⁴ and R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

Another embodiment of the present invention is a composition for a light-emitting device formed by mixing a first organic compound having a benzofuropyrimidine skeleton represented by General Formula (G2), and a second organic compound having a bicarbazole skeleton represented by General Formula (Q2).

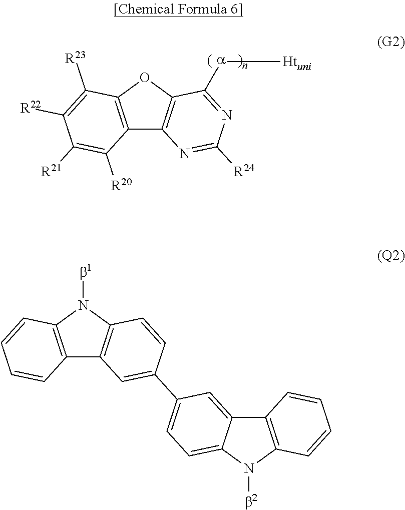

In General Formula (G2) or General Formula (Q2) above, α represents a substituted or unsubstituted phenylene group, and n is an integer of 0 to 4. Htᵤₙᵢ represents any one of a substituted or unsubstituted dibenzothiophenyl group, a substituted or unsubstituted dibenzofuranyl group, and a substituted or unsubstituted carbazolyl group. R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

Another embodiment of the present invention is a composition for a light-emitting device formed by mixing a first organic compound having a benzofuropyrimidine skeleton represented by General Formula (G3), and a second organic compound having a bicarbazole skeleton represented by General Formula (Q1).

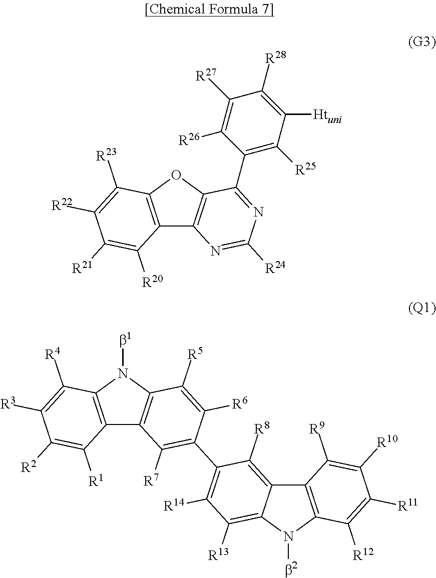

In General Formula (G3) or General Formula (Q1) above, Htᵤₙᵢ represents any one of a substituted or unsubstituted dibenzothiophenyl group, a substituted or unsubstituted dibenzofuranyl group, and a substituted or unsubstituted carbazolyl group. R¹ to R¹⁴ and R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

Another embodiment of the present invention is a composition for alight-emitting device formed by mixing a first organic compound having a benzofuropyrimidine skeleton represented by General Formula (G3), and a second organic compound having a bicarbazole skeleton represented by General Formula (Q2).

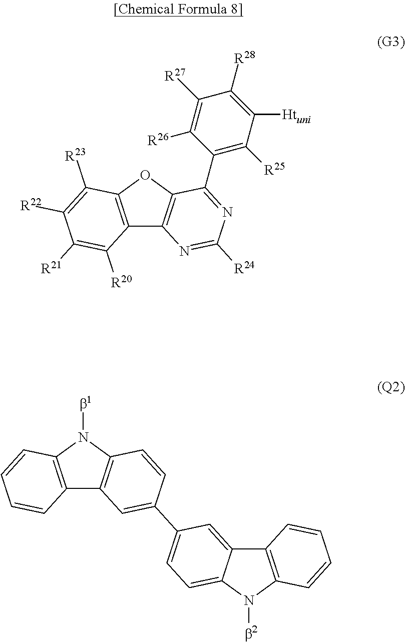

In General Formula (G3) or General Formula (Q2) above, Htᵤₙᵢ represents any one of a substituted or unsubstituted dibenzothiophenyl group, a substituted or unsubstituted dibenzofuranyl group, and a substituted or unsubstituted carbazolyl group. R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

In the composition for a light-emitting device with any of the above structures, only one of β¹ and β² in General Formula (Q1) or General Formula (Q2) is preferably an unsubstituted (3-naphthyl group.

In the composition for a light-emitting device with any of the above structures, Htᵤₙᵢ in General Formula (G2) or General Formula (G3) is preferably any one of General Formulae (Ht-1) to (Ht-6).

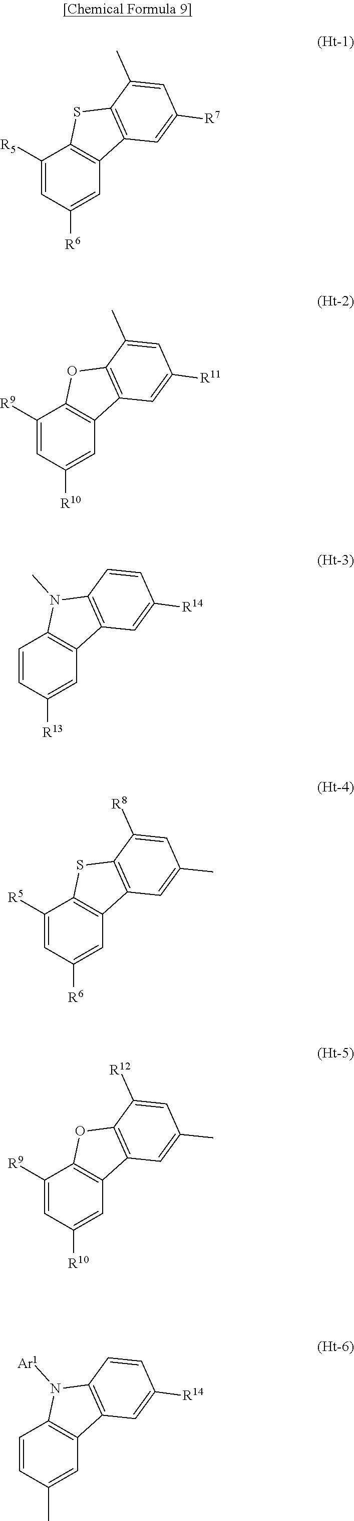

In General Formulae (Ht-1) to (Ht-6) above, R⁵ to R¹⁴ each independently represent any one of hydrogen, an alkyl group having 1 to 6 carbon atoms, and a substituted or unsubstituted phenyl group. Furthermore, Ar¹ represents any of an alkyl group having 1 to 6 carbon atoms and a substituted or unsubstituted phenyl group.

In the composition for a light-emitting device with any of the above structures, a combination of the first organic compound and the second organic compound can preferably form an exciplex.

In the composition for a light-emitting device with any of the above structures, the first organic compound is preferably mixed in a larger proportion than the second organic compound.

In the composition for a light-emitting device with any of the above structures, the molecular weight of the first organic compound is preferably smaller than that of the second organic compound, and the difference in molecular weight is preferably less than or equal to 200.

Another embodiment of the present invention is a light-emitting device including an EL layer between a pair of electrodes. The EL layer includes a first organic compound having a benzofuropyrimidine skeleton, a second organic compound represented by General Formula (Q1), and a light-emitting substance. In the case where a phosphorescent substance is used as the light-emitting substance in the EL layer, a light-emitting substance having a T1 level of 2.5 eV or less is preferably used in terms of excitation energy transfer, in which case the efficiency of energy transfer from a host material in an excited state to a guest material can be improved and a synergistic effect of increasing the reliability of an element is expected.

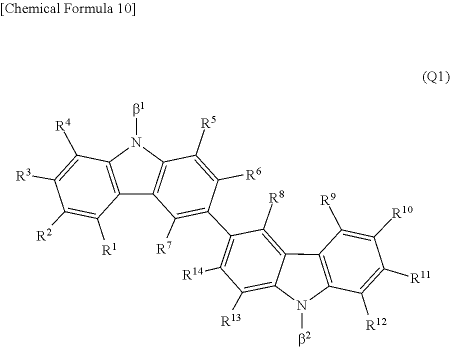

In General Formula (Q1) above, R¹ to R¹⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

Another embodiment of the present invention is a light-emitting device including an EL layer between a pair of electrodes. The EL layer includes a first organic compound represented by General Formula (G1), a second organic compound represented by General Formula (Q1), and a light-emitting substance. In the case where a phosphorescent substance is used as the light-emitting substance in the EL layer, a light-emitting substance having a T1 level of 2.5 eV or less is preferably used in terms of excitation energy transfer, in which case the efficiency of energy transfer from a host material in an excited state to a guest material can be improved and a synergistic effect of increasing the reliability of an element is expected.

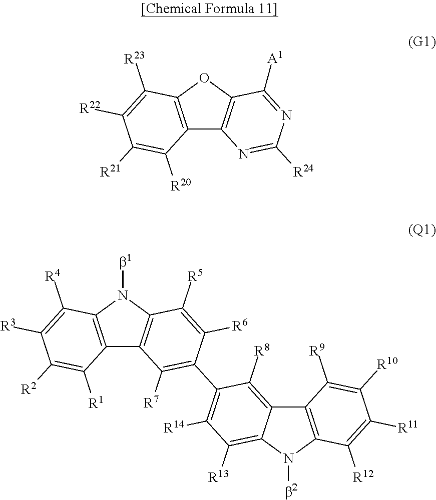

In General Formula (G1) or General Formula (Q1) above, A¹ represents an aryl group having 6 to 100 carbon atoms. Note that A¹ may include a heteroaromatic ring. R¹ to R¹⁴ and R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

In the light-emitting device with any of the above structures, the first organic compound, the second organic compound, and the light-emitting substance are preferably included in a light-emitting layer in the EL layer. In the case where a phosphorescent substance is used as the light-emitting substance in the EL layer, a light-emitting substance having a T1 level of 2.5 eV or less is preferably used in terms of excitation energy transfer, in which case the efficiency of energy transfer from a host material in an excited state to a guest material can be improved and a synergistic effect of increasing the reliability of an element is expected.

In the light-emitting device with any of the above structures, only one of β¹ and β² in General Formula (Q1) is preferably an unsubstituted β-naphthyl group.

One embodiment of the present invention includes, in its category, in addition to the composition for a light-emitting device, a light-emitting device (also referred to as a light-emitting element) manufactured using the composition for a light-emitting device, a light-emitting apparatus including the light-emitting device, an electronic device including the light-emitting apparatus (specifically, an electronic device including a light-emitting device or a light-emitting apparatus, and a connection terminal or an operation key), and a lighting device (specifically, a lighting device including a light-emitting device or a light-emitting apparatus, and a housing). Accordingly, a light-emitting apparatus in this specification refers to an image display device or a light source (including a lighting device). In addition, a light-emitting apparatus includes a module in which a light-emitting apparatus is attached to a connector such as an FPC (Flexible Printed Circuit) or a TCP (Tape Carrier Package), a module in which a printed wiring board is provided on the tip of a TCP, or a module in which an IC (integrated circuit) is directly mounted on a light-emitting device by a COG (Chip On Glass) method.

### Effect of the Invention

One embodiment of the present invention can provide a composition for a light-emitting device, which enables manufacture of a highly productive light-emitting device while device characteristics and reliability of the light-emitting device are maintained.

Note that the description of these effects does not preclude the existence of other effects. Note that one embodiment of the present invention does not need to have all these effects. Note that effects other than these will be apparent from the description of the specification, the drawings, the claims, and the like and effects other than these can be derived from the description of the specification, the drawings, the claims, and the like. In addition, a novel light-emitting device whose reliability can be improved can be provided.

### BRIEF DESCRIPTION OF THE DRAWINGS

FIG. 1A is a diagram showing a structure of a light-emitting device. FIG. 1B is a diagram showing a structure of a light-emitting device.

FIG. 2A and FIG. 2B are diagrams each showing an evaporation method.

FIG. 3A, FIG. 3B, and FIG. 3C are diagrams each showing a light-emitting apparatus.

FIG. 4A and FIG. 4B are diagrams showing a light-emitting apparatus.

FIG. 5A is a diagram showing a mobile computer. FIG. 5B is a diagram showing a portable image reproducing device. FIG. 5C is a diagram showing a digital camera. FIG. 5D is a diagram showing a portable information terminal. FIG. 5E is a diagram showing a portable information terminal. FIG. 5F is a diagram showing a television device. FIG. 5G is a diagram showing a portable information terminal.

FIG. 6A, FIG. 6B, and FIG. 6C are diagrams showing an electronic device.

FIG. 7A and FIG. 7B are diagrams showing an automobile.

FIG. 8A and FIG. 8B are diagrams each showing a lighting device.

FIG. 9 is a diagram showing a light-emitting device.

FIG. 10 is a graph showing the voltage-current characteristics of a light-emitting device 1 and a comparative light-emitting device 2.

FIG. 11 is a graph showing the luminance-external quantum efficiency characteristics of the light-emitting device 1 and the comparative light-emitting device 2.

FIG. 12 is a graph showing the emission spectra of the light-emitting device 1 and the comparative light-emitting device 2.

FIG. 13 is a graph showing the reliability of the light-emitting device 1 and the comparative light-emitting device 2.

FIG. 14 is a graph showing the voltage-current characteristics of a light-emitting device 3, a light-emitting device 4, and a comparative light-emitting device 5.

FIG. 15 is a graph showing the luminance-external quantum efficiency characteristics of the light-emitting device 3, the light-emitting device 4, and the comparative light-emitting device 5.

FIG. 16 is a graph showing the emission spectra of the light-emitting device 3, the light-emitting device 4, and the comparative light-emitting device 5.

FIG. 17 is a graph showing the reliability of the light-emitting device 3, the light-emitting device 4, and the comparative light-emitting device 5.

FIG. 18 is a graph showing the voltage-current characteristics of a light-emitting device 6 and a comparative light-emitting device 7.

FIG. 19 is a graph showing the luminance-external quantum efficiency characteristics of the light-emitting device 6 and the comparative light-emitting device 7.

FIG. 20 is a graph showing the emission spectra of the light-emitting device 6 and the comparative light-emitting device 7.

FIG. 21 is a graph showing the reliability of the light-emitting device 6 and the comparative light-emitting device 7.

FIG. 22 is a graph showing the voltage-current characteristics of the light-emitting device 1.

FIG. 23 is a graph showing the luminance-external quantum efficiency characteristics of the light-emitting device 1.

FIG. 24 is a graph showing the emission spectrum of the light-emitting device 1.

FIG. 25 is a graph showing the voltage-current characteristics of the light-emitting device 3.

FIG. 26 is a graph showing the luminance-external quantum efficiency characteristics of the light-emitting device 3.

FIG. 27 is a graph showing the emission spectrum of the light-emitting device 3.

FIG. 28 is a graph showing the voltage-current characteristics of a light-emitting device 6′.

FIG. 29 is a graph showing the luminance-external quantum efficiency characteristics of the light-emitting device 6′.

FIG. 30 is a graph showing the emission spectrum of the light-emitting device 6′.

FIG. 31 is a graph showing the reliability of the light-emitting device 1.

FIG. 32 is a graph showing the reliability of the light-emitting device 3.

FIG. 33 is a graph showing the reliability of the light-emitting device 6′.

### MODE FOR CARRYING OUT THE INVENTION

Hereinafter, a composition for a light-emitting device of one embodiment of the present invention is described in detail. Note that the present invention is not limited to the following description, and the modes and details of the present invention can be modified in various ways without departing from the spirit and scope of the present invention. Thus, the present invention should not be construed as being limited to the description in the following embodiments.

Note that the position, size, range, or the like of each component shown in drawings and the like is not accurately represented in some cases for easy understanding. Therefore, the disclosed invention is not necessarily limited to the position, size, range, or the like disclosed in drawings and the like.

Furthermore, in describing structures of the invention with reference to the drawings in this specification and the like, the same components in different drawings are commonly denoted by the same reference numeral.

### Embodiment 1

In this embodiment, a material for a light-emitting device of one embodiment of the present invention is described. Note that a composition for a light-emitting device of one embodiment of the present invention can be used as a material for forming an EL layer of a light-emitting device. In particular, the composition for a light-emitting device can be used as a material for forming an EL layer by an evaporation method. Thus, described is a structure of a composition for a light-emitting device used as a plurality of materials (including a host material) other than a guest material when a light-emitting layer included in an EL layer of a light-emitting device is formed by an evaporation method.

When a light-emitting layer of an EL layer is formed by a co-evaporation method, a composition for a light-emitting device that can be used together with a guest material is a mixture combining organic compounds shown below, preferably a mixture of a first organic compound having a benzofuropyrimidine skeleton and a second organic compound having a bicarbazole skeleton represented by General Formula (Q1).

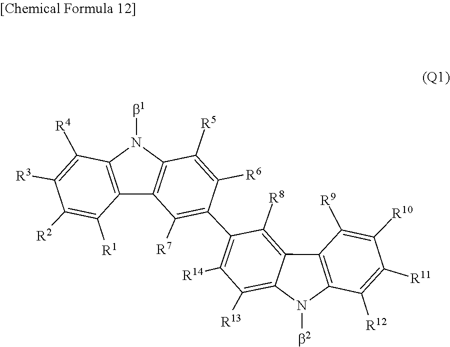

In General Formula (Q1) above, R¹ to R¹⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

A composition for a light-emitting device with a structure other than the above can be formed by mixing a first organic compound having a benzofuropyrimidine skeleton, and a second organic compound having a bicarbazole skeleton represented by General Formula (Q2).

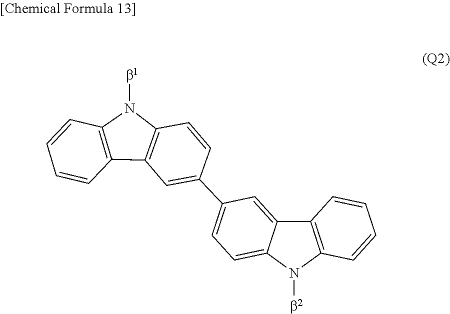

In General Formula (Q2) above, β¹ and β² each represent any of an unsubstituted 3-naphthyl group, an unsubstituted biphenyl group, and an unsubstituted terphenyl group. At least one of β¹ and β² is an unsubstituted β-naphthyl group.

A composition for a light-emitting device with a structure other than the above can be formed by mixing a first organic compound having a benzofuropyrimidine skeleton represented by General Formula (G1), and a second organic compound having a bicarbazole skeleton represented by General Formula (Q1).

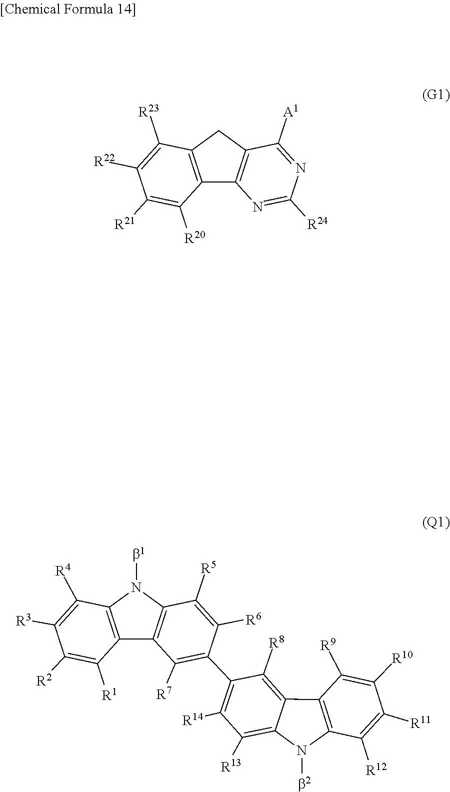

In General Formula (G1) or General Formula (Q1) above, A¹ represents an aryl group having 6 to 100 carbon atoms. Note that A¹ may include a heteroaromatic ring. R¹ to R¹⁴ and R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

A composition for a light-emitting device with a structure other than the above can be formed by mixing a first organic compound having a benzofuropyrimidine skeleton represented by General Formula (G1), and a second organic compound having a bicarbazole skeleton represented by General Formula (Q2).

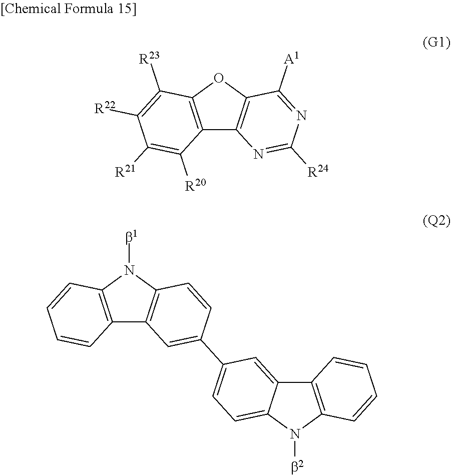

In General Formula (G1) or General Formula (Q2) above, A¹ represents an aryl group having 6 to 100 carbon atoms. Note that A¹ may include a heteroaromatic ring. R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

A composition for a light-emitting device with a structure other than the above can be formed by mixing a first organic compound having a benzofuropyrimidine skeleton represented by General Formula (G2), and a second organic compound having a bicarbazole skeleton represented by General Formula (Q1).

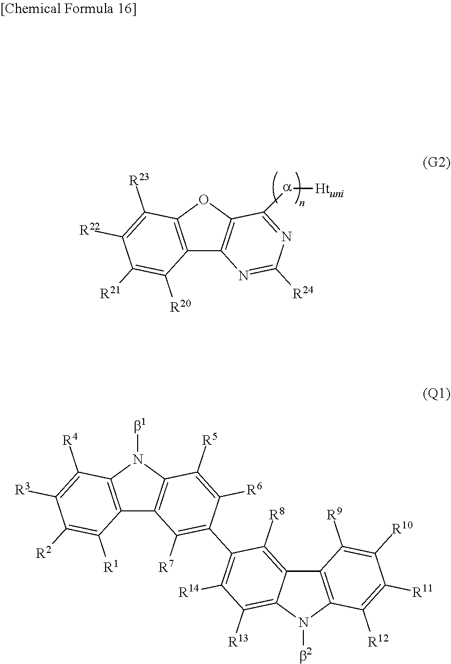

In General Formula (G2) or General Formula (Q1) above, α represents a substituted or unsubstituted phenylene group, and n is an integer of 0 to 4. Htᵤₙᵢ represents any one of a substituted or unsubstituted dibenzothiophenyl group, a substituted or unsubstituted dibenzofuranyl group, and a substituted or unsubstituted carbazolyl group. R¹ to R¹⁴ and R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

A composition for a light-emitting device with a structure other than the above can be formed by mixing a first organic compound having a benzofuropyrimidine skeleton represented by General Formula (G2), and a second organic compound having a bicarbazole skeleton represented by General Formula (Q2).

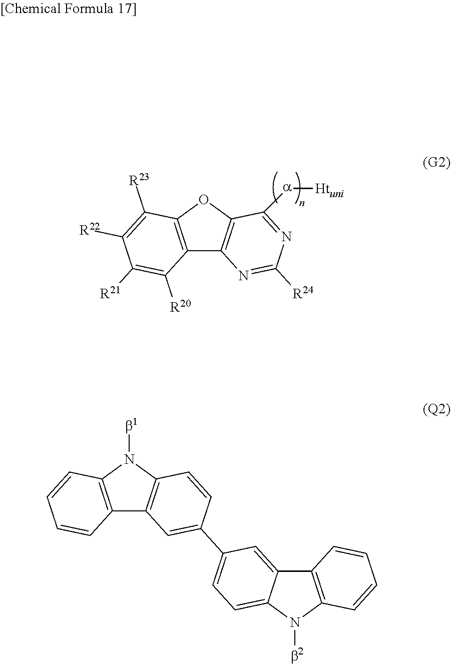

In General Formula (G2) or General Formula (Q2) above, α represents a substituted or unsubstituted phenylene group, and n is an integer of 0 to 4. Htᵤₙᵢ represents any one of a substituted or unsubstituted dibenzothiophenyl group, a substituted or unsubstituted dibenzofuranyl group, and a substituted or unsubstituted carbazolyl group. R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

A composition for a light-emitting device with a structure other than the above can be formed by mixing a first organic compound having a benzofuropyrimidine skeleton represented by General Formula (G3), and a second organic compound having a bicarbazole skeleton represented by General Formula (Q1).

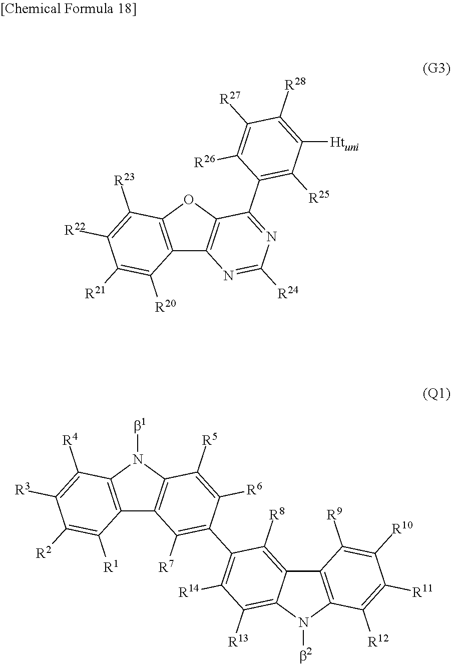

In General Formula (G3) or General Formula (Q1) above, Htᵤₙᵢ represents any one of a substituted or unsubstituted dibenzothiophenyl group, a substituted or unsubstituted dibenzofuranyl group, and a substituted or unsubstituted carbazolyl group. R¹ to R¹⁴ and R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, β¹ and β² each represent any of an unsubstituted β-naphthyl group, an unsubstituted biphenyl group, and an unsubstituted terphenyl group. At least one of β¹ and β² is an unsubstituted β-naphthyl group.

A composition for a light-emitting device with a structure other than the above can be formed by mixing a first organic compound having a benzofuropyrimidine skeleton represented by General Formula (G3), and a second organic compound having a bicarbazole skeleton represented by General Formula (Q2).

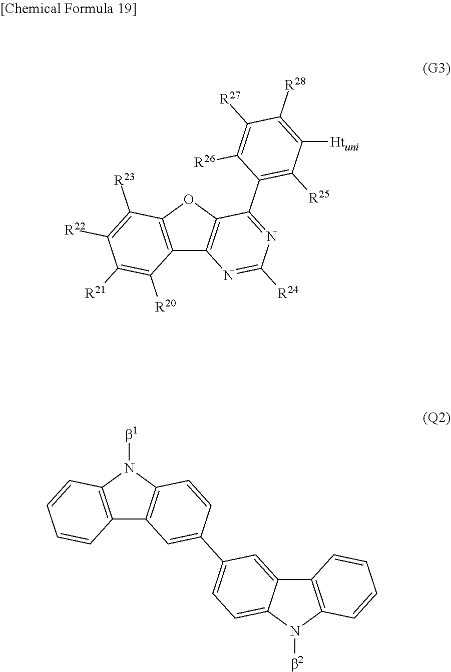

In General Formula (G3) or General Formula (Q2) above, Htᵤₙᵢ represents any one of a substituted or unsubstituted dibenzothiophenyl group, a substituted or unsubstituted dibenzofuranyl group, and a substituted or unsubstituted carbazolyl group. R²⁰ to R²⁴ each independently represent hydrogen (including deuterium), an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring. Furthermore, R³ and β² each represent any of an unsubstituted β-naphthyl group, an unsubstituted biphenyl group, and an unsubstituted terphenyl group. At least one of β¹ and β² is an unsubstituted β-naphthyl group.

In the composition for a light-emitting device shown above, only one of β³ and β² in General Formula (Q1) or General Formula (Q2) is preferably an unsubstituted β-naphthyl group. Only one unsubstituted β-naphthyl group probably contributes to stabilization of an excited state while maintains or slightly improves the hole-transport property of the light-emitting layer. In the case where the composition for a light-emitting device has such a structure in which β¹ and β² in General Formula (Q1) or General Formula (Q2) have different structures, the reliability of a light-emitting device using this composition for a light-emitting device can be improved.

In the composition for a light-emitting device shown above, Htᵤₙᵢ in General Formula (G2) or General Formula (G3) is preferably any one of General Formulae (Ht-1) to (Ht-6).

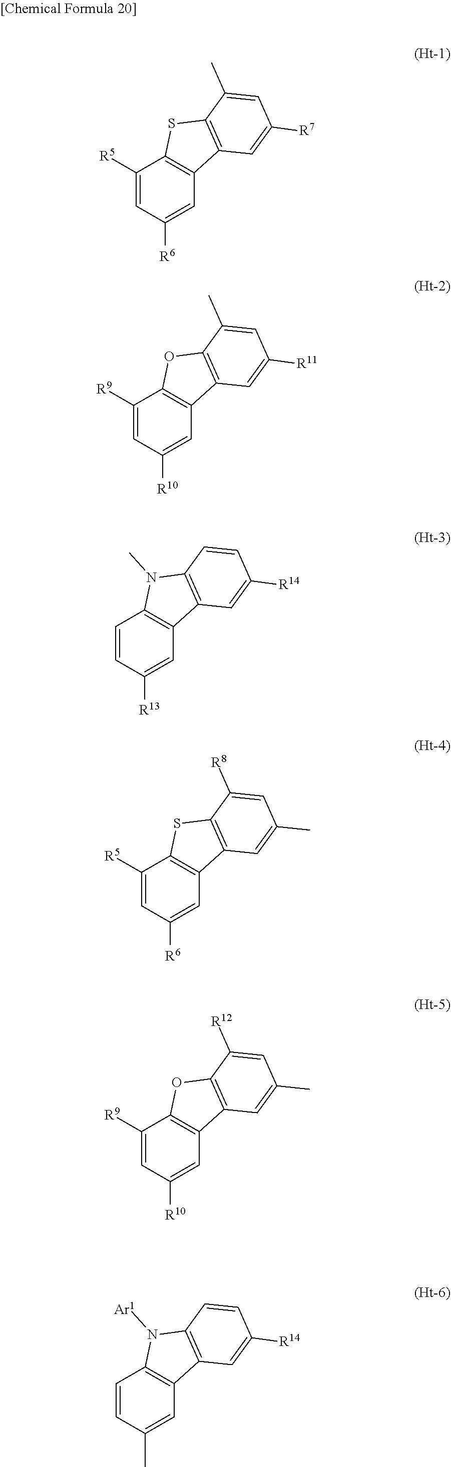

In General Formulae (Ht-1) to (Ht-6) above, R⁵ to R¹⁴ each independently represent any one of hydrogen, an alkyl group having 1 to 6 carbon atoms, and a substituted or unsubstituted phenyl group. Furthermore, Ar¹ represents any of an alkyl group having 1 to 6 carbon atoms and a substituted or unsubstituted phenyl group.

Next, specific examples of the first organic compound, which is included in the composition for a light-emitting device of one embodiment of the present invention and represented by any one of General Formula (G1), General Formula (G2), and General Formula (G3) above, are shown in Structural Formula (100) to Structural Formula (137) below.

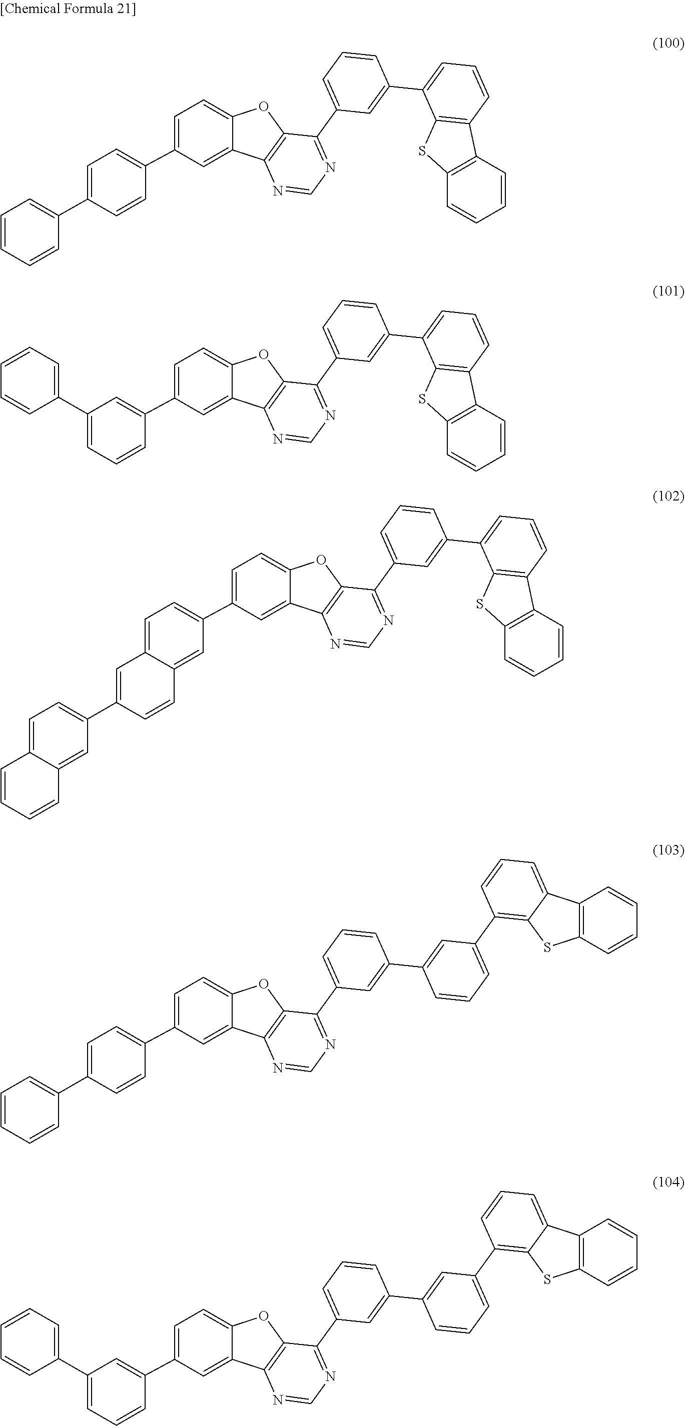

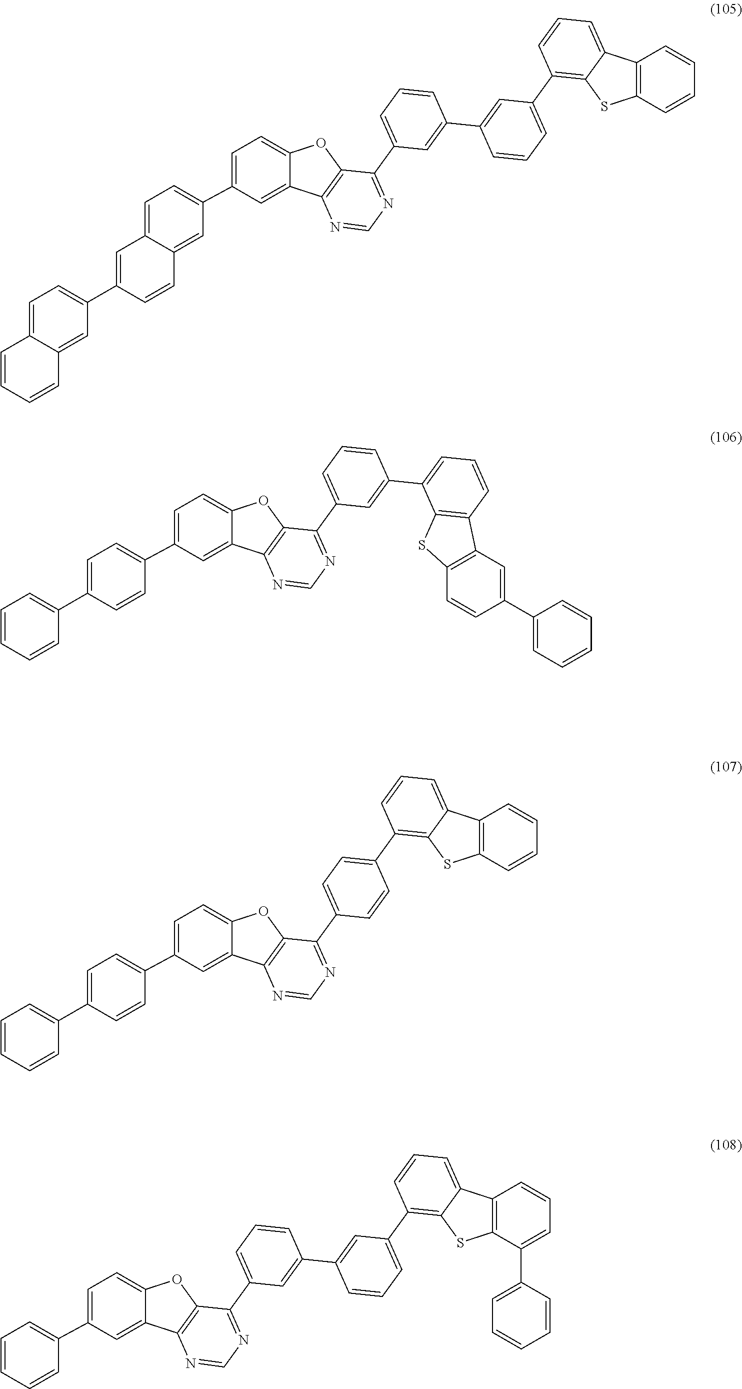

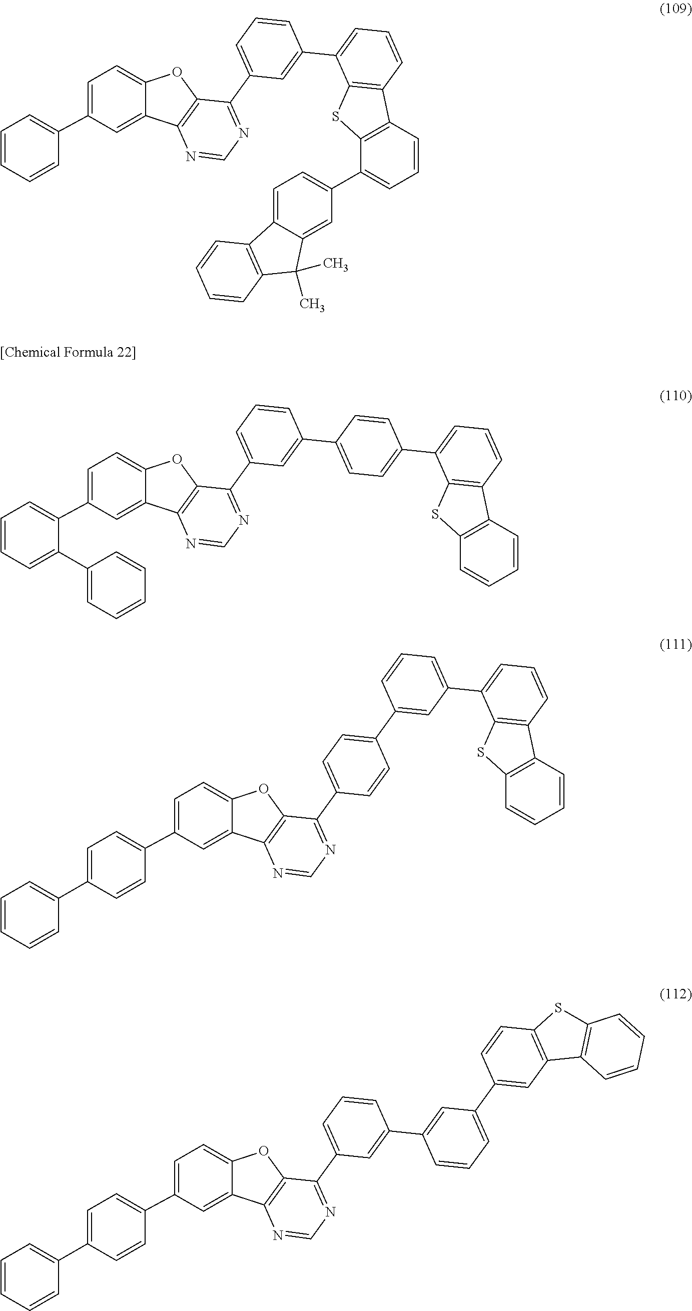

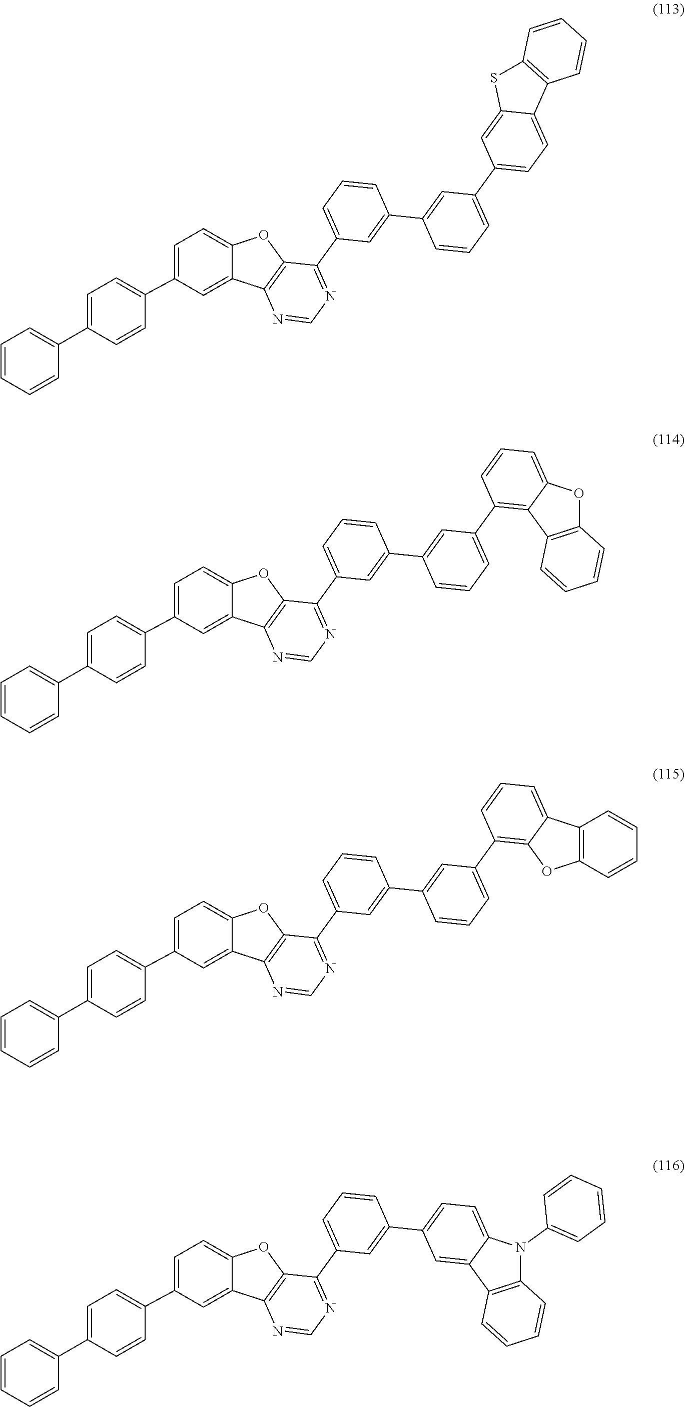

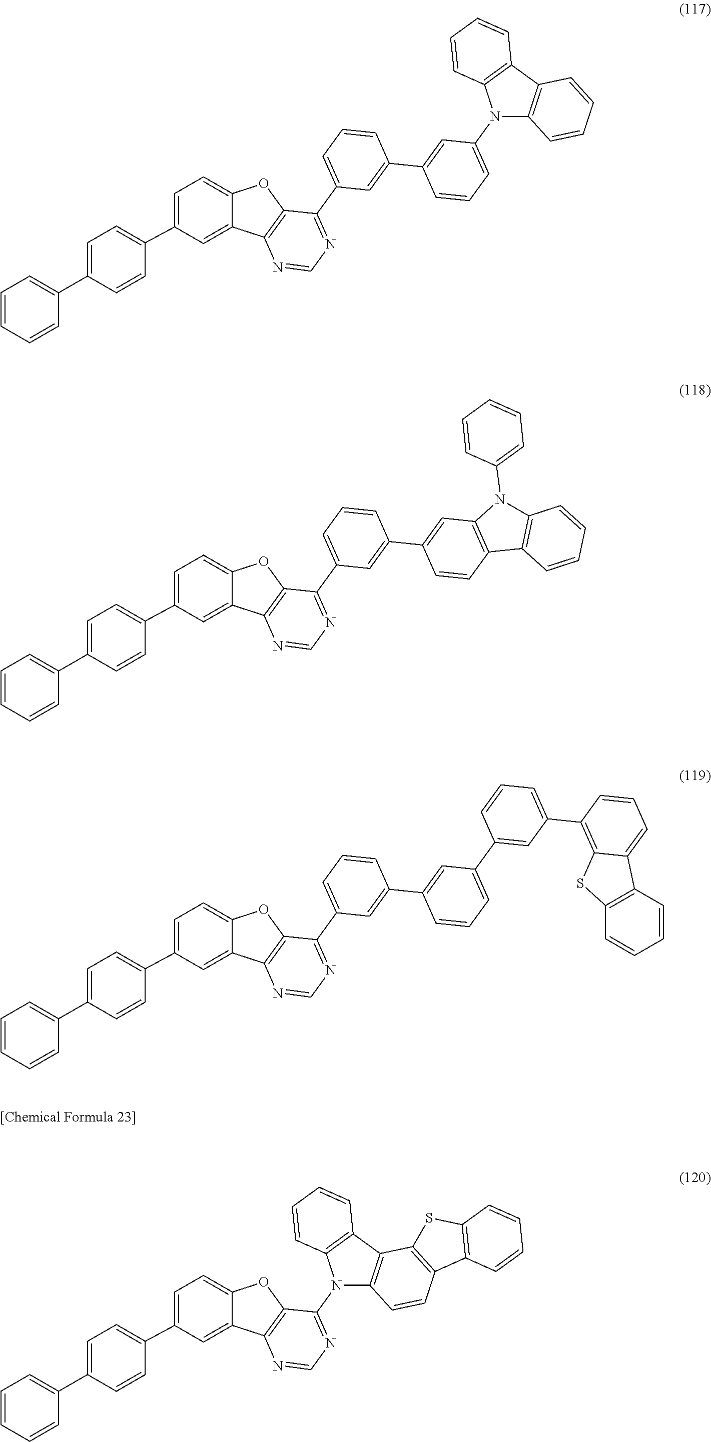

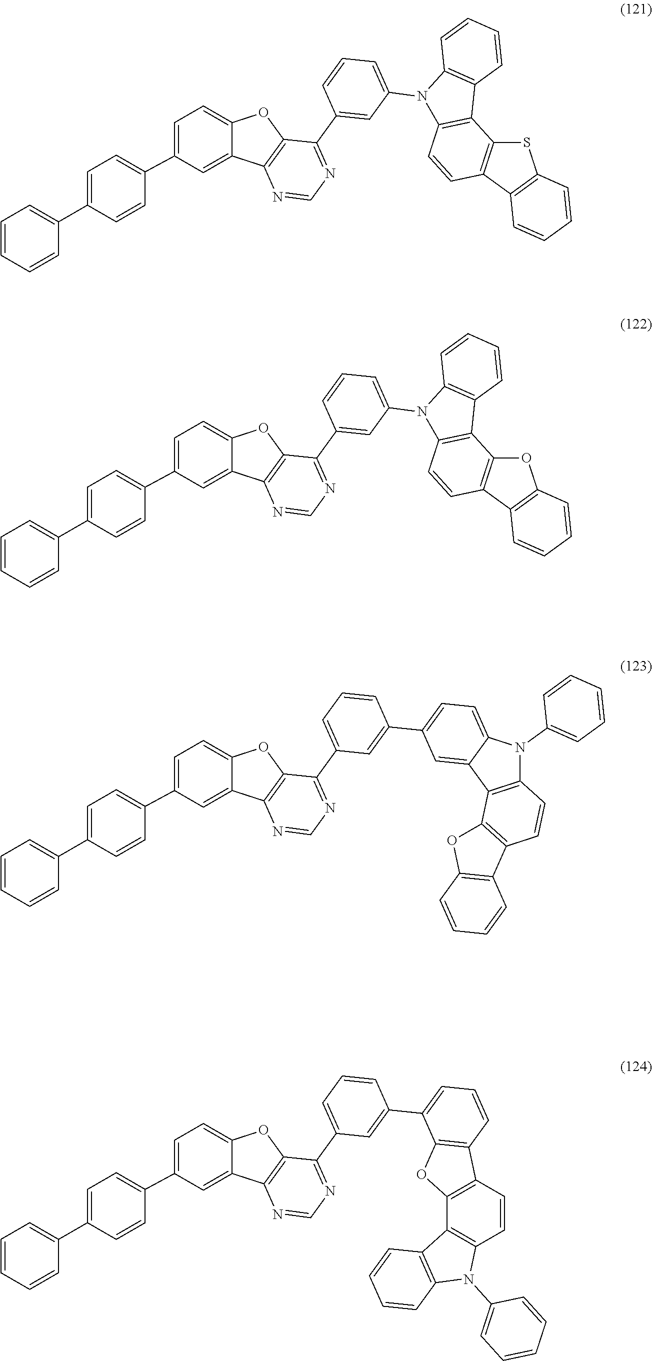

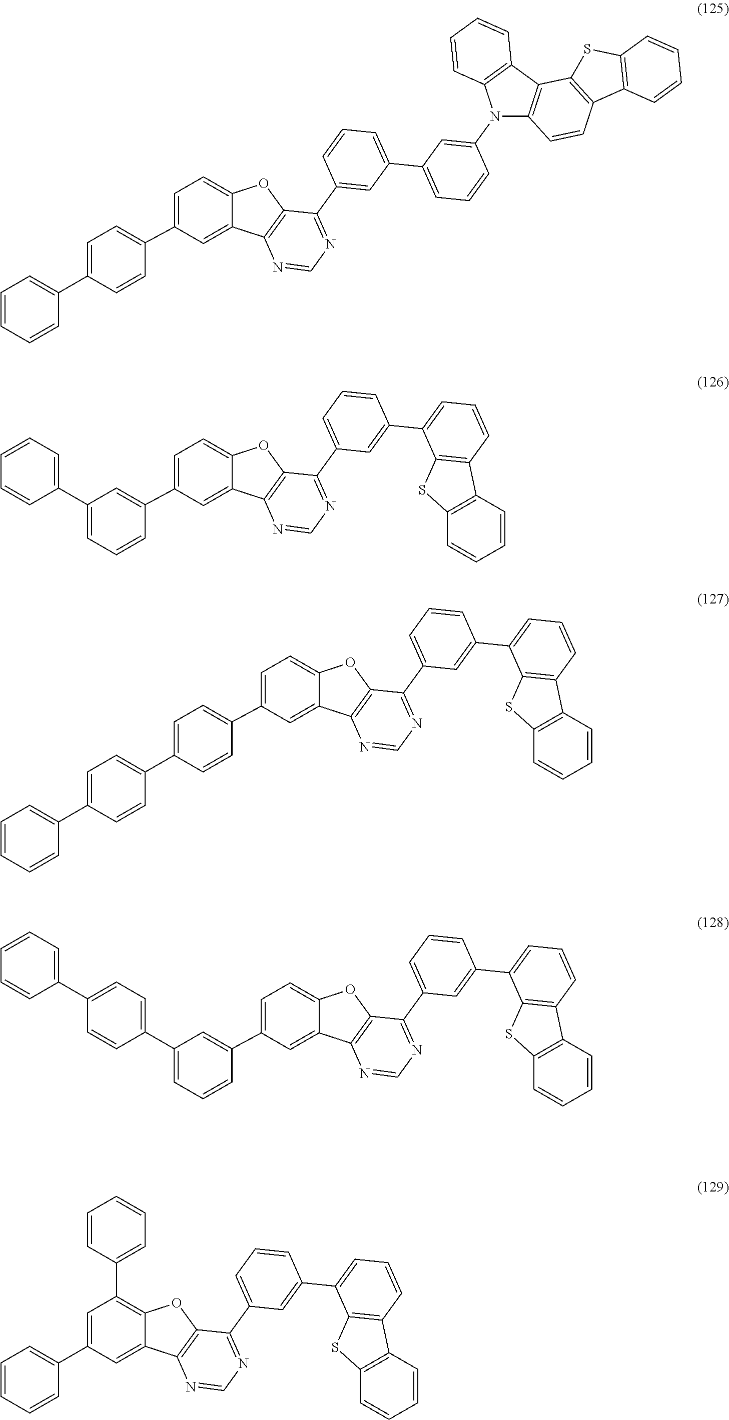

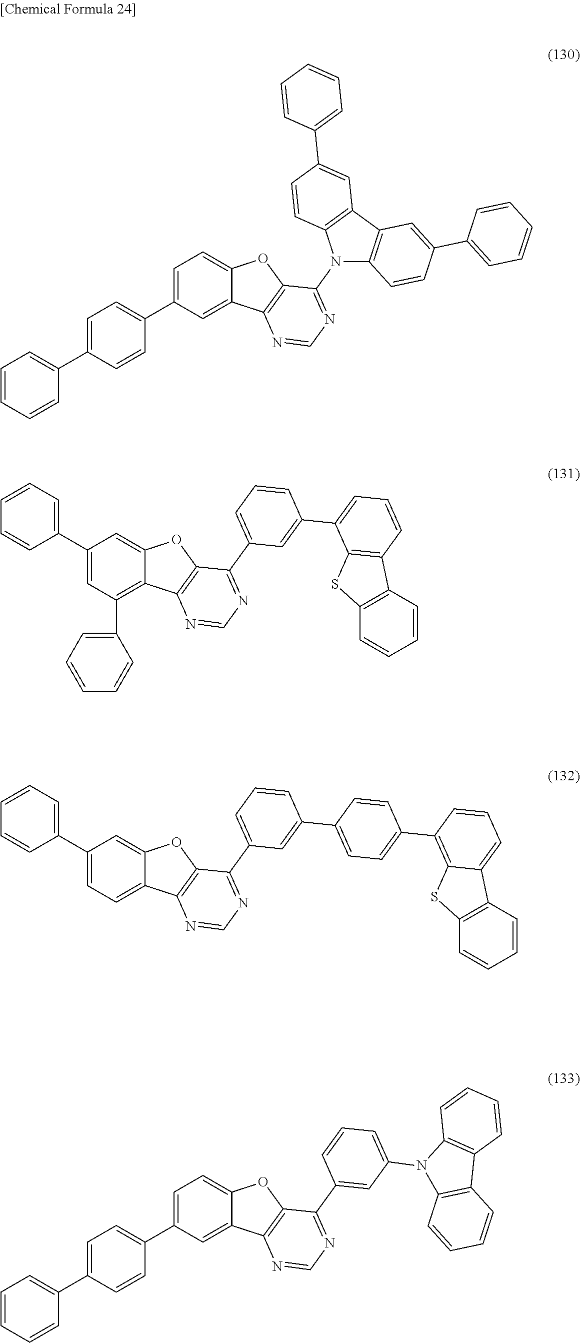

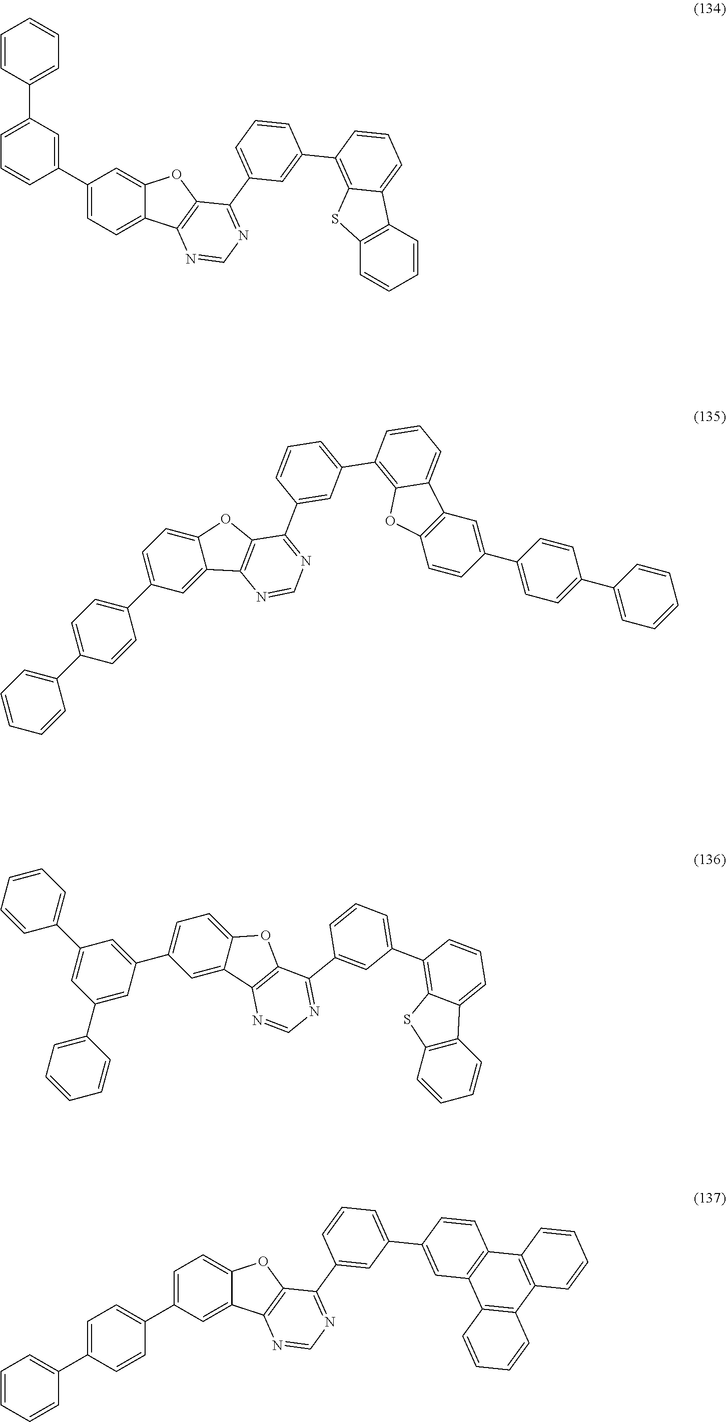

Next, specific examples of the second organic compound, which is included in the composition for a light-emitting device of one embodiment of the present invention and represented by any of General Formula (Q1) and General Formula (Q2) above, are shown in Structural Formula (200) to Structural Formula (215) below.

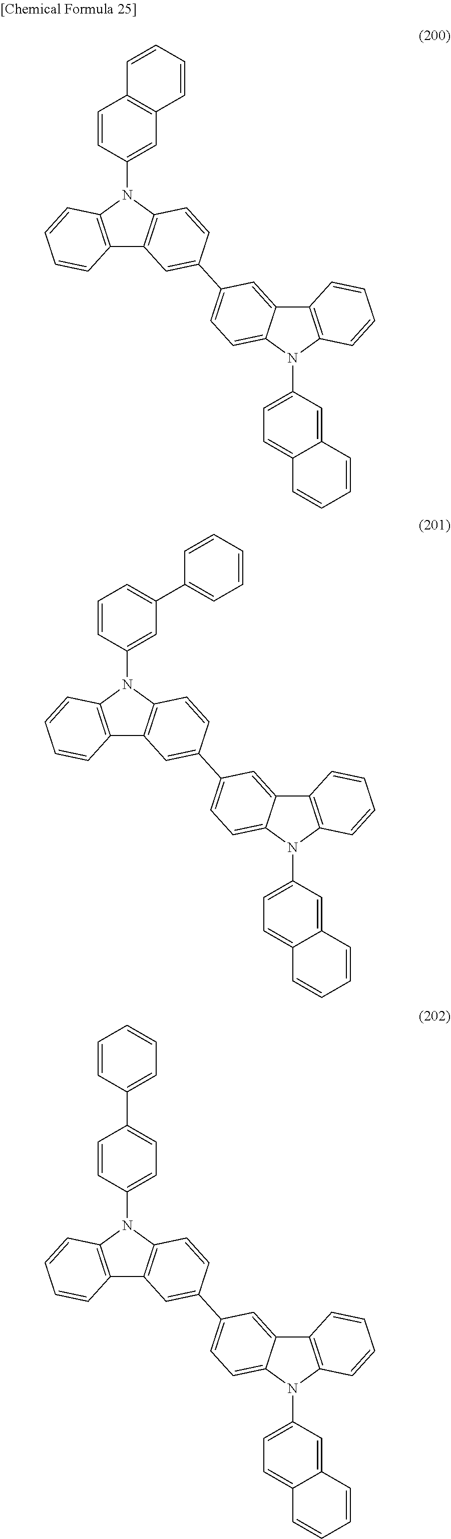

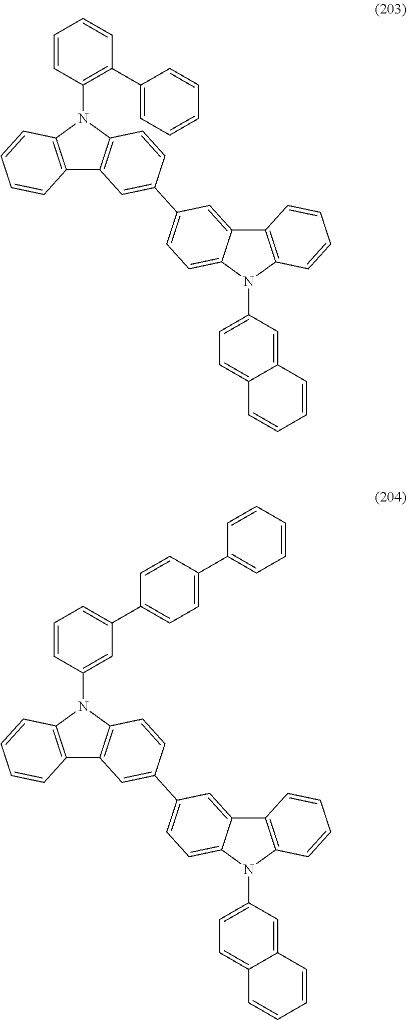

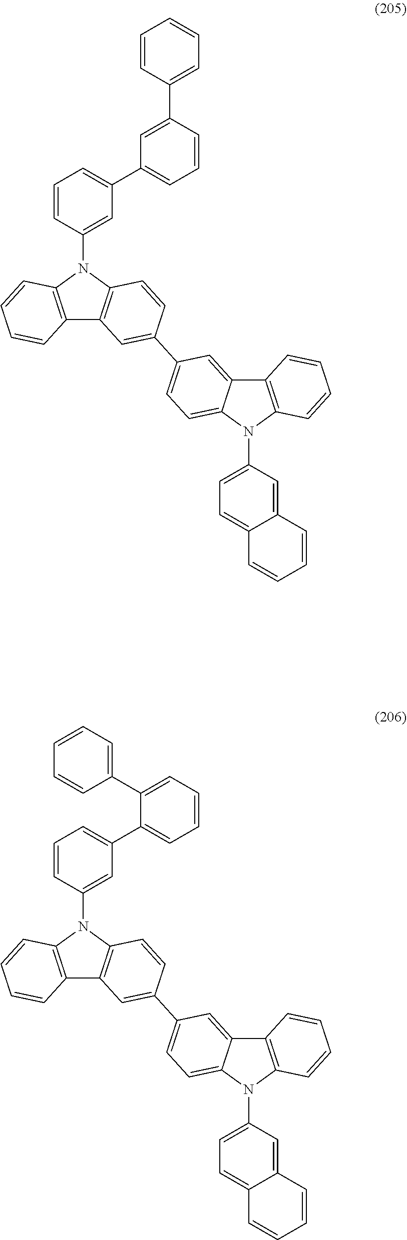

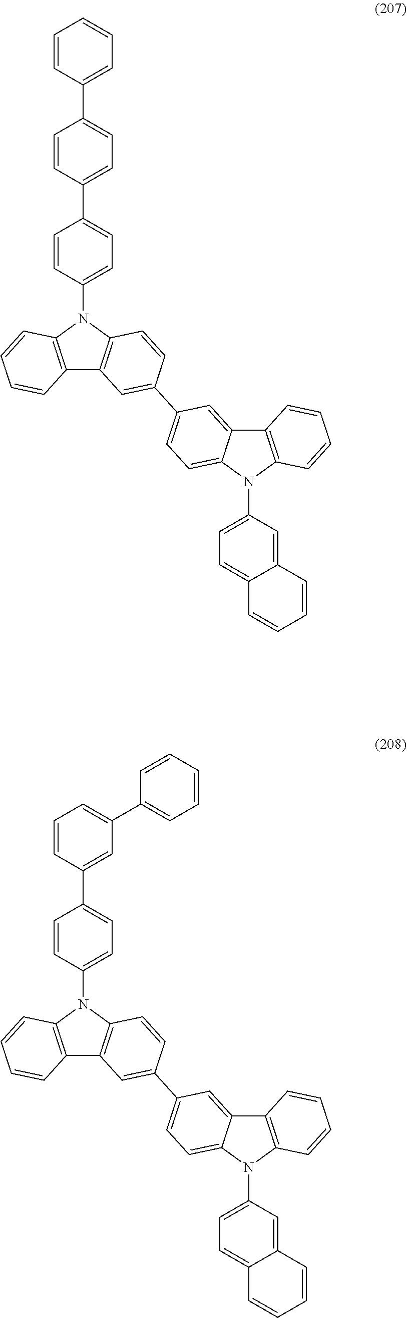

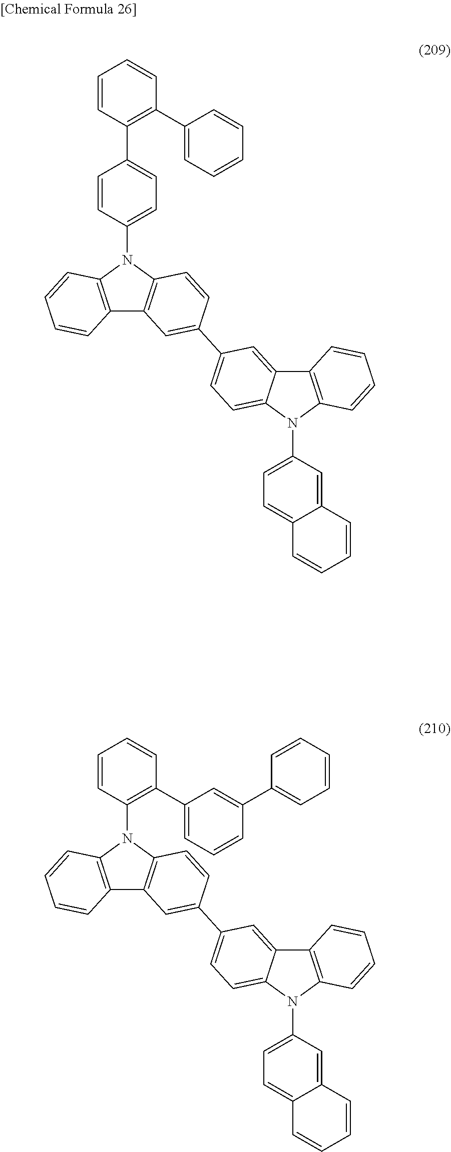

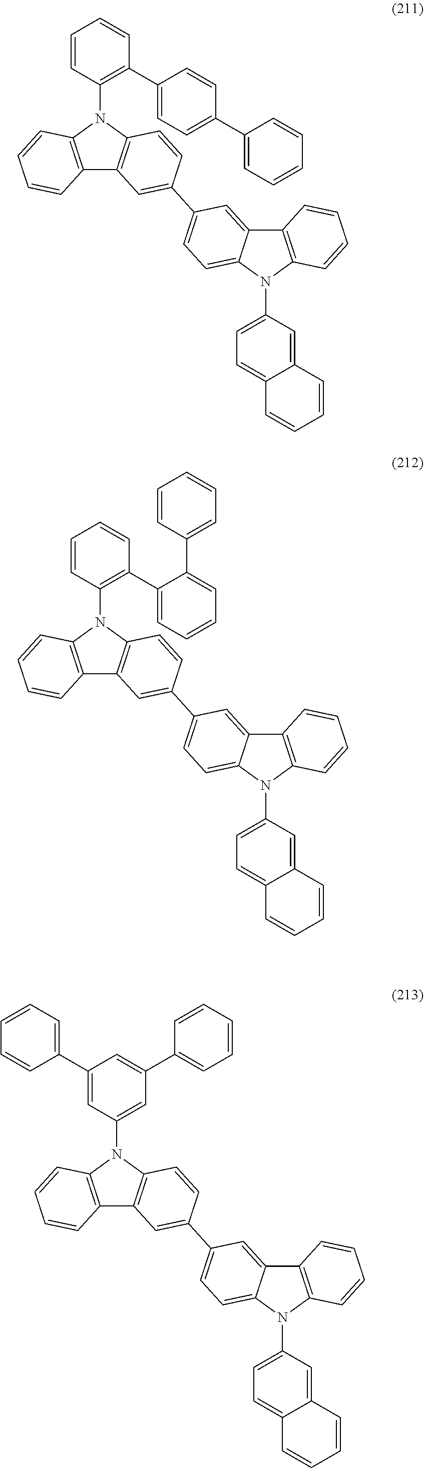

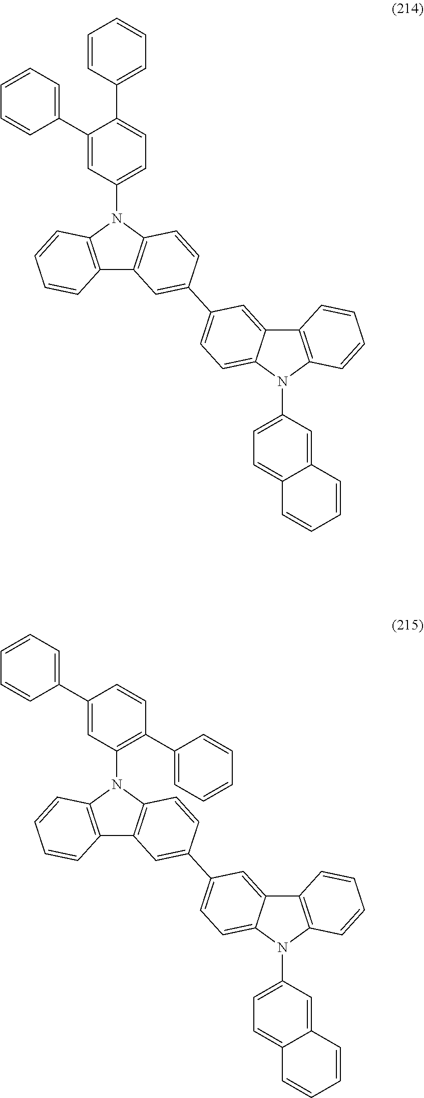

In the composition for a light-emitting device shown in Embodiment 1, a combination of the first organic compound and the second organic compound can preferably form an exciplex.

In the composition for a light-emitting device shown in Embodiment 1, the first organic compound is preferably mixed in a larger proportion than the second organic compound.

In the composition for a light-emitting device shown in Embodiment 1, the molecular weight of the first organic compound is preferably smaller than that of the second organic compound, and the difference in molecular weight is preferably less than or equal to 200.

### Embodiment 2

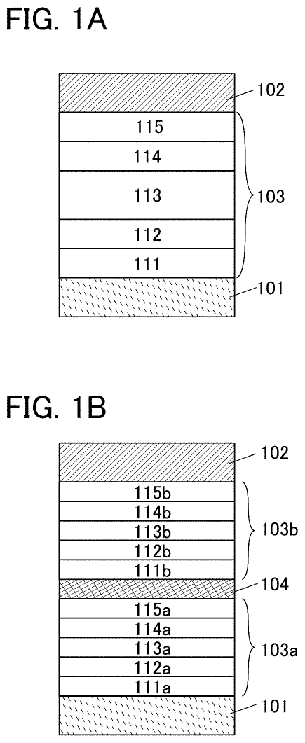

In this embodiment, a light-emitting device in which the composition for a light-emitting device of one embodiment of the present invention can be used will be described with reference to FIG. 1. Note that the composition for a light-emitting device is preferably used for a light-emitting layer in an EL layer.

### <<Structure of Light-Emitting Device>>

FIG. 1 illustrates examples of a light-emitting device including, between a pair of electrodes, an EL layer including a light-emitting layer. Specifically, the light-emitting device has a structure in which an EL layer 103 is sandwiched between a first electrode 101 and a second electrode 102. Note that the EL layer 103 has a structure in which, for example, a hole-injection layer 111, a hole-transport layer 112, a light-emitting layer 113, an electron-transport layer 114, and an electron-injection layer 115 are sequentially stacked as functional layers, in the case where the first electrode 101 serves as an anode. Embodiments of the present invention also include light-emitting devices having other structures: for example, a light-emitting device that can be driven at a low voltage by having a structure (a tandem structure) in which a plurality of EL layers, between which a charge-generation layer is sandwiched, are provided between a pair of electrodes; and a light-emitting device that has improved optical characteristics by having a micro-optical resonator (microcavity) structure between a pair of electrodes. Note that the charge-generation layer has a function of injecting electrons into one of the adjacent EL layers and injecting holes into the other of the EL layers when a voltage is applied to the first electrode 101 and the second electrode 102.

Note that at least one of the first electrode 101 and the second electrode 102 of the above light-emitting device is an electrode having a light-transmitting property (e.g., a transparent electrode or a semi-transmissive and semi-reflective electrode). In the case where the electrode having a light-transmitting property is a transparent electrode, the visible light transmittance of the transparent electrode is higher than or equal to 40%. In the case where the electrode having a light-transmitting property is a semi-transmissive and semi-reflective electrode, the visible light reflectance of the semi-transmissive and semi-reflective electrode is higher than or equal to 20% and lower than or equal to 80%, preferably higher than or equal to 40% and lower than or equal to 70%. The resistivity of these electrodes is preferably lower than or equal to 1×10⁻² Ωcm.

Furthermore, when one of the first electrode 101 and the second electrode 102 is an electrode having reflectivity (reflective electrode) in the above light-emitting device of one embodiment of the present invention, the visible light reflectance of the electrode having reflectivity is higher than or equal to 40% and lower than or equal to 100%, preferably higher than or equal to 70% and lower than or equal to 100%. The resistivity of this electrode is preferably lower than or equal to 1×10⁻² Ωcm.

### <First Electrode and Second Electrode>

As materials for forming the first electrode 101 and the second electrode 102, any of the following materials can be used in an appropriate combination as long as the functions of the electrodes described above can be fulfilled. For example, a metal, an alloy, an electrically conductive compound, a mixture of these, and the like can be used as appropriate. Specifically, an In—Sn oxide (also referred to as ITO), an In—Si—Sn oxide (also referred to as ITSO), an In—Zn oxide, or an In—W—Zn oxide can be given. In addition, it is also possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 of the periodic table, which is not listed above as an example (for example, lithium (Li), cesium (Cs), calcium (Ca), or strontium (Sr)), a rare earth metal such as europium (Eu) or ytterbium (Yb), an alloy containing an appropriate combination of any of these elements, graphene, or the like.

For fabrication of these electrodes, a sputtering method or a vacuum evaporation method can be used.

### <Hole-Injection Layer>

The hole-injection layer 111 is a layer injecting holes from the first electrode 101 that is an anode to the EL layer 103, and is a layer containing an organic acceptor material or a material with a high hole-injection property.

The organic acceptor material is a material that allows holes to be generated in another organic compound whose HOMO level value is close to the LUMO level value of the organic acceptor material when charge separation is caused between the organic acceptor material and the organic compound. Thus, as the organic acceptor material, a compound having an electron-withdrawing group (a halogen group or a cyano group), such as a quinodimethane derivative, a chloranil derivative, or a hexaazatriphenylene derivative, can be used. For example, 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), or 1,3,4,5,7,8-hexafluorotetracyano-naphthoquinodimethane (abbreviation: F6-TCNNQ) can be used. Among organic acceptor materials, HAT-CN, which has a high acceptor property and stable film quality against heat, is particularly favorable. Besides, a [3]radialene derivative has a very high electron-accepting property and thus is preferable; specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

Examples of the material with a high hole-injection property include transition metal oxides such as molybdenum oxide, vanadium oxide, ruthenium oxide, tungsten oxide, and manganese oxide. Alternatively, it is possible to use a phthalocyanine-based compound such as phthalocyanine (abbreviation: H₂Pc) or copper phthalocyanine (abbreviation: CuPc), or the like.

In addition to the above materials, it is also possible to use an aromatic amine compound, which is a low molecular compound, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), or 3-[N-(1-naphthyl)-N-(9-phenylcarbazol-3-yl)amino]-9-phenylcarbazole (abbreviation: PCzPCN1).

It is also possible to use a high molecular compound (an oligomer, a dendrimer, a polymer, or the like) such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD). Alternatively, it is also possible to use a high molecular compound to which acid is added, such as poly(3,4-ethylenedioxythiophene)/poly(styrenesulfonic acid) (abbreviation: PEDOT/PSS) or polyaniline/poly(styrenesulfonic acid) (abbreviation: PAni/PSS), or the like.

Alternatively, as the material having a high hole-injection property, a composite material containing a hole-transport material and an acceptor material (electron-accepting material) can be used. In this case, the acceptor material extracts electrons from the hole-transport material, so that holes are generated in the hole-injection layer 111 and the holes are injected into the light-emitting layer 113 through the hole-transport layer 112. Note that the hole-injection layer 111 may be formed to have a single-layer structure of a composite material containing a hole-transport material and an acceptor material (electron-accepting material), or a stacked-layer structure in which a layer containing a hole-transport material and a layer containing an acceptor material (electron-accepting material) are stacked.

As the hole-transport material, a substance having a hole mobility of greater than or equal to 1×10⁻⁶ cm²/Vs is preferable. Note that other substances can be used as long as they have a property of transporting more holes than electrons.

As the hole-transport material, a material having a high hole-transport property, such as a π-electron rich heteroaromatic compound, is preferable. As the second organic compound used for the composition for a light-emitting device of one embodiment of the present invention, a material such as a π-electron rich heteroaromatic compound is preferable among the materials included in the hole-transport material. Note that as the π-electron rich heteroaromatic compound, an aromatic amine compound having an aromatic amine skeleton (having a triarylamine skeleton), a carbazole compound having a carbazole skeleton (not having a triarylamine skeleton), a thiophene compound (a compound having a thiophene skeleton), a furan compound (a compound having a furan skeleton), or the like can be given.

Examples of the above aromatic amine compound include 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N′-phenyl-N′-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 2,7-bis[N-(4-diphenylaminophenyl)-N-phenylamino]-spiro-9,9′-bifluorene (abbreviation: DPA2SF), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: m-MTDATA), N,N′-di(p-tolyl)-N,N′-diphenyl-p-phenylenediamine (abbreviation: DTDPPA), 4,4′-bis[N-(4-diphenylaminophenyl)-N′-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

Examples of the aromatic amine compound having a carbazolyl group include 4-phenyl-4′-(9-phenyl-9H-carbazol-3-yl)triphenylamine (abbreviation: PCBA1BP), N-(4-biphenyl)-N-(9,9-dimethyl-9H-fluoren-2-yl)-9-phenyl-9H-carbazol-3-amine (abbreviation: PCBiF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N′,N″-triphenyl-N,N′,N″-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-[4-(9-phenyl-9H-carbazol-3-yl)phenyl]-bis(9,9-dimethyl-9H-fluoren-2-yl)amine (abbreviation: PCBFF), N-[4-(9-phenyl-9H-carbazol-3-yl)phenyl]-N-[4-(1-naphthyl)phenyl]-9,9′-spirobi(9H-fluoren)-2-amine (abbreviation: PCBNBSF), N-[4-(9-phenyl-9H-carbazol-3-yl)phenyl]-9,9-dimethyl-N-[4-(1-naphthyl)phenyl]-9H-fluoren-2-amine (abbreviation: PCBNBF), N-phenyl-N-[4-(9-phenyl-9H-carbazol-3-yl)phenyl]spiro-9,9′-bifluoren-2-amine (abbreviation: PCBASF), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino]spiro-9,9′-bifluorene (abbreviation: PCASF), N-[4-(9H-carbazol-9-yl)phenyl]-N-(4-phenyl)phenylaniline (abbreviation: YGA1BP), N,N′-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

Examples of the carbazole compound (not having a triarylamine skeleton) include 3-[4-(9-phenanthryl)-phenyl]-9-phenyl-9H-carbazole (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA). Furthermore, examples of the carbazole compound (not having a triarylamine skeleton) include 3,3′-bis(9-phenyl-9H-carbazole) (abbreviation: PCCP), 9-(1,1′-biphenyl-3-yl)-9′-(1,1′-biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: ONCCP), which are bicarbazole derivatives (e.g., a 3,3′-bicarbazole derivative).

Examples of the thiophene compound (the compound having a thiophene skeleton) include 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Examples of the furan compound (the compound having a furan skeleton) include 4,4′,4″-(benzene-1,3,5-triyl)tri(dibenzofuran) (abbreviation: DBF3P-II), and 4-{3-[3-(9-phenyl-9H-fluoren-9-yl)phenyl]phenyl}dibenzofuran (abbreviation: mmDBFFLBi-II).

In addition, a high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can also be used as the hole-transport material.

Note that the hole-transport material is not limited to the above, and one of or a combination of various known materials may be used as the hole-transport material.

As the acceptor material used for the hole-injection layer 111, an oxide of a metal belonging to any of Group 4 to Group 8 of the periodic table can be used. As specific examples, molybdenum oxide, vanadium oxide, niobium oxide, tantalum oxide, chromium oxide, tungsten oxide, manganese oxide, and rhenium oxide can be given. Among these, molybdenum oxide is particularly preferable since it is stable in the air, has a low hygroscopic property, and is easy to handle. It is also possible to use any of the above-described organic acceptor materials.

Note that the hole-injection layer 111 can be formed by any of various known deposition methods, and can be formed by a vacuum evaporation method, for example.

### <Hole-Transport Layer>

The hole-transport layer 112 is a layer transporting holes, which are injected from the first electrode 101 through the hole-injection layer 111, to the light-emitting layer 113. Note that the hole-transport layer 112 is a layer containing a hole-transport material. Thus, for the hole-transport layer 112, a hole-transport material that can be used for the hole-injection layer 111 can be used.

Note that in the light-emitting device of one embodiment of the present invention, the same organic compound as that for the hole-transport layer 112 is preferably used for the light-emitting layer 113. This is because the use of the same organic compounds for the hole-transport layer 112 and the light-emitting layer 113 allows efficient hole transport from the hole-transport layer 112 to the light-emitting layer 113.

### <Light-Emitting Layer>

The light-emitting layer 113 is a layer containing a light-emitting substance. There is no particular limitation on the light-emitting substance that can be used for the light-emitting layer 113, and it is possible to use a light-emitting substance that converts singlet excitation energy into light in the visible light range (e.g., a fluorescent substance) or a light-emitting substance that converts triplet excitation energy into light in the visible light range (e.g., a phosphorescent substance or a TADF material exhibiting thermally activated delayed fluorescence). In addition, a substance that exhibits emission color of blue, purple, bluish purple, green, yellow green, yellow, orange, red, or the like can be appropriately used.

The light-emitting layer 113 includes a guest material (a light-emitting substance), a host material (an organic compound), and the like. Note that as the host material and the like, it is preferable to use a substance whose energy gap is larger than the energy gap of the guest material. Examples of the host material include organic compounds such as a hole-transport material that can be used for the hole-transport layer 112 described above and an electron-transport material that can be used for the electron-transport layer 114 described later.

In the case where the light-emitting layer 113 includes the first organic compound, the second organic compound, and the light-emitting substance, the composition for a light-emitting device of one embodiment of the present invention, which is formed by mixing the first organic compound and the second organic compound, is preferably used. In such a case, it is possible to use an electron-transport material as the first organic compound, a hole-transport material as the second organic compound, and a phosphorescent substance, a fluorescent substance, a TADF material, or the like as the light-emitting substance. Furthermore, in such a case, a combination of the first organic compound and the second organic compound preferably forms an exciplex.

The light-emitting layer 113 may have a structure including a plurality of light-emitting layers containing different light-emitting substances to exhibit different emission colors (for example, white light emission obtained by a combination of complementary emission colors). Alternatively, a structure may be employed in which one light-emitting layer contains a plurality of different light-emitting substances.

Examples of the light-emitting substance that can be used for the light-emitting layer 113 are given below.

As an example of the light-emitting substance that converts singlet excitation energy into light, a substance that emits fluorescence (a fluorescent substance) can be given.

Example of the fluorescent substance that is the light-emitting substance that converts singlet excitation energy into light include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N′-bis(3-methylphenyl)-N,N′-bis[3-(9-phenyl-9H-fluoren-9-yl)phenyl]pyrene-1,6-diamine (abbreviation: 1,6mMemFLPAPrn), (N,N′-diphenyl-N,N′-bis[4-(9-phenyl-9H-fluoren-9-yl)phenyl]pyrene-1,6-diamine) (abbreviation: 1,6FLPAPrn), N,N′-bis(dibenzofuran-2-yl)-N,N′-diphenylpyrene-1,6-diamine (abbreviation: 1,6FrAPrn), N,N′-bis(dibenzothiophen-2-yl)-N,N′-diphenylpyrene-1,6-diamine (abbreviation: 1,6ThAPrn), N,N′-(pyrene-1,6-diyl)bis[(N-phenylbenzo[b]naphtho[1,2-d]furan)-6-amine](abbreviation: 1,6BnfAPrn), N,N′-(pyrene-1,6-diyl)bis[(N-phenylbenzo[b]naphtho[1,2-d]furan)-8-amine] (abbreviation: 1,6BnfAPrn-02), and N,N′-(pyrene-1,6-diyl)bis[(6,N-diphenylbenzo[b]naphtho[1,2-d]furan)-8-amine] (abbreviation: 1,6BnfAPrn-03).

In addition, it is possible to use 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N′-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra-tert-butylperylene (abbreviation: TBP), N,N′-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), or the like.

Note that as the light-emitting substance that converts singlet excitation energy into light (the fluorescent substance), which can be used for the light-emitting layer 113, a fluorescent substance that exhibits emission color (an emission peak) in part of the near-infrared light range (e.g., a material that emits red light and has a peak at greater than or equal to 800 nm and less than or equal to 950 nm) can also be used without limitation to the above-described fluorescent substance that exhibits emission color (an emission peak) in the visible light range.

Next, as an example of the light-emitting substance that converts triplet excitation energy into light, a substance that emits phosphorescence (a phosphorescent substance) and a thermally activated delayed fluorescent (TADF) material that exhibits thermally activated delayed fluorescence can be given.

First, examples of the phosphorescent substance that is the light-emitting substance that converts triplet excitation energy into light include an organometallic complex, a metal complex (a platinum complex), and a rare earth metal complex. These substances exhibit different emission colors (emission peaks), and thus are used through appropriate selection as needed. Note that, of the phosphorescent substances, the following materials can be given as the material that exhibits emission color (an emission peak) in the visible light range.

The following substances can be given as examples of a phosphorescent substance which emits blue or green light and whose emission spectrum has a peak wavelength at greater than or equal to 450 nm and less than or equal to 570 nm (for example, preferably at greater than or equal to 450 nm and less than or equal to 495 nm in the case of blue light and at greater than or equal to 495 nm and less than or equal to 570 nm in the case of green light).

For example, organometallic complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Ir(iPr5btz)₃]); organometallic complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic complexes having an imidazole skeleton, such as fac-tris[1-(2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Ir(dmpimpt-Me)₃]); organometallic complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)); and the like can be given.

The following substances can be given as examples of a phosphorescent substance which emits green, yellow green, or yellow light and whose emission spectrum has a peak wavelength at greater than or equal to 495 nm and less than or equal to 590 nm. (For example, a peak wavelength at greater than or equal to 495 nm and less than or equal to 570 nm is preferable in the case of green light, a peak wavelength at greater than or equal to 530 nm and less than or equal to 570 nm is preferable in the case of yellow green light, and a peak wavelength at greater than or equal to 570 nm and less than or equal to 590 nm is preferable in the case of yellow light.)

The examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), bis[2-(2-pyridinyl-κN)phenyl-κC][2-(4-phenyl-2-pyridinyl-κN)phenyl-κC]iridium(III) (abbreviation: [Ir(ppy)₂(4dppy)]), bis[2-(2-pyridinyl-κN)phenyl-κC][2-(4-methyl-5-phenyl-2-pyridinyl-κN)phenyl-κC], and [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]); organometallic complexes such as bis(2,4-diphenyl-1,3-oxazolato-N,C^{2′})iridium(III) acetylacetonate (abbreviation: [Ir(dpo)₂(acac)]), bis{2-[4′-(perfluorophenyl)phenyl]pyridinato-N,C^{2′}}iridium(III) acetylacetonate (abbreviation: [Ir(p-PF-ph)₂(acac)]), and bis(2-phenylbenzothiazolato-N,C^{2′})iridium(III) acetylacetonate (abbreviation: [Ir(bt)₂(acac)]); and rare earth metal complexes such as tris(acetylacetonato) (monophenanthroline)terbium(III) (abbreviation: [Tb(acac)₃(Phen)]).

The following substances can be given as examples of a phosphorescent substance which emits yellow, orange, or red light and whose emission spectrum has a peak wavelength at greater than or equal to 570 nm and less than or equal to 750 nm. (For example, a peak wavelength at greater than or equal to 570 nm and less than or equal to 590 nm is preferable in the case of yellow light, a peak wavelength at greater than or equal to 590 nm and less than or equal to 620 nm is preferable in the case of orange light, and a peak wavelength at greater than or equal to 600 nm and less than or equal to 750 nm is preferable in the case of red light.)

For example, organometallic complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and (dipivaloylmethanato)bis[4,6-di(naphthalen-1-yl)pyrimidinato]iridium(III) (abbreviation: [Ir(d1npm)₂(dpm)]); organometallic complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-κN]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-N]phenyl-κC}(2,2,6,6-tetramethyl-3,5-heptanedionato-κ²O,O′)iridium(III) (abbreviation: [Ir(dmdppr-dmCP)₂(dpm)]), bis{4,6-dimethyl-2-[5-(5-cyano-2-methylphenyl)-3-(3,5-dimethylphenyl)-2-pyrazinyl-N]phenyl-κC}(2,2,6,6-tetramethyl-3,5-heptanedionato-κ²O,O′)iridium(III) (abbreviation: [Ir(dmdppr-m5CP)₂(dpm)]), (acetylacetonato)bis[2-methyl-3-phenylquinoxalinato-N,C^{2′}]iridium(III) (abbreviation: [Ir(mpq)₂(acac)]), (acetylacetonato)bis(2,3-diphenylquinoxalinato-N,C^{2′})iridium(III) (abbreviation: [Ir(dpq)₂(acac)]), and (acetylacetonato)bis[2,3-bis(4-fluorophenyl)quinoxalinato]iridium(III) (abbreviation: [Ir(Fdpq)₂(acac)]); organometallic complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), and bis[4,6-dimethyl-2-(2-quinolinyl-κN)phenyl-κC](2,4-pentanedionato-κ²O,O′)iridium(III) (abbreviation: [Ir(dmpqn)₂(acac)]); platinum complexes such as 2,3,7,8,12,13,17,18-octaethyl-21H,23H-porphyrinplatinum(II) (abbreviation: [PtOEP]); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]) can be given.

As the material that can be used for the light-emitting layer, a phosphorescent substance that exhibits emission color (an emission peak) in part of the near-infrared light range (e.g., a material that emits red light and has a peak at greater than or equal to 800 nm and less than or equal to 950 nm), such as a phtalocyanine compound (central metal: aluminum, zinc, or the like), a naphthalocyanine compound, a dithiolene compound (central metal: nickel), a quinone-based compound, a diimonium-based compound, or an azo-based compound, can also be used without limitation to the above phosphorescent substance that exhibits emission color (an emission peak) in the visible light range.

The following materials can be used as the TADF material that is a fluorescent substance that converts triplet excitation energy into light. The TADF material is a material that can up-convert a triplet excited state into a singlet excited state (reverse intersystem crossing) using a little thermal energy and efficiently exhibits light emission (fluorescence) from the singlet excited state. The thermally activated delayed fluorescence is efficiently obtained under the condition where the energy difference between the triplet excited level and the singlet excited level is greater than or equal to 0 eV and less than or equal to 0.2 eV, preferably greater than or equal to 0 eV and less than or equal to 0.1 eV. Note that delayed fluorescence by the TADF material refers to light emission having a spectrum similar to that of normal fluorescence and an extremely long lifetime. The lifetime is longer than or equal to 1×10⁻⁶ seconds, preferably longer than or equal to 1×10⁻³ seconds.

Specific examples of the TADF material include fullerene, a derivative thereof, an acridine derivative such as proflavine, and eosin. Other examples include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

Alternatively, a heterocyclic compound having one or both of a π-electron rich heteroaromatic ring and a π-electron deficient heteroaromatic ring, such as 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA), can also be used.

Note that a substance in which a π-electron rich heteroaromatic ring is directly bonded to a π-electron deficient heteroaromatic ring is particularly preferable because both the donor property of the π-electron rich heteroaromatic ring and the acceptor property of the π-electron deficient heteroaromatic ring are improved and the energy difference between the singlet excited state and the triplet excited state becomes small.

In the case where the above-described light-emitting substance (the light-emitting substance that converts singlet excitation energy into light in the visible light range (e.g., the fluorescent substance) or the light-emitting substance that converts triplet excitation energy into light in the visible light range (e.g., the phosphorescent substance or the TADF material that exhibits thermally activated delayed fluorescence)) is used in the light-emitting layer 113, the composition for a light-emitting device of one embodiment of the present invention may include the following organic compounds in addition to the compositions for light-emitting devices shown in Embodiment 1.

For example, in the case where a fluorescent substance, which is a light-emitting substance that converts singlet excitation energy into light, is used as the light-emitting substance in the light-emitting layer 113, it may be used in combination with an organic compound like a condensed polycyclic aromatic compound or the like, such as an anthracene derivative, a tetracene derivative, a phenanthrene derivative, a pyrene derivative, a chrysene derivative, or a dibenzo[g,p]chrysene derivative.

Specific examples include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), 3-[4-(1-naphthyl)-phenyl]-9-phenyl-9H-carbazole (abbreviation: PCPN), 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetraamine (abbreviation: DBC1), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)-biphenyl-4′-yl}-anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, and 5,12-bis(biphenyl-2-yl)tetracene.

In the case where a phosphorescent substance, which is a light-emitting substance that converts triplet excitation energy into light, is used as the light-emitting substance in the light-emitting layer 113, it is preferably used in combination with an organic compound having triplet excitation energy (energy difference between a ground state and a triplet excited state) higher than the triplet excitation energy of the light-emitting substance. The above-described organic compound having a high hole-transport property (the second organic compound) and an organic compound having a high electron-transport property (the first organic compound) may be used in combination.

Furthermore, a plurality of organic compounds that can form an exciplex (e.g., the first organic compound and the second organic compound, or a first host material and a second host material) may be used. Note that in the case where a plurality of organic compound are used to form an exciplex, a compound that easily accepts holes (a hole-transport material) and a compound that easily accepts electrons (an electron-transport material) are preferably combined, in which case an exciplex can be formed efficiently. In addition, when a phosphorescent substance and an exciplex are included in a light-emitting layer, ExTET (Exciplex-Triplet Energy Transfer), which is energy transfer from an exciplex to a light-emitting substance, can be performed efficiently, increasing emission efficiency. Note that a fluorescent substance and an exciplex may be included in a light-emitting layer.

Any of the above materials may be used in combination with a low molecular material or a high molecular material. A stacked-layer structure may also be employed. Specific examples of the high molecular material include poly(2,5-pyridinediyl) (abbreviation: PPy), poly[(9,9-dihexylfluorene-2,7-diyl)-co-(pyridine-3,5-diyl)] (abbreviation: PF-Py), and poly[(9,9-dioctylfluorene-2,7-diyl)-co-(2,2′-bipyridine-6,6′-diyl)] (abbreviation: PF-BPy).

### <Electron-Transport Layer>

The electron-transport layer 114 is a layer transporting electrons, which are injected from the second electrode 102 through the electron-injection layer 115 to be described later, to the light-emitting layer 113. Note that the electron-transport layer 114 is a layer containing an electron-transport material. The electron-transport material used for the electron-transport layer 114 is preferably a substance having an electron mobility of greater than or equal to 1×10⁻⁶ cm²/Vs. Note that other substances can be used as long as they have a property of transporting more electrons than holes. The electron-transport layers (114, 114a, and 114b) each function even with a single-layer structure, but can improve the device characteristics when having a stacked-layer structure of two or more layers as needed.

A material having a high electron-transport property, such as a π-electron deficient heteroaromatic compound, is preferable as the organic compound that can be used for the electron-transport layer 114. Furthermore, as the first organic compound used for the composition for a light-emitting device of one embodiment of the present invention, a material such as a π-electron deficient heteroaromatic compound is preferable among the materials included in the electron-transport materials. Examples of the π-electron deficient heteroaromatic compound include a compound having a benzofurodiazine skeleton in which a benzene ring as an aromatic ring is condensed with a furan ring of a furodiazine skeleton, a compound having a naphtofurodiazine skeleton in which a naphthyl ring as an aromatic ring is condensed with a furan ring of a furodiazine skeleton, a compound having a phenanthrofurodiazine skeleton in which a phenanthro ring as an aromatic ring is condensed with a furan ring of a furodiazine skeleton, a compound having a benzothienodiazine skeleton in which a benzene ring as an aromatic ring is condensed with a thieno ring of a thienodiazine skeleton, a compound having a naphthothienodiazine skeleton in which a naphthyl ring as an aromatic ring is condensed with a thieno ring of a thienodiazine skeleton, and a compound having a phenanthrothienodiazine skeleton in which a phenanthro ring as an aromatic ring is condensed with a thieno ring of a thienodiazine skeleton. Other examples include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a nitrogen-containing heteroaromatic compound.

Note that examples of the electron-transport material include 9-[(3′-dibenzothiophen-4-yl)biphenyl-3-yl]naphtho[1′,2′:4,5]furo[2,3-b]pyrazine (abbreviation: 9mDBtBPNfpr), 9-(9′-phenyl-3,3′-bi-9H-carbazol-9-yl)naphtho[1′,2′:4,5]furo[2,3-b]pyrazine (abbreviation: 9PCCzNfpr), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-[3-(9′-phenyl-2,3′-bi-9H-carbazol-9-yl)phenyl]naphtho[1′,2′:4,5]furo[2,3-b]pyrazine (abbreviation: 9mPCCzPNfpr-02), 10-[(3′-dibenzothiophen-4-yl)biphenyl-3-yl]naphtho[1′,2′:4,5]furo[2,3-b]pyrazine (abbreviation: 10mDBtBPNfpr), 10-(9′-phenyl-3,3′-bi-9H-carbazol-9-yl)naphtho[1′,2′:4,5]furo[2,3-b]pyrazine (abbreviation: 10PCCzNfpr), 12-[(3′-dibenzothiophen-4-yl)biphenyl-3-yl]phenanthro[9′,10′:4,5]furo[2,3-b]pyrazine (abbreviation: 12mDBtBPPnfpr), 9-[4-(9′-phenyl-3,3′-bi-9H-carbazol-9-yl)phenyl]naphtho[1′,2′:4,5]furo[2,3-b]pyrazine (abbreviation: 9pPCCzPNfpr), 9-[4-(9′-phenyl-2,3′-bi-9H-carbazol-9-yl)phenyl]naphtho[1′,2′:4,5]furo[2,3-b]pyrazine (abbreviation: 9pPCCzPNfpr-02), 9-[3′-(6-phenylbenzo[b]naphtho[1,2-d]furan-8-yl)biphenyl-3-yl]naphtho[1′,2′:4,5]furo[2,3-b]pyrazine (abbreviation: 9mBnfBPNfpr), 9-[3′-(6-phenyldibenzothiophen-4-yl)biphenyl-3-yl]naphtho[1′,2′:4,5]furo[2,3-b]pyrazine (abbreviation: 9mDBtBPNfpr-02), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 11-(3-naphtho[1′,2′:4,5]furo[2,3-b]pyrazin-9-yl-phenyl)-12-phenylindolo[2,3-a]carbazole (abbreviation: 9mIcz(II)PNfpr), 3-naphtho[1′,2′:4,5]furo[2,3-b]pyrazin-9-yl-N,N-diphenylbenzenamine (abbreviation: 9mTPANfpr), 10-[4-(9′-phenyl-3,3′-bi-9H-carbazol-9-yl)phenyl]naphtho[1′,2′:4,5]furo[2,3-b]pyrazine (abbreviation: 10mPCCzPNfpr), 11-[(3′-(dibenzothiophen-4-yl)biphenyl-3-yl]phenanthro[9′,10′:4,5]furo[2,3-b]pyrazine (abbreviation: 11mDBtBPPnfpr), 10-[3-(9′-phenyl-3,3′-bi-9H-carbazol-9-yl)phenyl]naphtho[1′,2′:4,5]furo[2,3-b]pyrazine (abbreviation: 10pPCCzPNfpr), 9-[3-(7H-dibenzo[c,g]carbazol-7-yl)phenyl]naphtho[1′,2′:4,5]furo[2,3-b]pyrazine (abbreviation: 9mcgDBCzPNfpr), 9-{3′-[6-(biphenyl-3-yl)dibenzothiophen-4-yl]biphenyl-3-yl}naphtho[1′,2′:4,5]furo[2,3-b]pyrazine (abbreviation: 9mDBtBPNfpr-03), 9-{3′-[6-(biphenyl-4-yl)dibenzothiophen-4-yl]biphenyl-3-yl}naphtho[1′,2′:4,5]furo[2,3-b]pyrazine (abbreviation: 9mDBtBPNfpr-04), and 11-[3′-(6-phenyldibenzothiophen-4-yl)biphenyl-3-yl]phenanthro[9′,10′:4,5]furo[2,3-b]pyrazine (abbreviation: 11mDBtBPPnfpr-02).

Alternatively, 4-[3-(dibenzothiophen-4-yl)phenyl]-8-(naphthalen-2-yl)-[1]benzofuro[3,2-d]pyrimidine (abbreviation: 8βN-4mDBtPBfpm), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 4,8-bis[3-(dibenzothiophen-4-yl)phenyl]-[1]benzofuro[3,2-d]pyrimidine (abbreviation: 4,8mDBtP2Bfpm), 8-[(2,2′-binaphthalen)-6-yl]-4-[3-(dibenzothiophen-4-yl)phenyl-[1]benzofuro[3,2-d]pyrimidine (abbreviation: 8(βN2)-4mDBtPBfpm), 3,8-bis[3-(dibenzothiophen-4-yl)phenyl]benzofuro[2,3-b]pyrazine (abbreviation: 3,8mDBtP2Bfpr), 8-[3′-(dibenzothiophen-4-yl)(1,1′-biphenyl-3-yl)]naphtho[1′,2′:4,5]furo[3,2-d]pyrimidine (abbreviation: 8mDBtBPNfpm), or the like can be used.

Further alternatively, a metal complex having a quinoline skeleton or a benzoquinoline skeleton, such as tris(8-quinolinolato)aluminum(III) (abbreviation: Alq₃), tris(4-methyl-8-quinolinolato)aluminum (abbreviation: Almq₃), bis(10-hydroxybenzo[h]quinolinato)beryllium (abbreviation: BeBq₂), bis(2-methyl-8-quinolinolato) (4-phenylphenolato)aluminum(III) (abbreviation: BAlq), or bis(8-quinolinolato)zinc(II) (abbreviation: Znq); a metal complex having an oxazole skeleton or a thiazole skeleton, such as bis[2-(2-benzoxazolyl)phenolato]zinc(II) (abbreviation: ZnPBO) or bis[2-(2-benzothiazolyl)phenolato]zinc(II) (abbreviation: ZnBTZ); or the like can be used.

Still further alternatively, any of the following can be used: an oxadiazole derivative such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), or 9-[4-(5-phenyl-1,3,4-oxadiazol-2-yl)phenyl]-9H-carbazole (abbreviation: CO11); a triazole derivative such as 3-(4-biphenylyl)-4-phenyl-5-(4-tert-butylphenyl)-1,2,4-triazole (abbreviation: TAZ) or 3-(4-tert-butylphenyl)-4-(4-ethylphenyl)-5-(4-biphenylyl)-1,2,4-triazole (abbreviation: p-EtTAZ); an imidazole derivative (including a benzimidazole derivative) such as 2,2′,2″-(1,3,5-benzenetriyl)tris(1-phenyl-1H-benzimidazole) (abbreviation: TPBI) or 2-[3-(dibenzothiophen-4-yl)phenyl]-1-phenyl-1H-benzimidazole (abbreviation: mDBTBIm-II); an oxazole derivative such as 4,4′-bis(5-methylbenzoxazol-2-yl)stilbene (abbreviation: BzOs); a phenanthroline derivative such as bathophenanthroline (abbreviation: Bphen), bathocuproine (abbreviation: BCP), or 2,9-bis(naphthalen-2-yl)-4,7-diphenyl-1,10-phenanthroline (abbreviation: NBphen); a quinoxaline derivative or a dibenzoquinoxaline derivative such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), or 6-[3-(dibenzothiophen-4-yl)phenyl]dibenzo[f,h]quinoxaline (abbreviation: 6mDBTPDBq-II); a pyridine derivative such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB); a pyrimidine derivative such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,6-bis[3-(9H-carbazol-9-yl)phenyl]pyrimidine (abbreviation: 4,6mCzP2Pm); and a triazine derivative such as 2-{4-[3-(N-phenyl-9H-carbazol-3-yl)-9H-carbazol-9-yl]phenyl}-4,6-diphenyl-1,3,5-triazine (abbreviation: PCCzPTzn), mPCCzPTzn-02, 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnfBPTzn-02)

It is also possible to use a high molecular compound such as PPy, PF-Py, or PF-BPy.

### <Electron-Injection Layer>

The electron-injection layer 115 is a layer for increasing the efficiency of electron injection from the second electrode (cathode) 102; thus, the electron-injection layer 115 is preferably formed using a material whose LUMO level value has a small difference (0.5 eV or less) from the work function value of the material of the second electrode (cathode) 102. Thus, the electron-injection layer 115 can be formed using an alkali metal, an alkaline earth metal, or a compound thereof, such as lithium, cesium, lithium fluoride (LiF), cesium fluoride (CsF), calcium fluoride (CaF₂), 8-(hydroxyquinolinato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. A rare earth metal compound like erbium fluoride (ErF₃) can also be used.

When a charge-generation layer 104 is provided between two EL layers (103a and 103b) as in the light-emitting device illustrated in FIG. 1B, a structure in which a plurality of EL layers are stacked between the pair of electrodes (also referred to as a tandem structure) can be employed. Note that in this embodiment, functions and materials of the hole-injection layer (111), the hole-transport layer (112), the light-emitting layer (113), the electron-transport layer (114), and the electron-injection layer (115) that are illustrated in FIG. 1A are the same as those of hole-injection layers (111a and 111b), hole-transport layers (112a and 112b), light-emitting layers (113a and 113b), electron-transport layers (114a and 114b), and electron-injection layers (115a and 115b) that are illustrated in FIG. 1B.

### <Charge-Generation Layer>

In the light-emitting device of FIG. 1B, the charge-generation layer 104 has a function of injecting electrons into the EL layer 103a and injecting holes into the EL layer 103b when voltage is applied between the first electrode (anode) 101 and the second electrode (cathode) 102. Note that the charge-generation layer 104 may have either a structure in which an electron acceptor (acceptor) is added to a hole-transport material or a structure in which an electron donor (donor) is added to an electron-transport material. Alternatively, both of these structures may be stacked. Note that forming the charge-generation layer 104 with the use of any of the above materials can inhibit an increase in driving voltage in the case where the EL layers are stacked.

In the case where the charge-generation layer 104 has a structure in which an electron acceptor is added to a hole-transport material, any of the materials described in this embodiment can be used as the hole-transport material. As the electron acceptor, 7,7,8,8-tetracyano-2,3,5,6-tetrafluoroquinodimethane (abbreviation: F₄-TCNQ), chloranil, and the like can be given. Other examples include oxides of metals belonging to Group 4 to Group 8 of the periodic table. Specific examples are vanadium oxide, niobium oxide, tantalum oxide, chromium oxide, molybdenum oxide, tungsten oxide, manganese oxide, and rhenium oxide.

In the case where the charge-generation layer 104 has a structure in which an electron donor is added to an electron-transport material, any of the materials described in this embodiment can be used as the electron-transport material. As the electron donor, it is possible to use an alkali metal, an alkaline earth metal, a rare earth metal, metals belonging to Groups 2 and 13 of the periodic table, or an oxide or carbonate thereof. Specifically, lithium (Li), cesium (Cs), magnesium (Mg), calcium (Ca), ytterbium (Yb), indium (In), lithium oxide, cesium carbonate, or the like is preferably used. An organic compound such as tetrathianaphthacene may be used as the electron donor.

Although FIG. 1B illustrates the structure in which two EL layers 103 are stacked, three or more EL layers may be stacked with a charge-generation layer provided between different EL layers. The light-emitting layers 113 (113a and 113b) included in the EL layers (103, 103a, and 103b) each include an appropriate combination of a light-emitting substance and a plurality of substances, so that fluorescence or phosphorescence of a desired emission color can be obtained. In the case where a plurality of light-emitting layers 113 (113a and 113b) are provided, emission colors of the respective light-emitting layers may be different from each other. In that case, light-emitting substances and other substances are different between the stacked light-emitting layers. For example, the light-emitting layer 113a can emit blue light, and the light-emitting layer 113b can emit red, green, or yellow light; for another example, the light-emitting layer 113a can emit red light, and the light-emitting layer 113b can emit blue, green, or yellow light. Furthermore, in the case where three or more EL layers are stacked, the light-emitting layer (113a) of the first EL layer can emit blue light, the light-emitting layer (113b) of the second EL layer can emit red, green, or yellow light, and a light-emitting layer of the third EL layer can emit blue light. For another example, the light-emitting layer (113a) of the first EL layer can emit red light, the light-emitting layer (113b) of the second EL layer can emit blue, green, or yellow light, and the light-emitting layer of the third EL layer can emit red light. Note that another combination of emission colors can be employed as appropriate in consideration of luminance and characteristics of the plurality of emission colors.

### <Substrate>

The light-emitting device described in this embodiment can be formed over any of a variety of substrates. Note that the type of the substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, and a base material film.

Note that examples of the glass substrate include barium borosilicate glass, aluminoborosilicate glass, and soda lime glass. Examples of the flexible substrate, the attachment film, and the base material film include plastics typified by polyethylene terephthalate (PET), polyethylene naphthalate (PEN), and polyether sulfone (PES); a synthetic resin such as an acrylic resin; polypropylene; polyester; polyvinyl fluoride; polyvinyl chloride; polyamide; polyimide; an aramid resin; an epoxy resin; an inorganic vapor deposition film; and paper.

For fabrication of the light-emitting device in this embodiment, a vacuum process such as an evaporation method or a solution process such as a spin coating method or an ink-jet method can be used. In the case of using an evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the functional layers (the hole-injection layers (111, 111a, and 111b), the hole-transport layers (112, 112a, and 112b), the light-emitting layers (113, 113a, and 113b), the electron-transport layers (114, 114a, and 114b), the electron-injection layers (115, 115a, and 115b), and the charge-generation layers (104, 104a, and 104b)) included in the EL layers of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, a micro-contact printing method, or a nanoimprinting method), or the like.

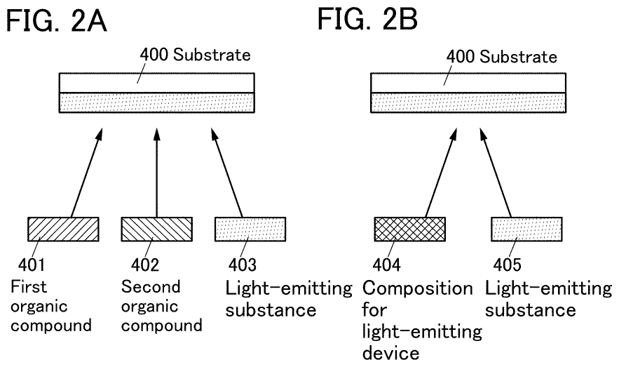

Note that in the case where the functional layer included in the EL layer of the light-emitting device is formed using the composition for a light-emitting device of one embodiment of the present invention, it is particularly preferable to employ an evaporation method. For example, in the case where three kinds of materials (the light-emitting substance, the first organic compound, and the second organic compound) are used for forming the light-emitting layer (113, 113a, or 113b), the same number of evaporation sources (three in this case) as the number of the materials to be evaporated are used as illustrated in FIG. 2A, a first organic compound 401, a second organic compound 402, and a light-emitting substance 403 are put in the respective evaporation sources and co-evaporation is performed; thus, the light-emitting layer (113, 113a, or 113b) that is a mixed film of the three kinds of evaporation materials is formed over a surface of a substrate 400. In the case where the composition for a light-emitting device in which the first organic compound and the second organic compound of the three kinds of materials are mixed is used, two kinds of evaporation sources are used as illustrated in FIG. 2B even though three kinds of materials are used for forming the light-emitting layer (113, 113a, or 113b), a composition 404 for a light-emitting device and a light-emitting substance 405 are put in the respective evaporation sources and co-evaporation is performed; thus, the light-emitting layer (113, 113a, or 113b) that is the same mixed film as the mixed film formed using three kinds of evaporation sources can be formed.

The composition for a light-emitting device is obtained by mixing compounds having a specific molecular structure as described in Embodiment 1; therefore, even though a plurality of unspecific compounds are mixed to be put in one evaporation source and evaporation is performed, it is difficult to obtain a film with a quality substantially the same as that in the case where the compounds are put in different evaporation sources and co-evaporation is performed. For example, there arise problems in that composition is changed because part of the mixed material is deposited first, a film with desired quality (e.g., composition and film thickness) is not obtained, and the like. In addition, in the mass-producing process, troubles such as complexity of apparatus specifications and increase in effort for maintenance occur.

Such a use of the composition for a light-emitting device of one embodiment of the present invention for part of an EL layer or a light-emitting layer is probably preferable because a highly productive light-emitting device can be manufactured while device characteristics and reliability of the light-emitting device are maintained.

Note that materials that can be used for the functional layers (the hole-injection layers (111, 111a, and 111b), the hole-transport layers (112, 112a, and 112b), the light-emitting layers (113, 113a, 113b, and 113c), the electron-transport layers (114, 114a, and 114b), the electron-injection layers (115, 115a, and 115b), and the charge-generation layers (104, 104a, and 104b)) included in the EL layers (103, 103a, and 103b) of the light-emitting device described in this embodiment are not limited to the above materials, and other materials can also be used in combination as long as the functions of the layers are fulfilled. For example, a high molecular compound (e.g., an oligomer, a dendrimer, and a polymer), a middle molecular compound (a compound between a low molecular compound and a high molecular compound with a molecular weight of 400 to 4000), or an inorganic compound (e.g., a quantum dot material) can be used. As the quantum dot material, a colloidal quantum dot material, an alloyed quantum dot material, a core-shell quantum dot material, a core quantum dot material, or the like can be used.

The structure described in this embodiment can be used in an appropriate combination with any of the structures described in the other embodiments.

### Embodiment 3

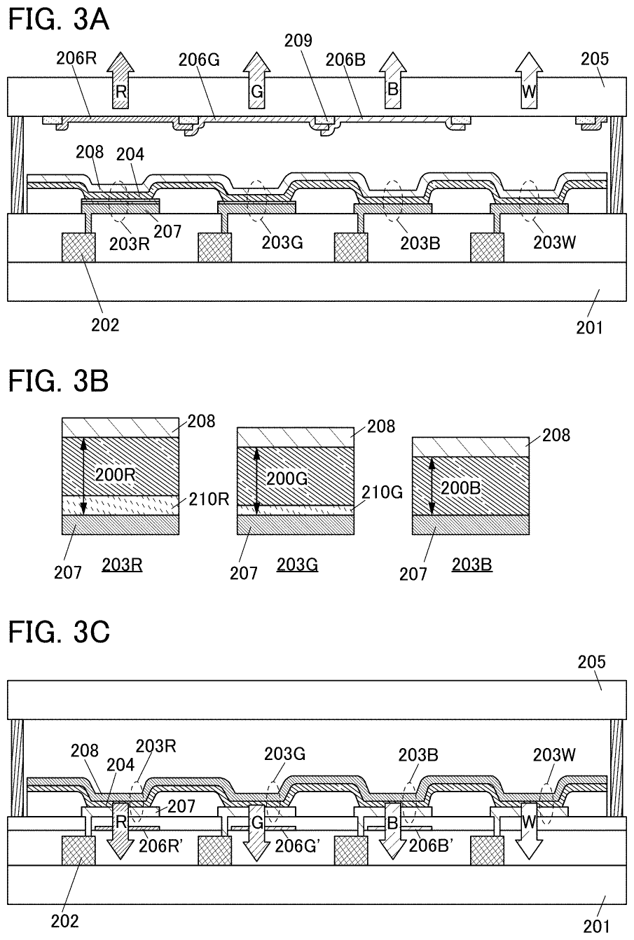

In this embodiment, a light-emitting apparatus of one embodiment of the present invention will be described. Note that a light-emitting apparatus illustrated in FIG. 3A is an active-matrix light-emitting apparatus in which transistors (FETs) 202 over a first substrate 201 are electrically connected to light-emitting devices (203R, 203G, 203B, and 203W); the light-emitting devices (203R, 203G, 203B, and 203W) include a common EL layer 204 and each have a microcavity structure in which the optical path length between electrodes of each light-emitting device is adjusted according to a desired emission color of the light-emitting device. In addition, the light-emitting apparatus is a top-emission light-emitting apparatus in which light is emitted from the EL layer 204 through color filters (206R, 206G, and 206B) formed on a second substrate 205.

In the light-emitting apparatus illustrated in FIG. 3A, a first electrode 207 is formed so as to function as a reflective electrode. A second electrode 208 is formed so as to function as a semi-transmissive and semi-reflective electrode. Note that description in any of the other embodiments can be referred to for electrode materials forming the first electrode 207 and the second electrode 208 and appropriate materials can be used.

In the case where the light-emitting device 203R is a red-light-emitting device, the light-emitting device 203G is a green-light-emitting device, the light-emitting device 203B is a blue-light-emitting device, and the light-emitting device 203W is a white-light-emitting device in FIG. 3A, for example, the gap between the first electrode 207 and the second electrode 208 in the light-emitting device 203R is adjusted to have an optical path length 200R, the gap between the first electrode 207 and the second electrode 208 in the light-emitting device 203G is adjusted to have an optical path length 200G, and the gap between the first electrode 207 and the second electrode 208 in the light-emitting device 203B is adjusted to have an optical path length 200B as illustrated in FIG. 3B. Note that optical adjustment can be performed in such a manner that a conductive layer 210R is stacked over the first electrode 207 in the light-emitting device 203R and a conductive layer 210G is stacked over the first electrode 207 in the light-emitting device 203G as illustrated in FIG. 3B.

The color filters (206R, 206G, and 206B) are formed on the second substrate 205. Note that the color filters each transmit visible light in a specific wavelength range and block visible light in a specific wavelength range. Thus, as illustrated in FIG. 3A, the color filter 206R that transmits only light in the red wavelength range is provided in a position overlapping with the light-emitting device 203R, whereby red light emission can be extracted from the light-emitting device 203R. The color filter 206G that transmits only light in the green wavelength range is provided in a position overlapping with the light-emitting device 203G, whereby green light emission can be obtained from the light-emitting device 203G. The color filter 206B that transmits only light in the blue wavelength range is provided in a position overlapping with the light-emitting device 203B, whereby blue light emission can be obtained from the light-emitting device 203B. Note that the light-emitting device 203W can emit white light without a color filter. Note that a black layer (a black matrix) 209 may be provided at an end portion of one type of color filter. The color filters (206R, 206G, and 206B) and the black layer 209 may be covered with an overcoat layer using a transparent material.

Although the light-emitting apparatus illustrated in FIG. 3A has a structure in which light is extracted from the second substrate 205 side (a top-emission structure), the light-emitting apparatus may have a structure in which light is extracted from the first substrate 201 side where the FETs 202 are formed (a bottom-emission structure) as illustrated in FIG. 3C. For a bottom-emission light-emitting apparatus, the first electrode 207 is formed so as to function as a semi-transmissive and semi-reflective electrode and the second electrode 208 is formed so as to function as a reflective electrode. As the first substrate 201, a substrate having at least a light-transmitting property is used. As illustrated in FIG. 3C, color filters (206R′, 206G′, and 206B′) are provided closer to the first substrate 201 than the light-emitting devices (203R, 203G, and 203B) are.

FIG. 3A illustrates the case where the light-emitting devices are the red-light-emitting device, the green-light-emitting device, the blue-light-emitting device, and the white-light-emitting device; however, the light-emitting devices of embodiments of the present invention are not limited to the above structures, and a yellow-light-emitting device or an orange-light-emitting device may be included. Note that description in any of the other embodiments can be referred to for materials that are used for the EL layers (a light-emitting layer, a hole-injection layer, a hole-transport layer, an electron-transport layer, an electron-injection layer, a charge-generation layer, and the like) to fabricate each of the light-emitting devices and appropriate materials can be used. In that case, a color filter needs to be appropriately selected according to the emission color of the light-emitting device.

With the above structure, a light-emitting apparatus including light-emitting devices that exhibit a plurality of emission colors can be obtained.

Note that the structures described in this embodiment can be used in an appropriate combination with any of the structures described in the other embodiments.

### Embodiment 4

In this embodiment, a light-emitting apparatus of one embodiment of the present invention is described.

The use of the device structure of the light-emitting device of one embodiment of the present invention allows fabrication of an active-matrix light-emitting apparatus or a passive-matrix light-emitting apparatus. Note that an active-matrix light-emitting apparatus has a structure including a combination of a light-emitting device and a transistor (FET). Thus, each of a passive-matrix light-emitting apparatus and an active-matrix light-emitting apparatus is included in one embodiment of the present invention. Note that any of the light-emitting devices described in the other embodiments can be used in the light-emitting apparatus described in this embodiment.

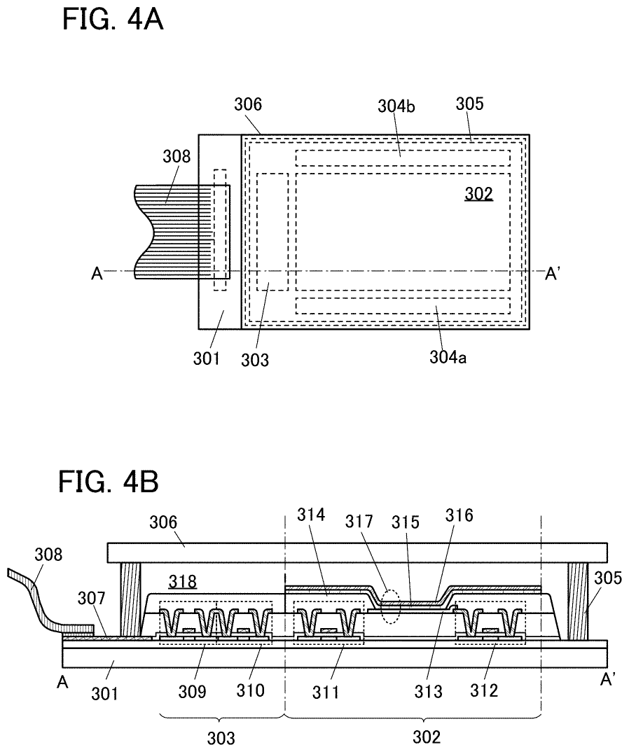

In this embodiment, an active-matrix light-emitting apparatus is described with reference to FIG. 4.

FIG. 4A is a top view illustrating a light-emitting apparatus, and FIG. 4B is a cross-sectional view taken along a chain line A-A′ in FIG. 4A. The active-matrix light-emitting apparatus includes a pixel portion 302, a driver circuit portion (source line driver circuit) 303, and driver circuit portions (gate line driver circuits) (304a and 304b) that are provided over a first substrate 301. The pixel portion 302 and the driver circuit portions (303, 304a, and 304b) are sealed between the first substrate 301 and a second substrate 306 with a sealant 305.

A lead wiring 307 is provided over the first substrate 301. The lead wiring 307 is electrically connected to an FPC 308 which is an external input terminal. Note that the FPC 308 transmits a signal (e.g., a video signal, a clock signal, a start signal, or a reset signal) or a potential from the outside to the driver circuit portions (303, 304a, and 304b). The FPC 308 may be provided with a printed wiring board (PWB). Note that the light-emitting apparatus provided with an FPC or a PWB is included in the category of a light-emitting apparatus.

Next, the cross-sectional structure is illustrated in FIG. 4B.

The pixel portion 302 is made up of a plurality of pixels each of which includes an FET (a switching FET) 311, an FET (a current control FET) 312, and a first electrode 313 electrically connected to the FET 312. Note that the number of FETs included in each pixel is not particularly limited and can be set appropriately as needed.

The driver circuit portion 303 includes the FET 309 and the FET 310. The driver circuit portion 303 may be formed with a circuit including transistors having the same conductivity type (either only n-channel transistors or only p-channel transistors) or a CMOS circuit including an n-channel transistor and a p-channel transistor. Furthermore, a structure including a driver circuit outside may be employed.

As FETs 309, 310, 311, and 312, for example, a staggered transistor or an inverted staggered transistor can be used without particular limitation. A top-gate transistor, a bottom-gate transistor, or the like may be used.

Note that there is no particular limitation on the crystallinity of a semiconductor that can be used for the FETs 309, 310, 311, and 312, and an amorphous semiconductor or a semiconductor having crystallinity (a microcrystalline semiconductor, a polycrystalline semiconductor, a single crystal semiconductor, or a semiconductor partly including crystal regions) may be used. The use of a semiconductor having crystallinity is preferable because deterioration of the transistor characteristics can be inhibited.

For these semiconductors, a Group 14 element, a compound semiconductor, an oxide semiconductor, an organic semiconductor, or the like can be used, for example. Typically, a semiconductor containing silicon, a semiconductor containing gallium arsenide, an oxide semiconductor containing indium, or the like can be used.

An end portion of the first electrode 313 is covered with an insulator 314. For the insulator 314, an organic compound such as a negative photosensitive resin or a positive photosensitive resin (an acrylic resin), or an inorganic compound such as silicon oxide, silicon oxynitride, or silicon nitride can be used. An upper end portion or a lower end portion of the insulator 314 preferably has a curved surface with curvature. In that case, favorable coverage with a film formed over the insulator 314 can be obtained.

An EL layer 315 and a second electrode 316 are stacked over the first electrode 313. The EL layer 315 includes a light-emitting layer, a hole-injection layer, a hole-transport layer, an electron-transport layer, an electron-injection layer, a charge-generation layer, and the like.

The structure and materials described in any of the other embodiments can be used for the structure of a light-emitting device 317 described in this embodiment. Although not illustrated here, the second electrode 316 is electrically connected to the FPC 308 which is an external input terminal.

Although the cross-sectional view in FIG. 4B illustrates only one light-emitting device 317, a plurality of light-emitting devices are arranged in a matrix in the pixel portion 302. Light-emitting devices from which light of three kinds of colors (R, G, and B) is obtained are selectively formed in the pixel portion 302, whereby a light-emitting apparatus capable of full-color display can be formed. In addition to the light-emitting devices from which light of three kinds of colors (R, G, and B) is obtained, for example, light-emitting devices from which light of white (W), yellow (Y), magenta (M), cyan (C), and the like is obtained may be formed. For example, the light-emitting devices from which light of some of the above colors is obtained are added to the light-emitting devices from which light of three kinds of colors (R, G, and B) is obtained, whereby effects such as an improvement in color purity and a reduction in power consumption can be obtained. Alternatively, a light-emitting apparatus that is capable of full-color display may be fabricated by a combination with color filters. As the kinds of color filters, red (R), green (G), blue (B), cyan (C), magenta (M), and yellow (Y) color filters and the like can be used.

When the second substrate 306 and the first substrate 301 are bonded to each other with the sealant 305, the FETs (309, 310, 311, and 312) and the light-emitting device 317 over the first substrate 301 are provided in a space 318 surrounded by the first substrate 301, the second substrate 306, and the sealant 305. Note that the space 318 may be filled with an inert gas (e.g., nitrogen or argon) or an organic substance (including the sealant 305).

An epoxy resin or glass frit can be used for the sealant 305. It is preferable to use a material that is permeable to as little moisture and oxygen as possible for the sealant 305. For the second substrate 306, a material that can be used for the first substrate 301 can be similarly used. Thus, any of the various substrates described in the other embodiments can be appropriately used. As the substrate, a glass substrate, a quartz substrate, or a plastic substrate made of FRP (Fiber-Reinforced Plastics), PVF (polyvinyl fluoride), polyester, an acrylic resin, or the like can be used. In the case where glass frit is used for the sealant, the first substrate 301 and the second substrate 306 are preferably glass substrates in terms of adhesion.

In the above manner, the active-matrix light-emitting apparatus can be obtained.

In the case where the active-matrix light-emitting apparatus is formed over a flexible substrate, the FETs and the light-emitting device may be directly formed over the flexible substrate; alternatively, the FETs and the light-emitting device may be formed over a substrate provided with a separation layer and then separated at the separation layer by application of heat, force, laser irradiation, or the like to be transferred to a flexible substrate. For the separation layer, a stack of inorganic films such as a tungsten film and a silicon oxide film, or an organic resin film of polyimide or the like can be used, for example. Examples of the flexible substrate include, in addition to a substrate over which a transistor can be formed, a paper substrate, a cellophane substrate, an aramid film substrate, a polyimide film substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, high durability, high heat resistance, a reduction in weight, and a reduction in thickness can be achieved.

The light-emitting device included in the active-matrix light-emitting apparatus may be driven to emit light in a pulsed manner (using a frequency of kHz or MHz, for example) so that the light is used for display. The light-emitting device formed using any of the above organic compounds has excellent frequency characteristics; thus, the time for driving the light-emitting device can be shortened, and the power consumption can be reduced. Furthermore, a reduction in driving time leads to inhibition of heat generation, so that the degree of deterioration of the light-emitting device can be reduced.

Note that the structures described in this embodiment can be used in an appropriate combination with the structures described in the other embodiments.

### Embodiment 5

In this embodiment, examples of a variety of electronic devices and an automobile completed using the light-emitting device of one embodiment of the present invention or a light-emitting apparatus including the light-emitting device of one embodiment of the present invention will be described. Note that the light-emitting apparatus can be used mainly in a display portion of the electronic device described in this embodiment.

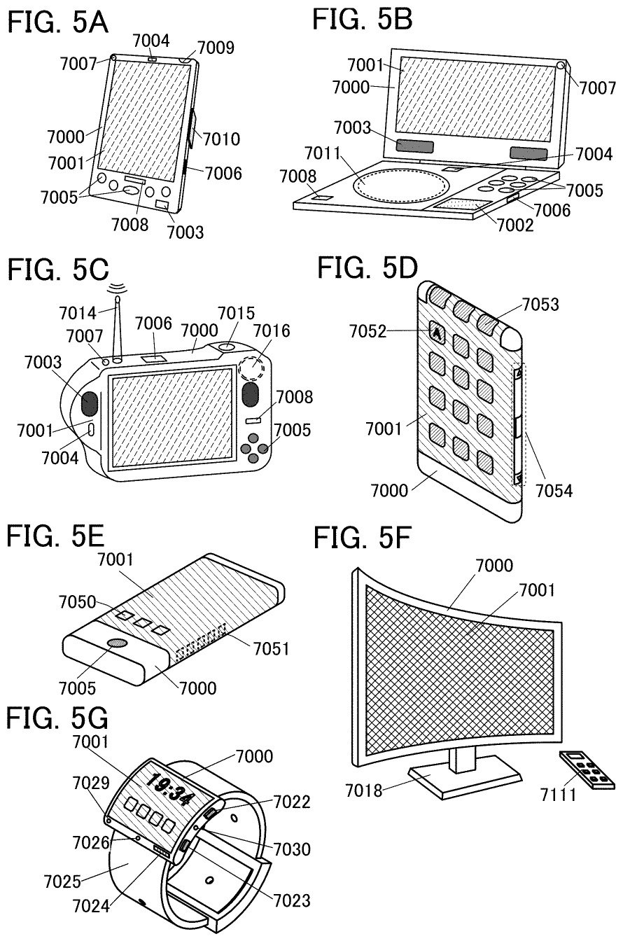

Electronic devices illustrated in FIG. 5A to FIG. 5E can include a housing 7000, a display portion 7001, a speaker 7003, an LED lamp 7004, operation keys 7005 (including a power switch or an operation switch), a connection terminal 7006, a sensor 7007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 7008, and the like.

FIG. 5A is a mobile computer which can include a switch 7009, an infrared port 7010, and the like in addition to the above components.

FIG. 5B is a portable image reproducing device (e.g., a DVD player) which is provided with a recording medium and can include a second display portion 7002, a recording medium reading portion 7011, and the like in addition to the above components.

FIG. 5C is a digital camera with a television reception function, which can include an antenna 7014, a shutter button 7015, an image receiving portion 7016, and the like in addition to the above components.

FIG. 5D is a portable information terminal. The portable information terminal has a function of displaying information on three or more surfaces of the display portion 7001. Here, an example in which information 7052, information 7053, and information 7054 are displayed on different surfaces is shown. For example, the user can check the information 7053 displayed in a position that can be observed from above the portable information terminal, with the portable information terminal put in a breast pocket of his/her clothes. The user can see the display without taking out the portable information terminal from the pocket and decide whether to answer the call, for example.

FIG. 5E is a portable information terminal (e.g., a smartphone), which can include the display portion 7001, the operation key 7005, and the like in the housing 7000. Note that a speaker, the connection terminal 7006, a sensor, or the like may be provided in the portable information terminal. The portable information terminal can display characters and image information on its plurality of surfaces. Here, an example in which three icons 7050 are displayed is shown. Information 7051 indicated by dashed rectangles can be displayed on another surface of the display portion 7001. Examples of the information 7051 include notification of reception of an e-mail, SNS, or an incoming call, the title and sender of an e-mail, SNS, or the like, the date, the time, remaining battery, and the reception strength of an antenna. Alternatively, the icon 7050 or the like may be displayed in the position where the information 7051 is displayed.

FIG. 5F is a large-size television set (also referred to as TV or television receiver), which can include the housing 7000, the display portion 7001, and the like. Here, a structure where the housing 7000 is supported by a stand 7018 is shown. The television set can be operated with a separate remote controller 7111 or the like. Note that the display portion 7001 may include a touch sensor, in which case the television set may be operated by touch on the display portion 7001 with a finger or the like. The remote controller 7111 may be provided with a display portion for displaying information output from the remote controller 7111. With operation keys or a touch panel provided in the remote controller 7111, channels and volume can be operated and images displayed on the display portion 7001 can be operated.

The electronic devices illustrated in FIG. 5A to FIG. 5F can have a variety of functions. For example, they can have a function of displaying a variety of information (e.g., a still image, a moving image, and a text image) on the display portion, a touch panel function, a function of displaying a calendar, date, time, or the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion. Furthermore, the electronic device including a plurality of display portions can have a function of displaying image information mainly on one display portion while displaying text information mainly on another display portion, a function of displaying a three-dimensional image by displaying images on a plurality of display portions with a parallax taken into account, or the like. Furthermore, the electronic device including an image receiving portion can have a function of taking a still image, a function of taking a moving image, a function of automatically or manually correcting a taken image, a function of storing a taken image in a recording medium (an external recording medium or a recording medium incorporated in the camera), a function of displaying a taken image on the display portion, or the like. Note that functions that the electronic devices illustrated in FIG. 5A to FIG. 5F can have are not limited to those, and the electronic devices can have a variety of functions.

FIG. 5G is a watch-type portable information terminal, which can be used as a smart watch, for example. The watch-type portable information terminal includes the housing 7000, the display portion 7001, operation buttons 7022 and 7023, a connection terminal 7024, a band 7025, a microphone 7026, a sensor 7029, a speaker 7030, and the like. The display surface of the display portion 7001 is bent, and display can be performed along the bent display surface. The portable information terminal enables hands-free calling by mutually communicating with, for example, a headset capable of wireless communication. With the connection terminal 7024, the portable information terminal can perform mutual data transmission with another information terminal and can be charged. Wireless power feeding can also be employed for the charging operation.

The display portion 7001 mounted in the housing 7000 also serving as a bezel includes a non-rectangular display region. The display portion 7001 can display an icon indicating time, another icon, and the like. The display portion 7001 may be a touch panel (input/output device) including a touch sensor (an input device).

Note that the smart watch illustrated in FIG. 5G can have a variety of functions. For example, the smart watch can have a function of displaying a variety of information (e.g., a still image, a moving image, and a text image) on the display portion, a touch panel function, a function of displaying a calendar, date, time, or the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion.

Moreover, a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like can be included inside the housing 7000.

Note that the light-emitting apparatus of one embodiment of the present invention can be used in the display portions of the electronic devices described in this embodiment, enabling the electronic devices to have a long lifetime.

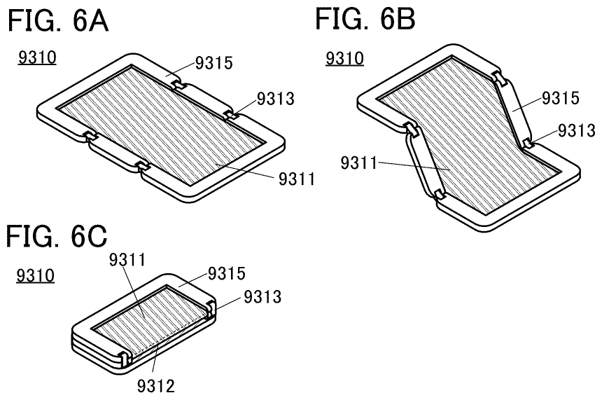

Another electronic device including the light-emitting apparatus is a foldable portable information terminal illustrated in FIG. 6A to FIG. 6C. FIG. 6A illustrates a portable information terminal 9310 which is opened. FIG. 6B illustrates the portable information terminal 9310 in a state in the middle of change from one of an opened state and a folded state to the other. FIG. 6C illustrates the portable information terminal 9310 which is folded. The portable information terminal 9310 is excellent in portability when folded, and is excellent in display browsability when opened because of a seamless large display region.

A display portion 9311 is supported by three housings 9315 joined together by hinges 9313. Note that the display portion 9311 may be a touch panel (an input/output device) including a touch sensor (an input device). By bending the display portion 9311 at a portion between two housings 9315 with the use of the hinges 9313, the portable information terminal 9310 can be reversibly changed in shape from an opened state to a folded state. The light-emitting apparatus of one embodiment of the present invention can be used in the display portion 9311. An electronic device having a long lifetime can be provided. A display region 9312 in the display portion 9311 is a display region that is positioned at a side surface of the portable information terminal 9310 which is folded. On the display region 9312, information icons, file shortcuts of frequently used applications or programs, and the like can be displayed, which allows confirmation of information and start of an application to be smoothly performed.

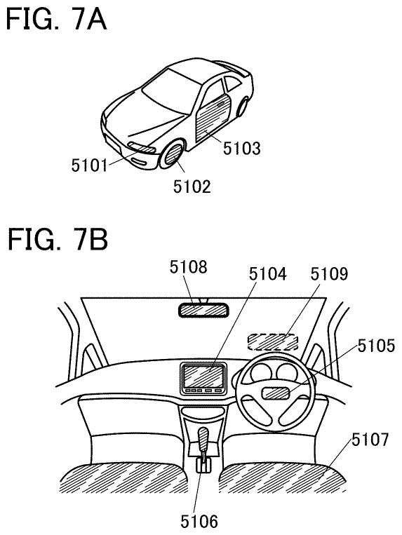

FIG. 7A and FIG. 7B illustrate an automobile including the light-emitting apparatus. In other words, the light-emitting apparatus can be integrated into an automobile. Specifically, the light-emitting apparatus can be used for lights 5101 (including lights of the rear part of the car), a wheel 5102, a part or the whole of a door 5103, or the like on the outer side of the automobile illustrated in FIG. 7A. The light-emitting apparatus can also be used for a display portion 5104, a steering wheel 5105, a shifter 5106, a seat 5107, an inner rearview mirror 5108, a windshield 5109, or the like on the inner side of the automobile illustrated in FIG. 7B. The light-emitting apparatus may be used for part of any of the other glass windows.

In the above manner, the electronic devices and automobiles each including the light-emitting apparatus of one embodiment of the present invention can be obtained. In that case, a long-lifetime electronic device can be obtained. Note that the light-emitting apparatus can be used for electronic devices and automobiles in a variety of fields without being limited to those described in this embodiment.

Note that the structures described in this embodiment can be used in an appropriate combination with any of the structures described in the other embodiments.

### Embodiment 6

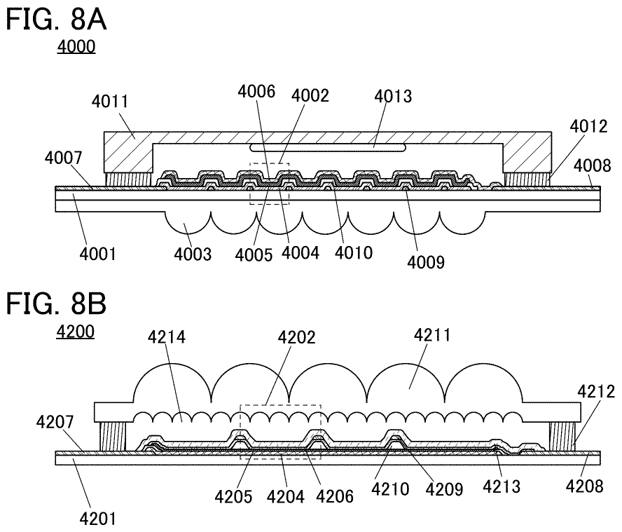

In this embodiment, structures of a lighting device fabricated using the light-emitting apparatus of one embodiment of the present invention or the light-emitting device which is part of the light-emitting apparatus will be described with reference to FIG. 8.

FIG. 8A and FIG. 8B each illustrate an example of a cross-sectional view of a lighting device. FIG. 8A is a bottom-emission lighting device in which light is extracted from the substrate side, and FIG. 8B is a top-emission lighting device in which light is extracted from the sealing substrate side.

A lighting device 4000 illustrated in FIG. 8A includes a light-emitting device 4002 over a substrate 4001. In addition, the lighting device 4000 includes a substrate 4003 with unevenness on the outside of the substrate 4001. The light-emitting device 4002 includes a first electrode 4004, an EL layer 4005, and a second electrode 4006.

The first electrode 4004 is electrically connected to an electrode 4007, and the second electrode 4006 is electrically connected to an electrode 4008. In addition, an auxiliary wiring 4009 electrically connected to the first electrode 4004 may be provided. Note that an insulating layer 4010 is formed over the auxiliary wiring 4009.

The substrate 4001 and a sealing substrate 4011 are bonded to each other with a sealant 4012. A desiccant 4013 is preferably provided between the sealing substrate 4011 and the light-emitting device 4002. Since the substrate 4003 has the unevenness shown in FIG. 8A, the extraction efficiency of light generated in the light-emitting device 4002 can be increased.

A lighting device 4200 in FIG. 8B includes a light-emitting device 4202 over a substrate 4201. The light-emitting device 4202 includes a first electrode 4204, an EL layer 4205, and a second electrode 4206.

The first electrode 4204 is electrically connected to an electrode 4207, and the second electrode 4206 is electrically connected to an electrode 4208. An auxiliary wiring 4209 electrically connected to the second electrode 4206 may also be provided. In addition, an insulating layer 4210 may be provided under the auxiliary wiring 4209.

The substrate 4201 and a sealing substrate 4211 with unevenness are bonded to each other with a sealant 4212. A barrier film 4213 and a planarization film 4214 may be provided between the sealing substrate 4211 and the light-emitting device 4202. Since the sealing substrate 4211 has the unevenness shown in FIG. 8B, the extraction efficiency of light generated in the light-emitting device 4202 can be increased.

Application examples of such lighting devices include a ceiling light for indoor lighting. Examples of the ceiling light include a ceiling direct mount light and a ceiling embedded light. Such a lighting device is fabricated using the light-emitting apparatus and a housing or a cover in combination.

As another example, such lighting devices can be used for a foot light that illuminates a floor so that safety on the floor can be improved. For example, the foot light can be effectively used in a bedroom, on a staircase, or on a passage. In that case, the size or shape of the foot light can be changed depending on the area or structure of a room. A stationary lighting device can also be fabricated using the light-emitting apparatus and a support base in combination.

Such lighting devices can also be used for a sheet-like lighting device (sheet-like lighting). The sheet-like lighting, which is attached to a wall when used, is space-saving and thus can be used for a wide variety of applications. Furthermore, the area of the sheet-like lighting can be easily increased. The sheet-like lighting can also be used on a wall or housing having a curved surface.

Besides the above examples, the light-emitting apparatus of one embodiment of the present invention or the light-emitting device which is part of the light-emitting apparatus can be used as part of furniture in a room, so that a lighting device which has a function of the furniture can be obtained.

As described above, a variety of lighting devices that include the light-emitting apparatus can be obtained. Note that these lighting devices are also embodiments of the present invention.

The structures described in this embodiment can be used in an appropriate combination with the structures described in the other embodiments.

### Example 1

In this example, a light-emitting device 1 was fabricated using, for a light-emitting layer 913 of an EL layer 902, a material contained in the composition for a light-emitting device (also referred to as a premixed material) of one embodiment of the present invention. Specifically, the light-emitting device 1 was fabricated using, for the light-emitting layer 913 of the EL layer 902, 8BP-4mDBtPBfpm (Structural Formula (100)), which is a first organic compound having a benzofuropyrimidine skeleton, and PNCCmBP (Structural Formula (201)), which is a second organic compound having a bicarbazole skeleton. As a comparative light-emitting device fabricated without consideration of element fabrication using the composition for a light-emitting device, a comparative light-emitting device 2 was fabricated for comparison using βNCCP as the second organic compound instead of PNCCmBP in the light-emitting device 1.

In this example, the light-emitting layer 913 of the light-emitting device 1 was formed by co-evaporation of the first organic compound (8BP-4mDBtPBfpm), the second organic compound (ONCCmBP), and a light-emitting substance; and the light-emitting layer 913 of the comparative light-emitting device 2 was formed by co-evaporation of the first organic compound (8BP-4mDBtPBfpm), the second organic compound (βNCCP), and a light-emitting substance.

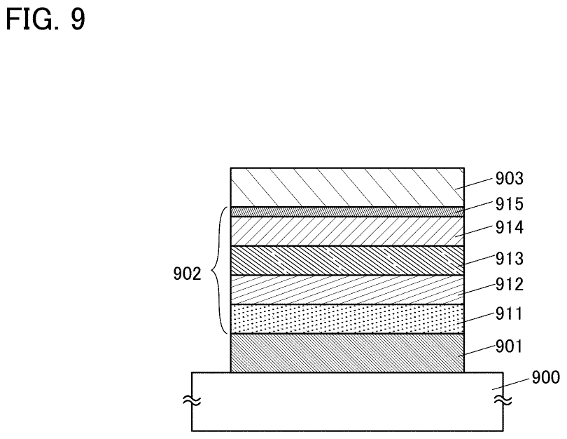

Specific device structures and fabrication methods of the light-emitting devices used in this example are described below. Note that FIG. 9 illustrates the device structure of the light-emitting devices described in this example, and Table 1 shows specific compositions. The chemical formulae of the materials used in this example are shown below.

TABLE 1

| | | | | Ligin- | | | Electron- | |
|---|---|---|---|---|---|---|---|---|
| | First | Hole-injection | Hole-transport | emitting | Electron-transport | | injection | Second |
| | electrode | layer | layer | layer | layer | | layer | electrode |
| | 901 | 911 | 912 | 913 | 914 | | 915 | 903 |
| Light-emitting | ITSO | DBT3P-II:MoOx | PCBBilBP | * | 8BP-4mDBtPBfpm | NBphen | LiF | Al |
| device 1 | (70 nm) | (2:1 45 nm) | (20 nm) | | (20 nm) | (10 nm) | (1 nm) | (200 nm) |
| Comparative | ITSO | DBT3P-II:MoOx | PCBBilBP | ** | 8BP-4mDBtPBfpm | NBphen | LiF | Al |
| light-emitting | (70 nm) | (2:1 45 nm) | (20 nm) | | (20 nm) | (10 nm) | (1 nm) | (200 nm) |
| device 2 | | | | | | | | |

* 8BP-4mDBtPBfpm:βNCCmBP:[Ir(ppy)₂(mbfpypy-d3)] (0.6:0.4:0.1 50 nm)
** 8BP-4mDBtPBfpm:βNCCP:[Ir(ppy)₂(mbfpypy-d3)] (0.6:0.4:0.1 50 nm)

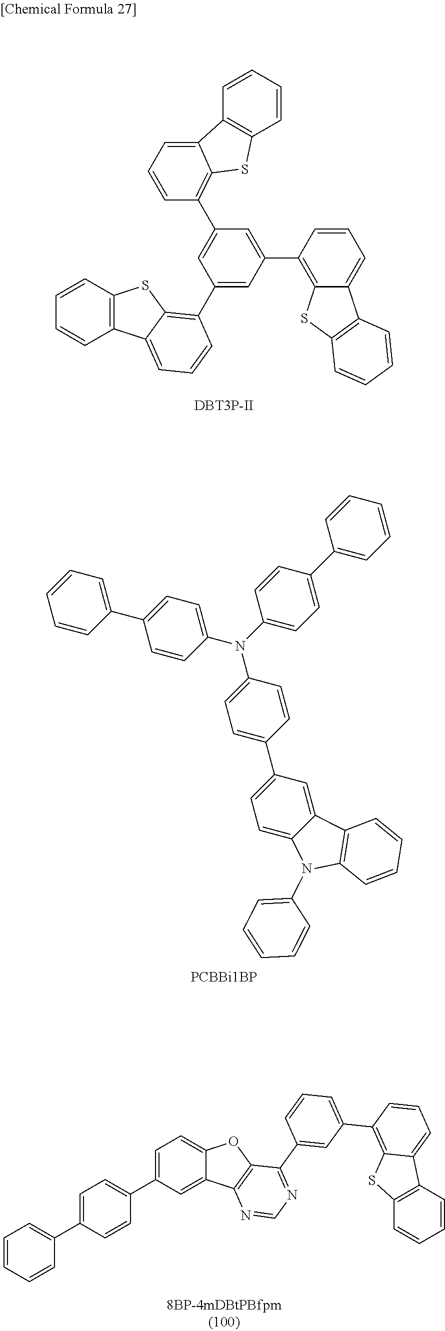

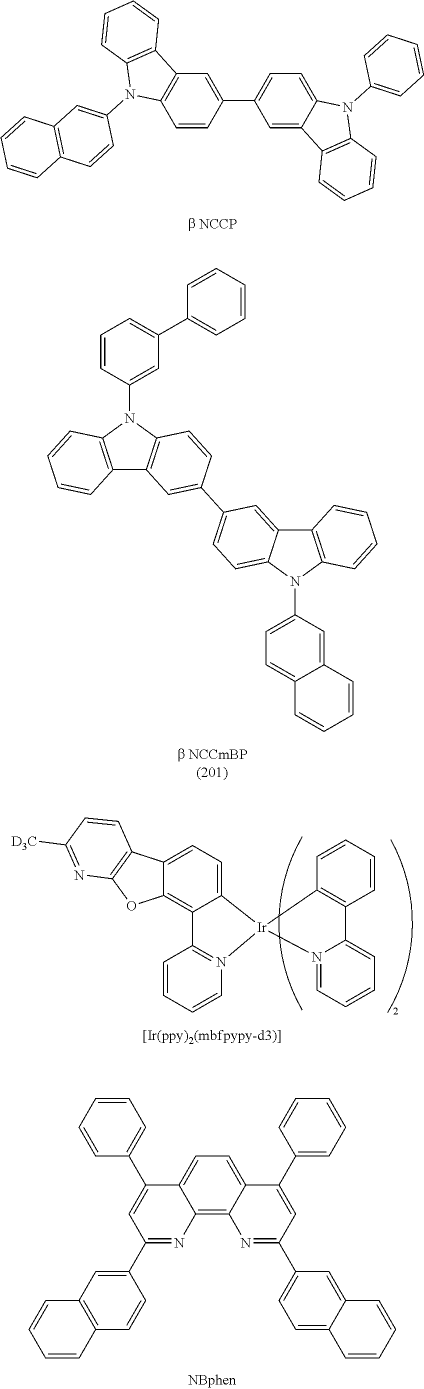

### <<Fabrication of Light-Emitting Devices>>

The light-emitting devices described in this example each have a structure illustrated in FIG. 9, in which a hole-injection layer 911, a hole-transport layer 912, a light-emitting layer 913, an electron-transport layer 914, and an electron-injection layer 915 are stacked in this order over a first electrode 901 formed over a substrate 900, and a second electrode 903 is stacked over the electron-injection layer 915.

First, the first electrode 901 was formed over the substrate 900. The electrode area was set to 4 mm² (2 mm×2 mm). A glass substrate was used as the substrate 900. The first electrode 901 was formed to a thickness of 70 nm using indium tin oxide containing silicon oxide (ITSO) by a sputtering method.

As pretreatment, a surface of the substrate was washed with water, baking was performed at 200° C. for one hour, and then UV ozone treatment was performed for 370 seconds. After that, the substrate was transferred into a vacuum evaporation apparatus in which the pressure was reduced to approximately 10⁻⁴ Pa, vacuum baking at 170° C. for 30 minutes was performed in a heating chamber in the vacuum evaporation apparatus, and then the substrate was cooled down for approximately 30 minutes.

Next, the hole-injection layer 911 was formed over the first electrode 901. After the pressure in the vacuum evaporation apparatus was reduced to 10⁻⁴ Pa, the hole-injection layer 911 was formed by co-evaporation so that DBT3P-II: molybdenum oxide=2:1 (mass ratio) and a thickness is 45 nm.

Then, the hole-transport layer 912 was formed over the hole-injection layer 911. The hole-transport layer 912 was formed to a thickness of 20 nm by evaporation of PCBBi1BP.

Next, the light-emitting layer 913 was formed over the hole-transport layer 912.

For the light-emitting layer 913 of the light-emitting device 1, 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm) and 9-(3-biphenyl)-9′-(2-naphthyl)-3,3′-bi-9H-carbazole (abbreviation: βNCCmBP) were used as host materials, and [2-d3-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d3)]) was used as a guest material. These materials were put in different evaporation sources (or evaporation boats) and co-evaporated so that the weight ratio was 8BP-4mDBtPBfpm: βNCCmBP:[Ir(ppy)₂(mbfpypy-d3)]=0.6:0.4::0.1. Note that the thickness was set to 50 nm.

For the comparative light-emitting device 2, 8BP-4mDtPBfpm and 9-(2-naphthyl)-9′-phenyl-9H,9′H-3,3′-bicarbazole (abbreviation: βNCCP) were used as host materials, and [Ir(ppy)₂(mbfpypy-d3)] was used as a guest material (a phosphorescent substance). These materials were put in different evaporation sources and co-evaporated so that the weight ratio was 8BP-4mDtPBfpm:βNCCP:[Ir(ppy)₂(mbfpypy-d3)]=0.6:0.4::0.1. Note that the thickness was set to 50 nm.

Next, the electron-transport layer 914 was formed over the light-emitting layer 913.

To form the electron-transport layer 914, 8BP-4mDtPBfpm and NBphen were sequentially deposited by evaporation to a thickness of 20 nm and a thickness of 10 nm, respectively.

Then, the electron-injection layer 915 was formed over the electron-transport layer 914. The electron-injection layer 915 was formed to a thickness of 1 nm by evaporation using lithium fluoride (LiF).

Next, the second electrode 903 was formed over the electron-injection layer 915. The second electrode 903 was formed to a thickness of 200 nm by an evaporation method using aluminum. In this example, the second electrode 903 functions as a cathode.

Through the above steps, the light-emitting devices in each of which an EL layer was provided between the pair of electrodes over the substrate 900 were formed. The hole-injection layer 911, the hole-transport layer 912, the light-emitting layer 913, the electron-transport layer 914, and the electron-injection layer 915 described in the above steps are functional layers forming the EL layer in one embodiment of the present invention. Furthermore, in all the evaporation steps in the above fabrication method, an evaporation method by a resistance-heating method was used.

The light-emitting devices fabricated as described above were each sealed using a different substrate (not illustrated). At the time of the sealing using the different substrate (not illustrated), the different substrate (not illustrated) coated with a sealant that solidifies by ultraviolet light was fixed onto the substrate 900 in a glove box containing a nitrogen atmosphere, and the substrates were bonded to each other such that the sealant would be attached to the periphery of the light-emitting device formed over the substrate 900. At the time of the sealing, the sealant was irradiated with 365-nm ultraviolet light at 6 J/cm² to be solidified, and the sealant was subjected to heat treatment at 80° C. for one hour to be stabilized.

### <<Operation Characteristics of Light-Emitting Devices>>

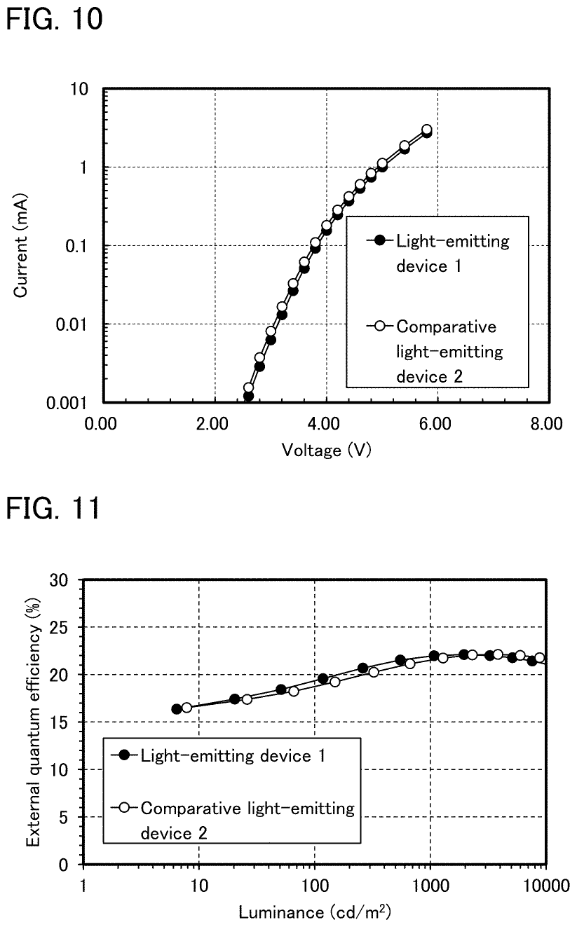

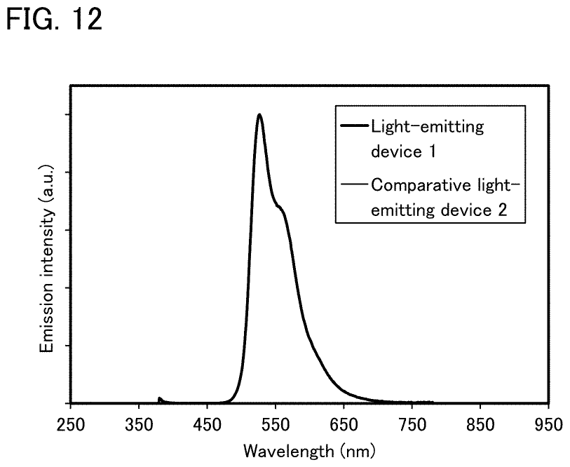

Measurement results of operation characteristics of the fabricated light-emitting devices are shown. Note that the measurement was carried out at room temperature (an atmosphere maintained at 25° C.). Luminance and CIE chromaticity were measured with a luminance colorimeter (BM-5A manufactured by TOPCON TECHNOHOUSE CORPORATION), and electroluminescence spectra were measured with a multi-channel spectrometer (PMA-11 manufactured by Hamamatsu Photonics K.K.). As the results of the operation characteristics of the light-emitting device 1 and the comparative light-emitting device 2, the voltage-current characteristics are shown in FIG. 10, and the luminance-external quantum efficiency characteristics are shown in FIG. 11.

Table 2 below shows the initial values of the main characteristics of the light-emitting devices at around 1000 cd/m².

TABLE 2

| | | | Current | | | Current | Power | External |
|---|---|---|---|---|---|---|---|---|
| | Voltage | Current | density | Chromaticity | Luminance | efficiency | efficiency | quantum |
| | (V) | (mA) | (mA/cm²) | (x, y) | (cd/m²) | (cd/A) | (lm/W) | efficiency (%) |
| Light-emitting | 3.6 | 0.051 | 1.3 | (0.35, 0.62) | 1100 | 84 | 74 | 22 |
| device 1 | | | | | | | | |
| Comparative | 3.6 | 0.062 | 1.5 | (0.34, 0.63) | 1300 | 84 | 73 | 22 |
| light-emitting | | | | | | | | |
| device 2 | | | | | | | | |

The above results show that the light-emitting device 1 using as the host materials of the light-emitting layer 8BP-4mDBtPBfpm and PNCCmBP, which are contained in the composition for a light-emitting device of one embodiment of the present invention, exhibits favorable initial characteristics comparable to those of the comparative light-emitting device 2.

FIG. 12 shows the emission spectra of the light-emitting devices to which current flows at a current density of 2.5 mA/cm².

The emission spectra shown in FIG. 12 have peaks at around 526 nm, and it is suggested that the peaks are derived from light emission of [Ir(ppy)₂(mbfpypy-d3)] contained in the light-emitting layers 913 of the light-emitting device 1 and the comparative light-emitting device 2.

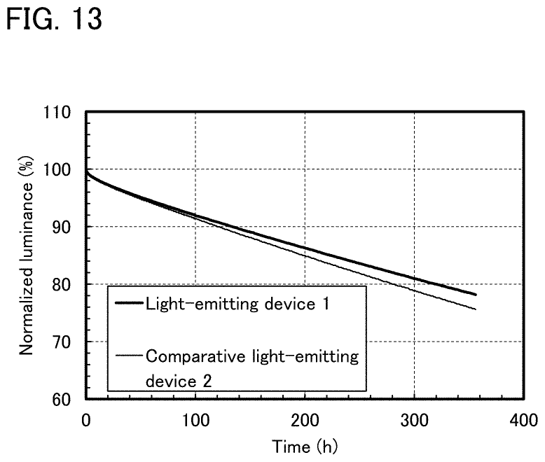

Next, a reliability test was performed on each light-emitting device. FIG. 13 shows the results of the reliability test of the light-emitting device 1 and the comparative light-emitting device 2. In the graph showing reliability, the vertical axis represents normalized luminance (%) with an initial luminance of 100%, and the horizontal axis represents device driving time (h). As the reliability test, a driving test at a constant current density of 50 mA/cm² was performed on the light-emitting device 1 and the comparative light-emitting device 2.

The above results indicate the following: the light-emitting device 1, which uses for the light-emitting layer 913 of the EL layer 902 the material contained in the composition for a light-emitting device (the premixed material) of one embodiment of the present invention, exhibits the operation characteristics comparable to those of the comparative light-emitting device 2; as for the reliability, the normalized luminance at 350 h is approximately 79% in the light-emitting device 1 but approximately 76% in the comparative light-emitting device 2, that is, the light-emitting device 1 has a longer lifetime than the comparative light-emitting device 2.

In other words, this example suggests that with the use of the materials contained in the composition for a light-emitting device (the premixed material) of one embodiment of the present invention for the light-emitting layer, a highly reliable and productive light-emitting device can be fabricated while the device characteristics of the conventional light-emitting device are maintained.

### Example 2

In this example, a light-emitting device 3 was fabricated using, for the light-emitting layer 913 of the EL layer 902, a material contained in the composition for a light-emitting device (also referred to as a premixed material) of one embodiment of the present invention. Specifically, the light-emitting device 3 was fabricated using, for the light-emitting layer 913 of the EL layer 902, 8BP-4mDBtPBfpm (Structural Formula (100)), which is a first organic compound having a benzofuropyrimidine skeleton, and βNCCBP (Structural Formula (202)), which is a second organic compound having a bicarbazole skeleton. As a comparative light-emitting device fabricated without consideration of element fabrication using the composition for a light-emitting device, a comparative light-emitting device 4 and a comparative light-emitting device 5 were fabricated for comparison using αNCCBP and βNCCP, respectively, as the second organic compound instead of βNCCBP in the light-emitting device 3.

In this example, the light-emitting layer 913 of the light-emitting device 3 was formed by co-evaporation of the first organic compound (8BP-4mDBtPBfpm), the second organic compound (βNCCBP), and a light-emitting substance; the light-emitting layer 913 of the comparative light-emitting device 4 was formed by co-evaporation of the composition for a light-emitting device (containing the first organic compound: 8BP-4mDBtPBfpm, and the second organic compound: αNCCBP) and a light-emitting substance; and the light-emitting layer 913 of the comparative light-emitting device 5 was formed by co-evaporation of the first organic compound (8BP-4mDBtPBfpm), the second organic compound (βNCCP), and a light-emitting substance.

Table 3 shows specific device structures of the light-emitting devices used in this example. The chemical formulae of the materials used in this example are shown below. Note that the device structures and fabrication methods of the light-emitting devices are similar to those in Example 1; thus, FIG. 9 is referred to also in this example.

TABLE 3

| | | | | Light- | | | Electron- | |
|---|---|---|---|---|---|---|---|---|
| | First | Hole-injection | Hole-transport | emitting | Electon-transport | | injection | Second |
| | electrode | layer | layer | layer | layer | | layer | electrode |
| | 901 | 911 | 912 | 913 | 914 | | 915 | 903 |
| Light-emitting | ITSO | DBT3P-II:MoOx | PCBBilBP | * | 8BP-4mDBtPBfpm | NBphen | LiF | Al |
| device 3 | (70 nm) | (2:1 45 nm) | (20 nm) | | (20 nm) | (10 nm) | (1 nm) | (200 nm) |
| Comparative | ITSO | DBT3P-II:MoOx | PCBBilBP | ** | 8BP-4mDBtPBfpm | NBphen | LiF | Al |
| light-emitting | (70 nm) | (2:1 45 nm) | (20 nm) | | (20 nm) | (10 nm) | (1 nm) | (200 nm) |
| device 4 | | | | | | | | |
| Comparative | ITSO | DBT3P-II:MoOx | PCBBilBP | *** | 8BP-4mDBtPBfpm | NBphen | LiF | Al |
| light-emitting | (70 nm) | (2:1 45 nm) | (20 nm) | | (20 nm) | (10 nm) | (1 nm) | (200 nm) |
| device 5 | | | | | | | | |

* 8BP-4mDBtPBfpm:βNCCBP:[Ir(ppy)₂(mbfpypy-d3)] (0.6:0.4:0.1 50 nm)
** 8BP-4mDBtPBfpm:αNCCBP:[Ir(ppy)₂(mbfpypy-d3)] (0.6:0.4:0.1 50 nm)
*** 8BP-4mDBtPBfpm:βNCCP:[Ir(ppy)₂(mbfpypy-d3)] (0.6:0.4:0.1 50 nm)

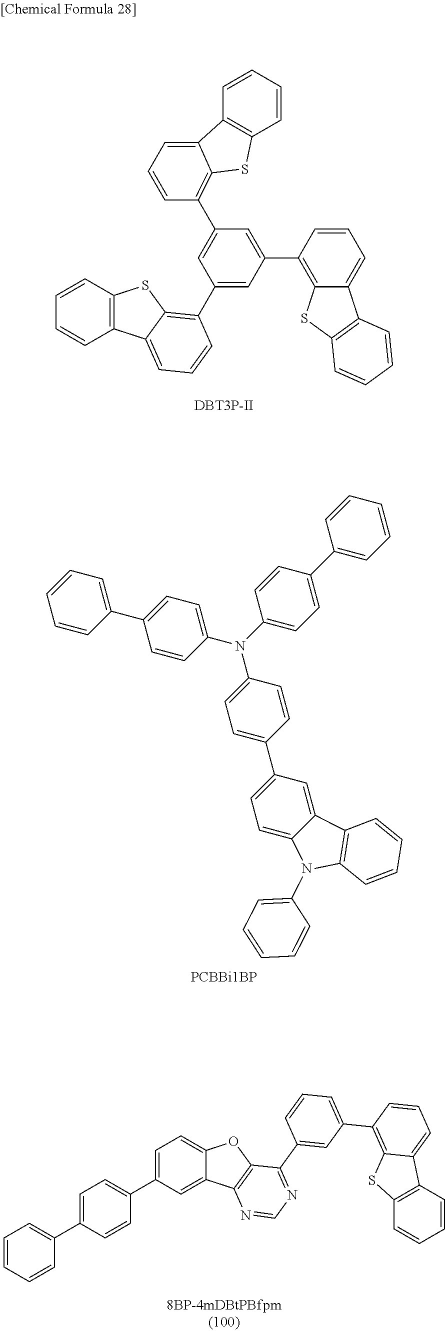

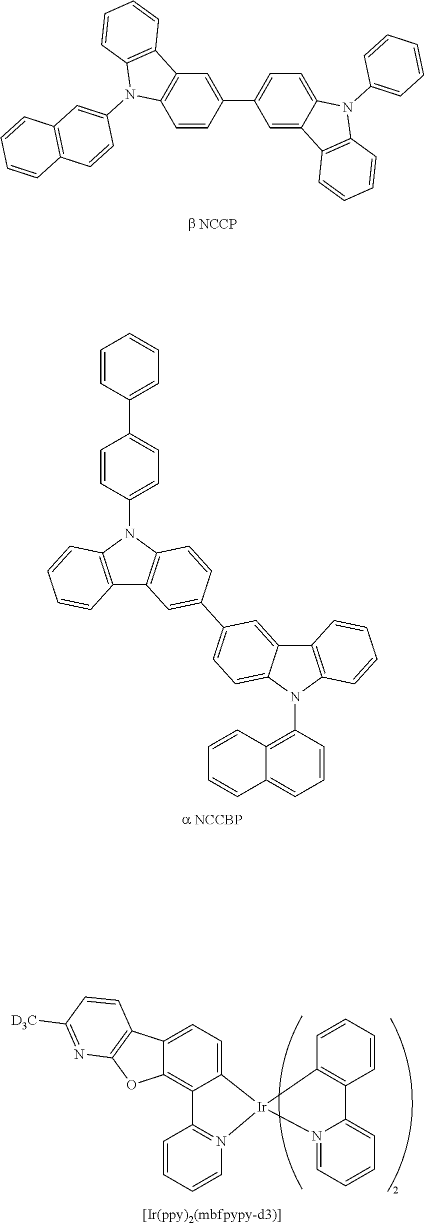

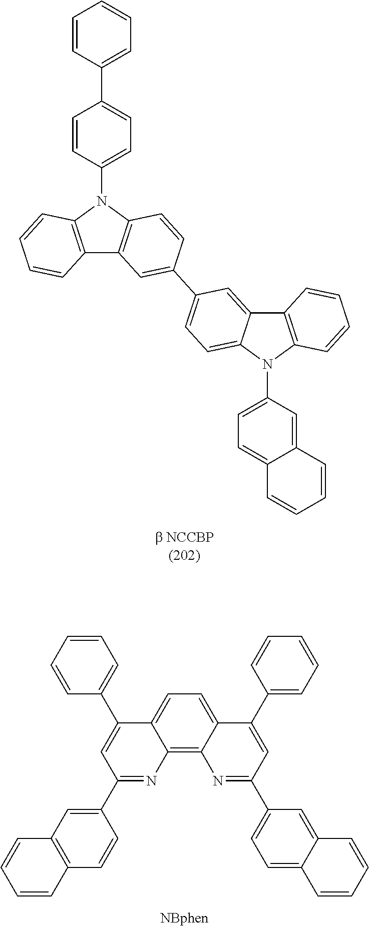 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2cc(-c3ccc4ccccc4c3)nc3c2ccc2c(-c4ccccc4)cc(-c4ccc5ccccc5c4)nc23)cc1]

### <<Operation Characteristics of Light-Emitting Devices>>

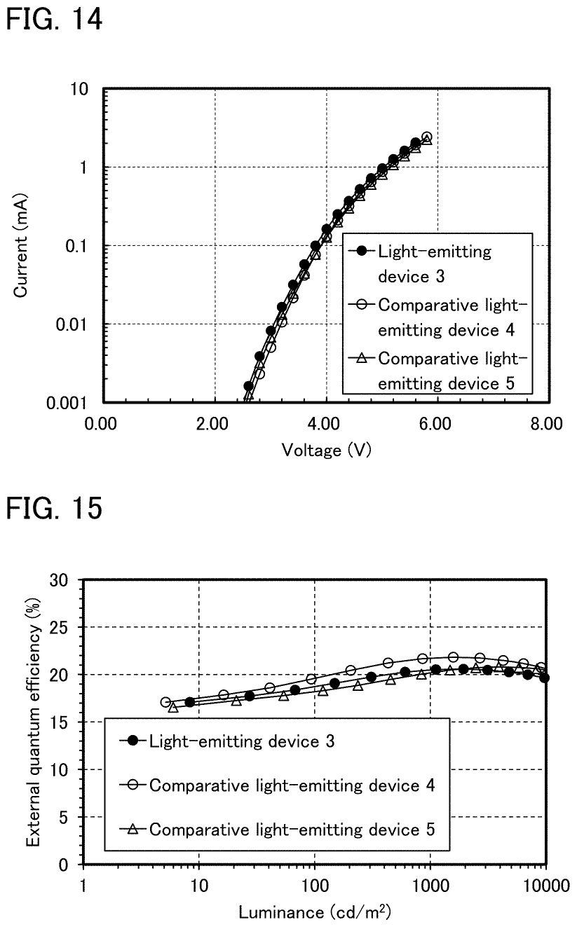

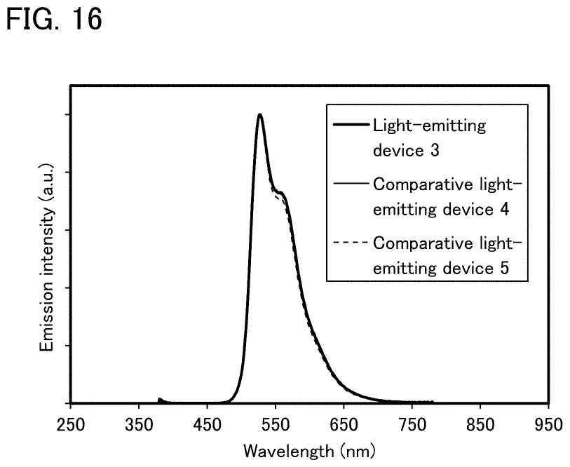

Measurement results of operation characteristics of the fabricated light-emitting devices are shown. Note that the measurement was carried out at room temperature (an atmosphere maintained at 25° C.). Luminance and CIE chromaticity were measured with a luminance colorimeter (BM-5A manufactured by TOPCON TECHNOHOUSE CORPORATION), and electroluminescence spectra were measured with a multi-channel spectrometer (PMA-11 manufactured by Hamamatsu Photonics K.K.). As the results of the operation characteristics of the light-emitting device 3, the comparative light-emitting device 4, and the comparative light-emitting device 5, the voltage-current characteristics are shown in FIG. 14, and the luminance-external quantum efficiency characteristics are shown in FIG. 15.

Table 4 below shows the initial values of the main characteristics of the light-emitting devices at around 1000 cd/m².

TABLE 4

| | | | Current | | | Current | Power | External |
|---|---|---|---|---|---|---|---|---|
| | Voltage | Current | density | Chromaticity | Luminance | efficiency | efficiency | quantum |
| | (V) | (mA) | (mA/cm²) | (x, y) | (cd/m²) | (cd/A) | (lm/W) | efficiency (%) |
| Light-emitting | 3.6 | 0.058 | 1.4 | (0.36, 0.61) | 1100 | 77 | 68 | 21 |
| device 3 | | | | | | | | |
| Comparative | 3.6 | 0.042 | 1.0 | (0.36, 0.61) | 860 | 82 | 72 | 22 |
| light-emitting | | | | | | | | |
| device 4 | | | | | | | | |
| Comparative | 3.6 | 0.044 | 1.1 | (0.36, 0.62) | 840 | 76 | 66 | 20 |
| light-emitting | | | | | | | | |
| device 5 | | | | | | | | |

The above results show that the light-emitting device 3 using as the host materials of the light-emitting layer 8BP-4mDBtPBfpm and βNCCBP, which are contained in the composition for a light-emitting device of one embodiment of the present invention, exhibits favorable initial characteristics comparable to those of the comparative light-emitting device 4 and the comparative light-emitting device 5.

FIG. 16 shows the emission spectra of the light-emitting devices to which current flows at a current density of 2.5 mA/cm².

The emission spectra shown in FIG. 16 have peaks at around 526 nm, and it is suggested that the peaks are derived from light emission of [Ir(ppy)₂(mbfpypy-d3)] contained in the light-emitting layers 913 of the light-emitting device 3, the comparative light-emitting device 4, and the comparative light-emitting device 5.

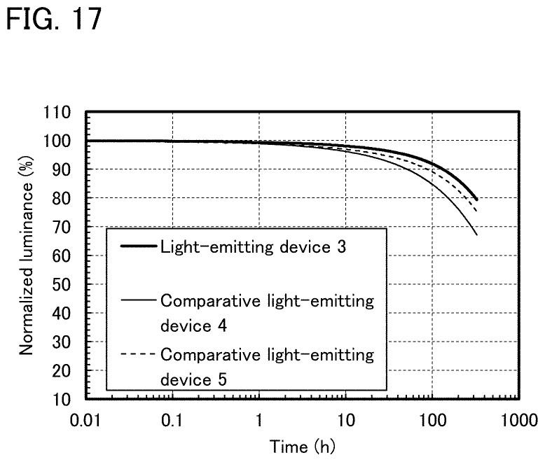

Next, a reliability test was performed on each light-emitting device. FIG. 17 shows the results of the reliability test of the light-emitting device 3, the comparative light-emitting device 4, and the comparative light-emitting device 5. In FIG. 17 showing reliability, the vertical axis represents normalized luminance (%) with an initial luminance of 100%, and the horizontal axis represents device driving time (h). As the reliability test, a driving test at a constant current density of 50 mA/cm² was performed on the light-emitting device 3, the comparative light-emitting device 4, and the comparative light-emitting device 5.

The above results indicate the following: the light-emitting device 3, which uses for the light-emitting layer 913 of the EL layer 902 the material contained in the composition for a light-emitting device (the premixed material) of one embodiment of the present invention, exhibits the operation characteristics comparable to those of the comparative light-emitting device 4 and the comparative light-emitting device 5; as for the reliability, the normalized luminance at 300 h is approximately 81% in the light-emitting device 3 but 77% and 69% in the comparative light-emitting device 4 and the comparative light-emitting device 5, respectively, that is, the light-emitting device 3 has a longer lifetime than the comparative light-emitting device 4 and the comparative light-emitting device 5.

In other words, this example suggests that with the use of the materials contained in the composition for a light-emitting device (the premixed material) of one embodiment of the present invention for the light-emitting layer, a highly reliable and productive light-emitting device can be fabricated while the device characteristics of the conventional light-emitting device are maintained.

### Example 3

In this example, a light-emitting device 6 was fabricated using, for the light-emitting layer 913 of the EL layer 902, a material contained in the composition for a light-emitting device (also referred to as a premixed material) of one embodiment of the present invention. Specifically, the light-emitting device 6 was fabricated using, for the light-emitting layer 913 of the EL layer 902, 8BP-4mDBtPBfpm (Structural Formula (100)), which is a first organic compound having a benzofuropyrimidine skeleton, and BisPNCz (Structural Formula (200)), which is a second organic compound having a bicarbazole skeleton. As a comparative light-emitting device fabricated without consideration of element fabrication using the composition for a light-emitting device, a comparative light-emitting device 7 was fabricated for comparison using βNCCP as the second organic compound instead of BisPNCz in the light-emitting device 6.

In this example, the light-emitting layer 913 of the light-emitting device 6 was formed by co-evaporation of the first organic compound (8BP-4mDBtPBfpm), the second organic compound (BisPNCz), and a light-emitting substance; and the light-emitting layer 913 of the comparative light-emitting device 7 was formed by co-evaporation of the first organic compound (8BP-4mDBtPBfpm), the second organic compound (βNCCP), and a light-emitting substance.

Table 5 shows specific device structures of the light-emitting devices used in this example. The chemical formulae of the materials used in this example are shown below. Note that the device structures and fabrication methods of the light-emitting devices are similar to those in Example 1; thus, FIG. 9 is referred to also in this example.

TABLE 5

| | | | | Light- | | | Electron- | |
|---|---|---|---|---|---|---|---|---|
| | Fist | Hole-injection | Hole-transport | emitting | Electron-transport | | injection | Second |
| | electrode | layer | layer | layer | layer | | layer | electrode |
| | 901 | 911 | 912 | 913 | 914 | | 915 | 903 |
| Light-emitting | ITSO | DBT3P-II:MoOx | PCBBilBP | * | 8BP-4mDBtPBfpm | NBphen | LiF | Al |
| device 6 | (70 nm) | (2:1 45 nm) | (20 nm) | | (20 nm) | (10 nm) | (1 nm) | (200 nm) |
| Comparative | ITSO | DBT3P-II:MoOx | PCBBilBP | ** | 8BP-4mDBtPBfpm | NBphen | LiF | Al |
| light-emitting | (70 nm) | (2:1 45 nm) | (20 nm) | | (20 nm) | (10 nm) | (1 nm) | (200 nm) |
| device 7 | | | | | | | | |

* 8BP-4mDBtPBfpm:BisβNCz:[Ir(ppy)₂(mbfpypy-d3)] (0.7:0.3:0.1 40 nm)
** 8BP-4mDBtPBfpm:βNCCP:[Ir(ppy)₂(mbfpypy-d3)] (0.6:0.4:0.1 40 nm)

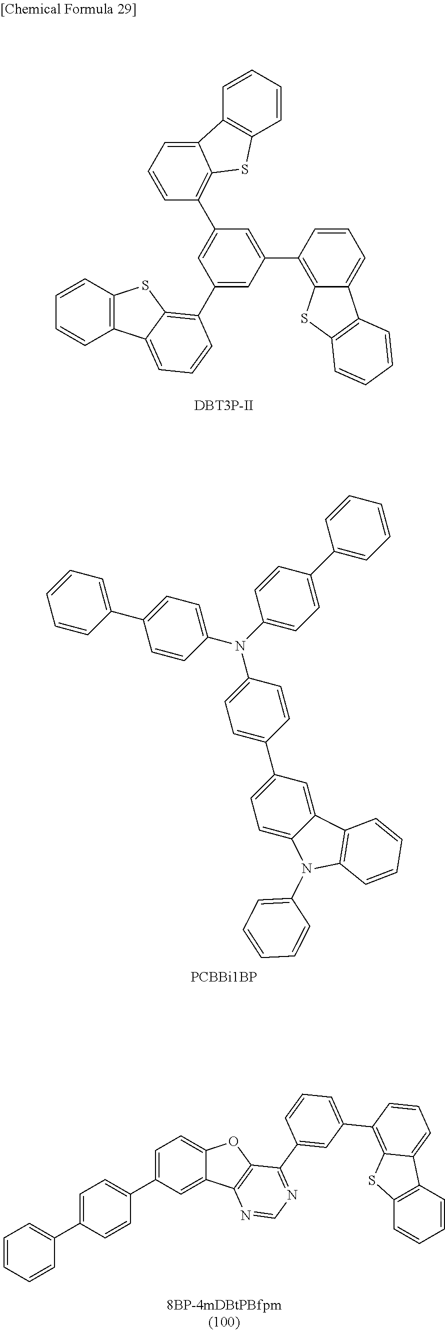

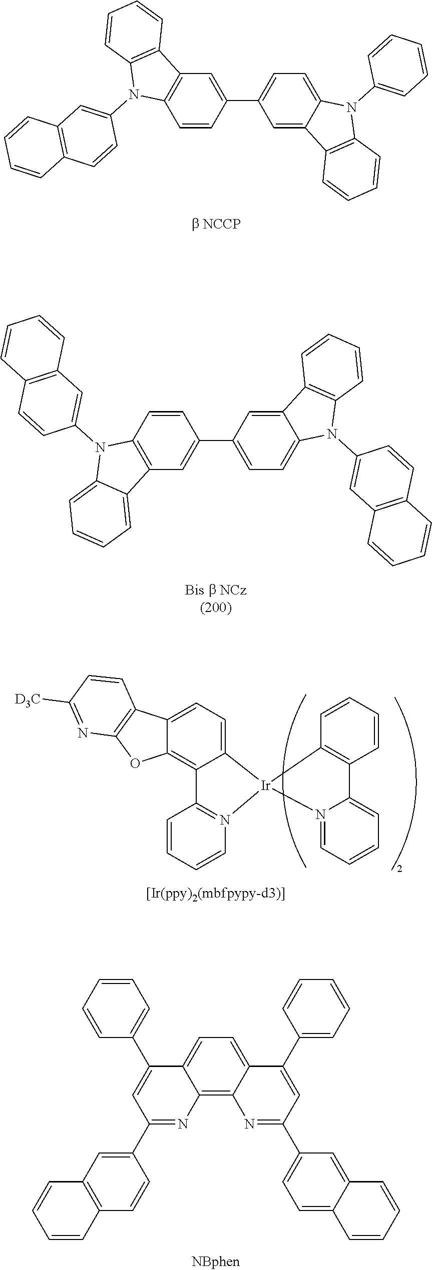

### <<Operation Characteristics of Light-Emitting Devices>>

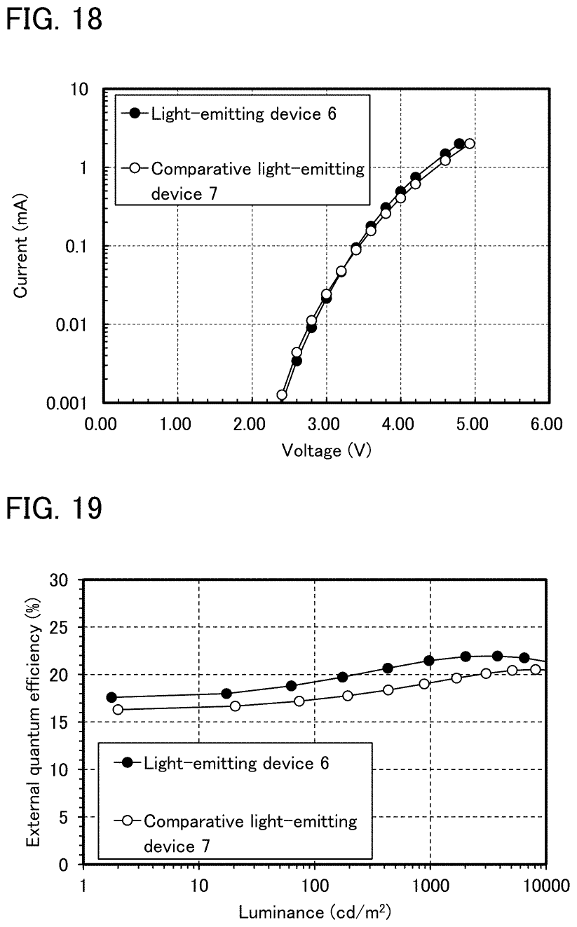

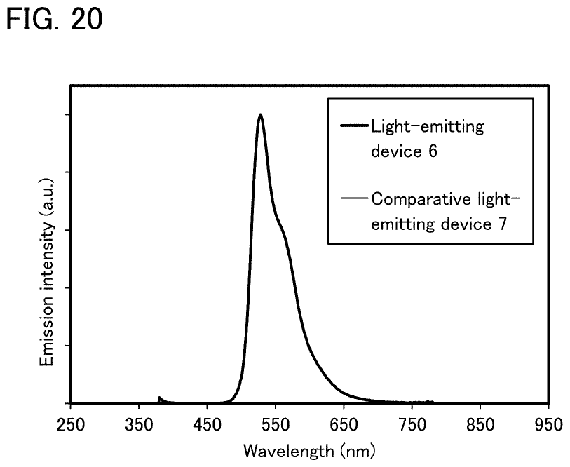

Measurement results of operation characteristics of the fabricated light-emitting devices are shown. Note that the measurement was carried out at room temperature (an atmosphere maintained at 25° C.). Luminance and CIE chromaticity were measured with a luminance colorimeter (BM-5A manufactured by TOPCON TECHNOHOUSE CORPORATION), and electroluminescence spectra were measured with a multi-channel spectrometer (PMA-11 manufactured by Hamamatsu Photonics K.K.). As the results of the operation characteristics of the light-emitting device 6 and the comparative light-emitting device 7, the voltage-current characteristics are shown in FIG. 18, and the luminance-external quantum efficiency characteristics are shown in FIG. 19.

Table 6 below shows the initial values of the main characteristics of the light-emitting devices at around 1000 cd/m².

TABLE 6

| | | | Current | | | Current | Power | External |
|---|---|---|---|---|---|---|---|---|
| | Voltage | Current | density | Chromaticity | Luminance | efficiency | efficiency | quantum |
| | (V) | (mA) | (mA/cm²) | (x, y) | (cd/m²) | (cd/A) | (lm/W) | efficiency (%) |
| Light-emitting | 3.2 | 0.047 | 1.2 | (0.34, 0.63) | 970 | 83 | 82 | 21 |
| device 6 | | | | | | | | |
| Comparative | 3.2 | 0.048 | 1.2 | (0.34, 0.63) | 880 | 74 | 73 | 19 |
| light-emitting | | | | | | | | |
| device 7 | | | | | | | | |

The above results show that the light-emitting device 6 using as the host materials of the light-emitting layer 8BP-4mDBtPBfpm and BisPNCz, which are contained in the composition for a light-emitting device of one embodiment of the present invention, exhibits favorable initial characteristics comparable to those of the comparative light-emitting device 7.

FIG. 20 shows the emission spectra of the light-emitting devices to which current flows at a current density of 2.5 mA/cm².

The emission spectra shown in FIG. 20 have peaks at around 528 nm, and it is suggested that the peaks are derived from light emission of [Ir(ppy)₂(mbfpypy-d3)] contained in the light-emitting layers 913 of the light-emitting device 6 and the comparative light-emitting device 7.

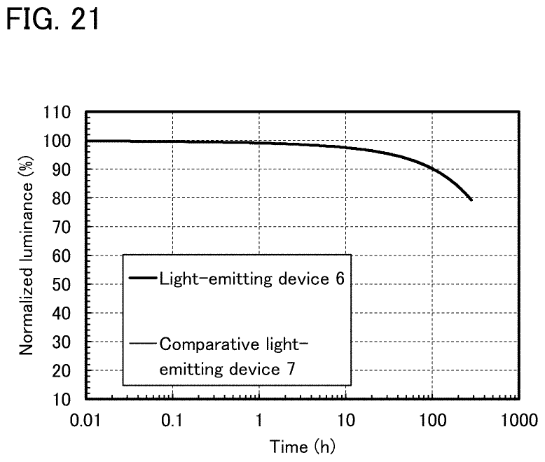

Next, a reliability test was performed on each light-emitting device. FIG. 21 shows the results of the reliability test of the light-emitting device 6 and the comparative light-emitting device 7. In FIG. 21 showing reliability, the vertical axis represents normalized luminance (%) with an initial luminance of 100%, and the horizontal axis represents device driving time (h). As the reliability test, a driving test at a constant current density of 50 mA/cm² was performed on the light-emitting device 6 and the comparative light-emitting device 7.

The above results indicate the following: the light-emitting device 6, which uses for the light-emitting layer 913 of the EL layer 902 the material contained in the composition for a light-emitting device (the premixed material) of one embodiment of the present invention, has high reliability, i.e., a long lifetime comparable to that of the comparative light-emitting device 7 (exhibits a normalized luminance at 280 h of approximately 80%).

In other words, this example suggests that with the use of the composition for a light-emitting device (the premixed material) of one embodiment of the present invention for the light-emitting layer, a highly productive light-emitting device can be fabricated while the device characteristics and reliability of the light-emitting device are maintained.

### Example 4

In this example, among the devices using for the light-emitting layer 913 of the EL layer 902 the composition for a light-emitting device (also referred to as a premixed material) of one embodiment of the present invention, the light-emitting device 1 shown in Example 1, the light-emitting device 3 shown in Example 2, and a light-emitting device 6′, which has the same stacked structure as the light-emitting device 6 shown in Example 3 and is different from the light-emitting device 6 only in the thicknesses of some films, were each fabricated to obtain some (N) samples under the same conditions and measured to confirm the reproducibility of the operation characteristics of the light-emitting devices.

Table 7 shows specific device structures of the light-emitting devices used in this example. The chemical formulae of the materials used in this example are shown below.

TABLE 7

| | | | | Light- | | | Electron- | |
|---|---|---|---|---|---|---|---|---|
| | First | Hole-injection | Hole-transport | emitting | Electron-transport | | injection | Second |
| | electrode | layer | layer | layer | layer | | layer | electrode |
| | 901 | 911 | 912 | 913 | 914 | | 915 | 903 |
| Light-emitting | ITSO | DBT3P-II:MoOx | PCBBilBP | * | 8BP-4mDBtPBfpm | NBphen | LiF | Al |
| device 1 | (70 nm) | (2:1 45 nm) | (20 nm) | | (20 nm) | (10 nm) | (1 nm) | (200 nm) |
| Light-emitting | ITSO | DBT3P-II:MoOx | PCBBilBP | ** | 8BP-4mDBtPBfpm | NBphen | LiF | Al |
| device 3 | (70 nm) | (2:1 45 nm) | (20 nm) | | (20 nm) | (10 nm) | (1 nm) | (200 nm) |
| Light-emitting | ITSO | DBT3P-II:MoOx | PCBBilBP | *** | 8BP-4mDBtPBfpm | NBphen | LiF | Al |
| device 6′ | (70 nm) | (2:1 45 nm) | (20 nm) | | (20 nm) | (10 mn) | (1 nm) | (200 nm) |

* 8BP-4mDBtPBfpm:βNCCmBP:[Ir(ppy)₂(mbfpypy-d3)] (0.6:0.4:0.1 50 nm)
** 8BP-4mDBtPBfpm:βNCCBP:[Ir(ppy)₂(mbfpypy-d3)] (0.6:0.4:0.1 50 nm)
** 8BP-4mDBtPBfpm:BisβNCz:[Ir(ppy)₂(mbfpypy-d3)] (0.6:0.4:0.1 50 nm)

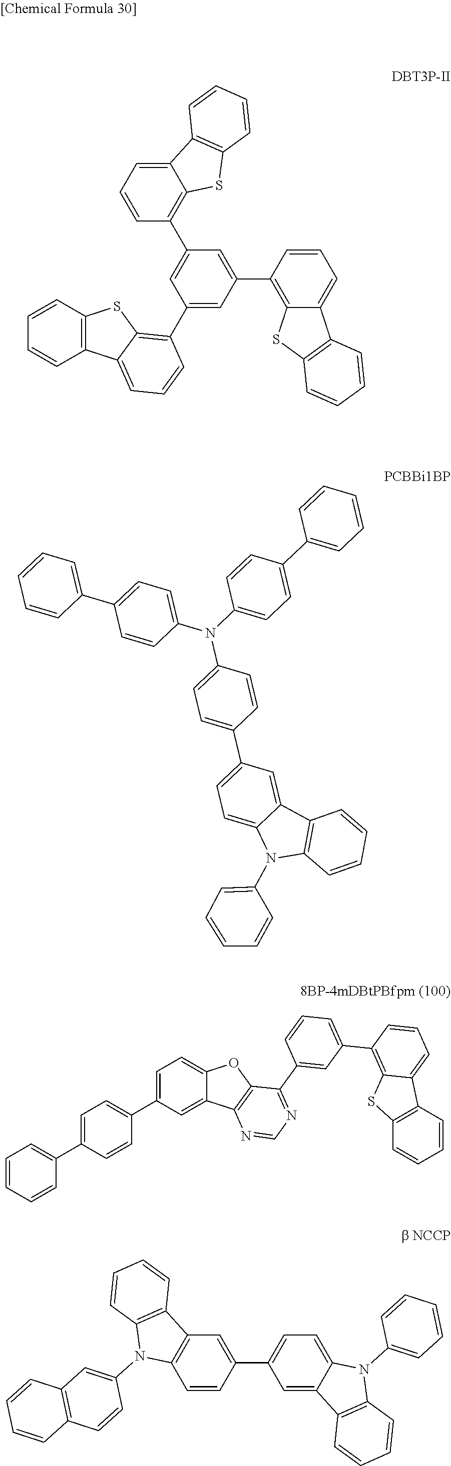 [SMILES: c1ccc2c(c1)sc1c(-c3cc(-c4cccc5c4sc4ccccc45)cc(-c4cccc5c4sc4ccccc45)c3)cccc12 ; c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(-c2ccc(-c3ccc4oc5c(-c6cccc(-c7cccc8c7sc7ccccc78)c6)ncnc5c4c3)cc2)cc1 ; c1ccc(-n2c3ccccc3c3cc(-c4ccc5c(c4)c4ccccc4n5-c4ccc5ccccc5c4)ccc32)cc1]

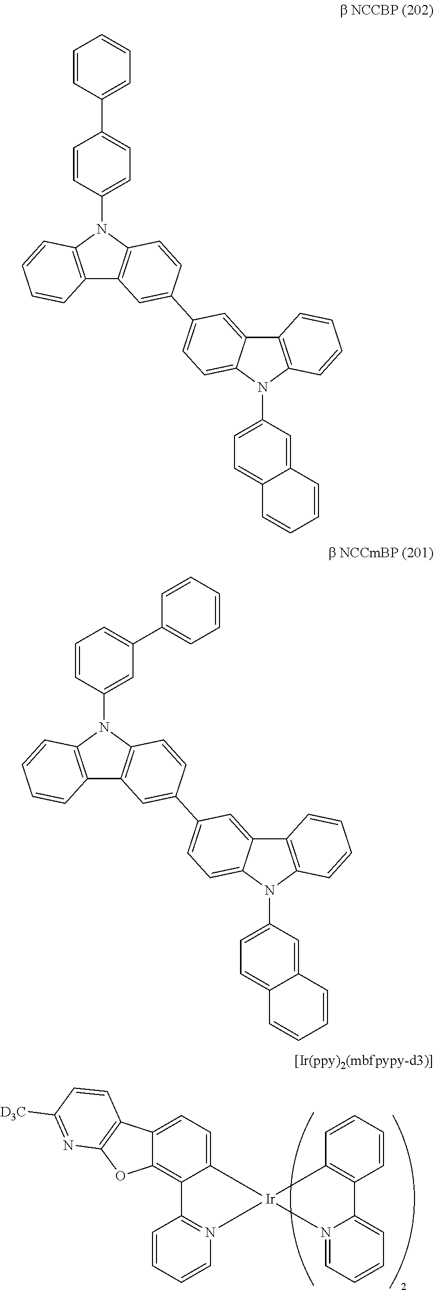

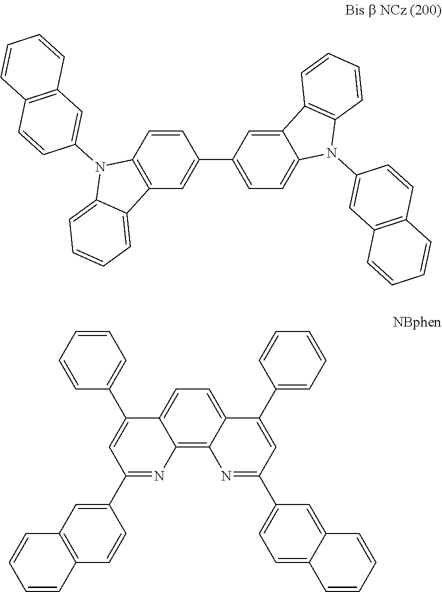 [SMILES: c1ccc2cc(-n3c4ccccc4c4cc(-c5ccc6c(c5)c5ccccc5n6-c5ccc6ccccc6c5)ccc43)ccc2c1 ; c1ccc(-c2cc(-c3ccc4ccccc4c3)nc3c2ccc2c(-c4ccccc4)cc(-c4ccc5ccccc5c4)nc23)cc1]

### <<Operation Characteristics of Light-Emitting Devices>>

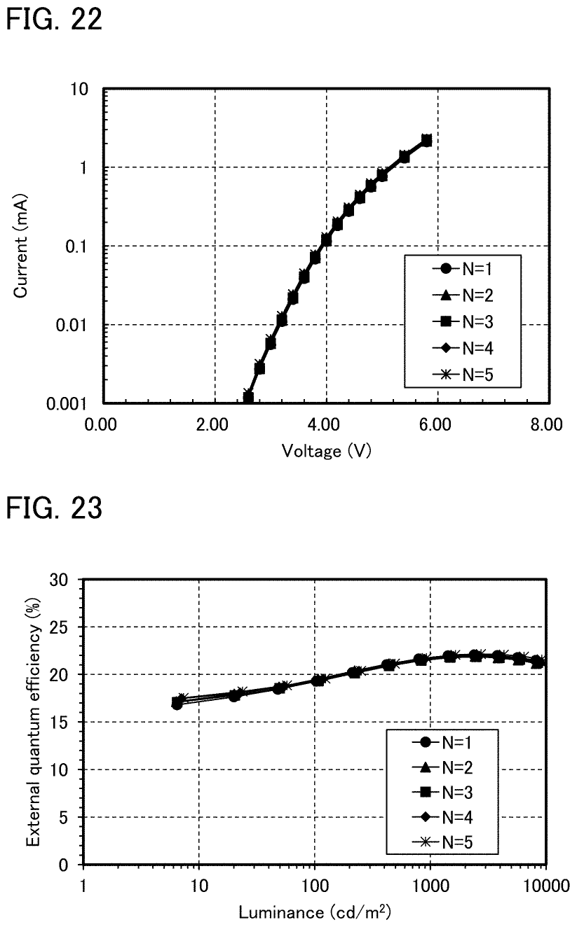

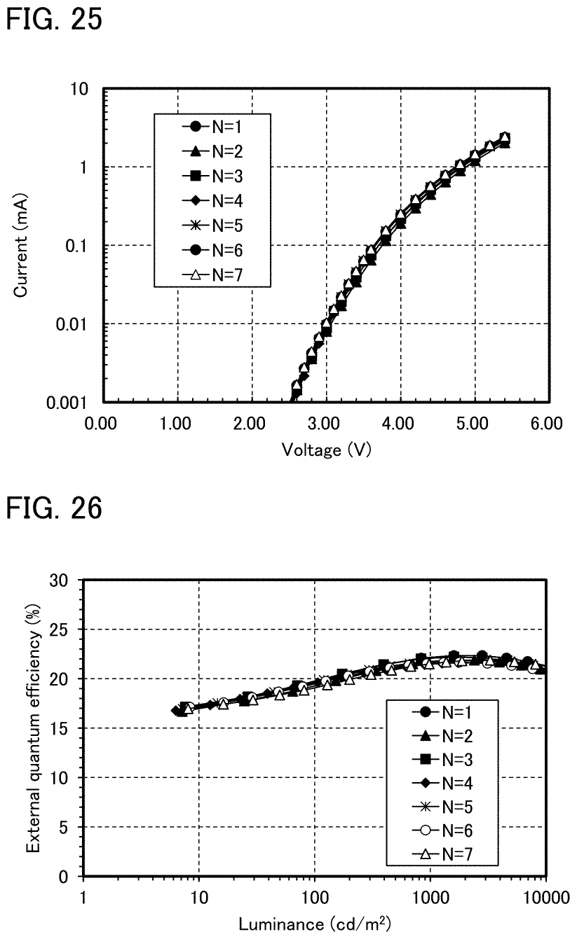

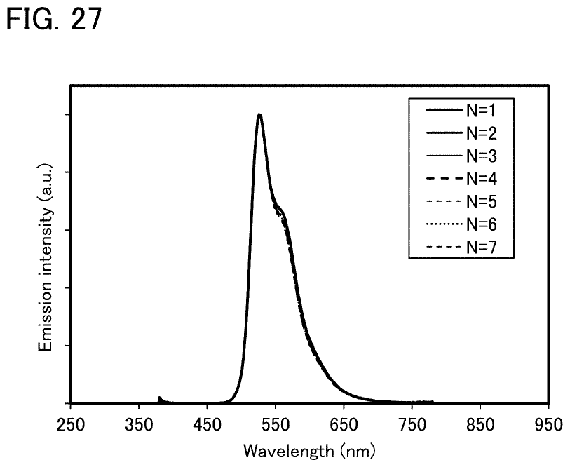

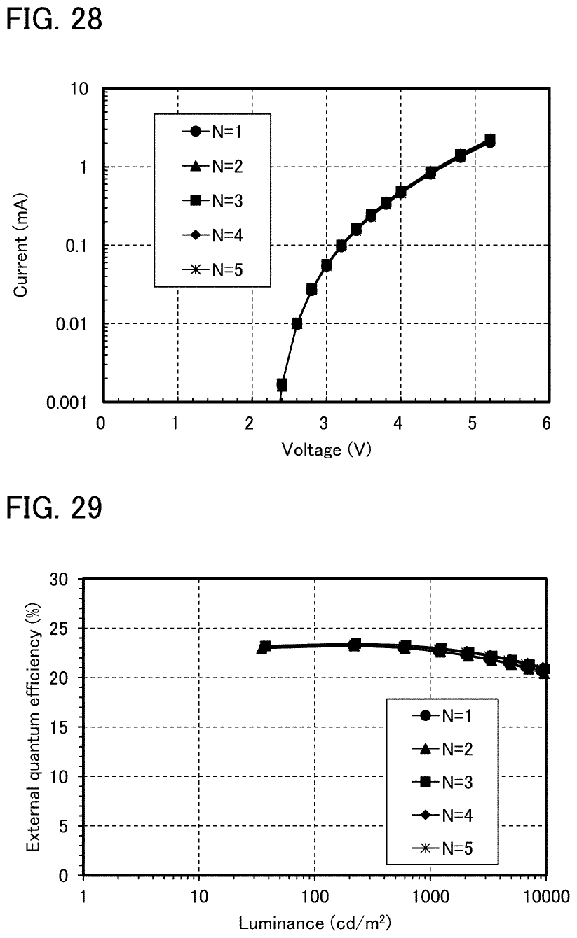

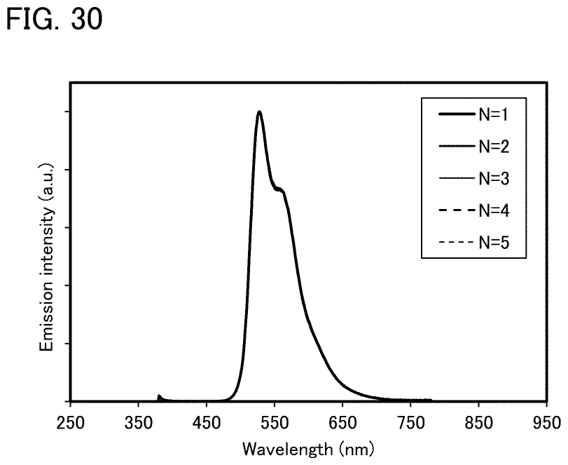

Measurement results of the operation characteristics of the fabricated light-emitting devices are shown. Note that the measurement was carried out at room temperature (an atmosphere maintained at 25° C.). Luminance and CIE chromaticity were measured with a luminance colorimeter (BM-5A manufactured by TOPCON TECHNOHOUSE CORPORATION), and electroluminescence spectra were measured with a multi-channel spectrometer (PMA-11 manufactured by Hamamatsu Photonics K.K.). As the results of the operation characteristics of the light-emitting device 1, the light-emitting device 3, and the light-emitting device 6′, the voltage-current characteristics and the luminance-external quantum efficiency characteristics of the light-emitting device 1 are shown in FIG. 22 and FIG. 23, respectively; the voltage-current characteristics and the luminance-external quantum efficiency characteristics of the light-emitting device 3 are shown in FIG. 25 and FIG. 26, respectively; and the voltage-current characteristics and the luminance-external quantum efficiency characteristics of the light-emitting device 6′ are shown in FIG. 28 and FIG. 29, respectively. Note that the number of samples of the light-emitting devices 1 is N=5, the number of samples of the light-emitting devices 3 is N=7, and the number of samples of the light-emitting devices 6′ is N=6.

Table 8 below shows the initial values of the main characteristics of the light-emitting devices at around 1000 cd/m².

TABLE 8

| | | | | Current | | | Current | Power | External |
|---|---|---|---|---|---|---|---|---|---|
| | Number | Voltage | Current | density | Chromaticity | Luminance | efficiency | efficiency | quantum |
| | N | (V) | (mA) | (mA/cm²) | (x, y) | (cd/m²) | (cd/A) | (lm/W) | efficiency (%) |
| Light-emitting | 1 | 3.6 | 0.038 | 1.0 | (0.35, 0.62) | 790 | 83 | 72 | 22 |
| device 1 | 2 | 3.6 | 0.040 | 1.0 | (0.36, 0.62) | 820 | 82 | 72 | 22 |
| | 3 | 3.6 | 0.041 | 1.0 | (0.36, 0.62) | 830 | 82 | 71 | 21 |
| | 4 | 3.6 | 0.043 | 1.1 | (0.36, 0.62) | 890 | 82 | 72 | 22 |
| | 5 | 3.6 | 0.045 | 1.1 | (0.35, 0.62) | 930 | 83 | 73 | 22 |
| Light-emitting | 1 | 3.4 | 0.039 | 0.99 | (0.34, 0.62) | 840 | 85 | 78 | 22 |
| device 3 | 2 | 3.4 | 0.034 | 0.85 | (0.35, 0.62) | 700 | 83 | 76 | 22 |
| | 3 | 3.4 | 0.039 | 0.98 | (0.35, 0.63) | 830 | 85 | 78 | 22 |
| | 4 | 3.4 | 0.043 | 1.1 | (0.34, 0.63) | 890 | 83 | 76 | 21 |
| | 5 | 3.4 | 0.045 | 1.1 | (0.34, 0.63) | 950 | 84 | 77 | 22 |
| | 6 | 3.4 | 0.045 | 1.1 | (0.34, 0.63) | 930 | 83 | 77 | 22 |
| | 7 | 3.4 | 0.047 | 1.2 | (0.34, 0.63) | 980 | 83 | 77 | 21 |
| Light-emitting | 1 | 3.0 | 0.054 | 1.3 | (0.36, 0.61) | 1200 | 86 | 90 | 23 |
| device 6′ | 2 | 3.0 | 0.057 | 1.4 | (0.36, 0.61) | 1200 | 85 | 90 | 23 |
| | 3 | 3.0 | 0.057 | 1.4 | (0.36, 0.61) | 1200 | 87 | 91 | 23 |
| | 4 | 3.0 | 0.054 | 1.4 | (0.36, 0.61) | 1200 | 87 | 91 | 23 |
| | 5 | 3.0 | 0.054 | 1.4 | (0.36, 0.61) | 1200 | 87 | 91 | 23 |

The above results show that the light-emitting devices fabricated in this example exhibit highly reproductive device characteristics.

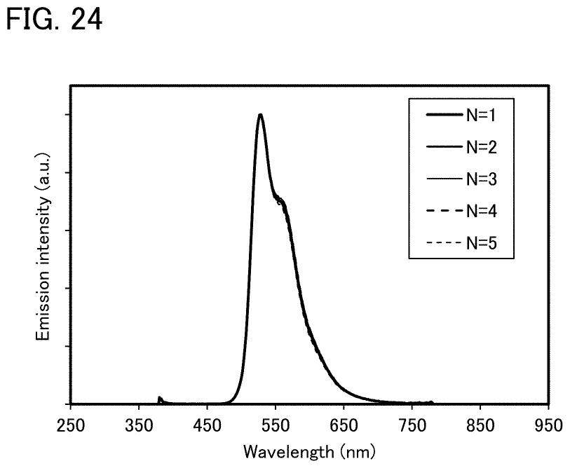

FIG. 24, FIG. 27, and FIG. 30 show the emission spectra of the light-emitting device 1, the light-emitting device 3, and the light-emitting device 6′, respectively, to each which current flows at a current density of 2.5 mA/cm².

The emission spectra shown in FIG. 24, FIG. 27, and FIG. 30 have peaks at around 527 nm, and it is suggested that the peaks are derived from light emission of [Ir(ppy)₂(mbfpypy-d3)] contained in the light-emitting layers 913 of the light-emitting device 1, the light-emitting device 3, and the light-emitting device 6′.

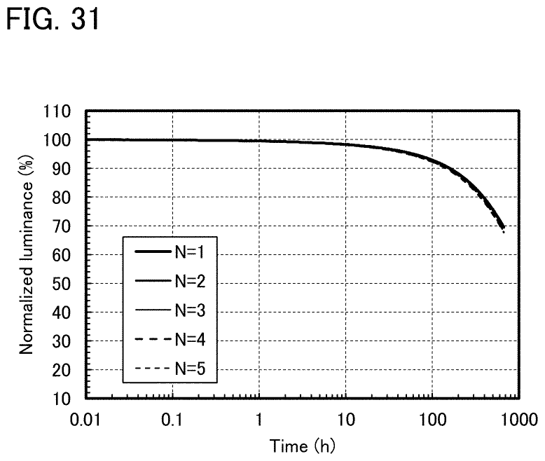

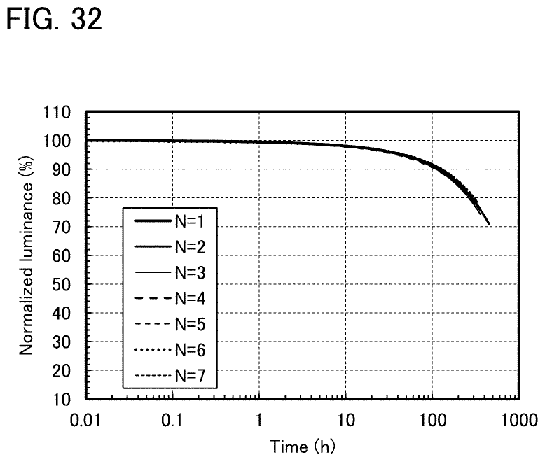

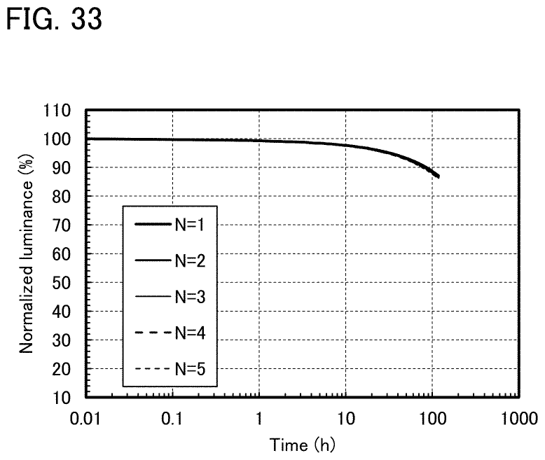

Next, a reliability test was performed on each light-emitting device. FIG. 31, FIG. 32, and FIG. 33 show the results of the reliability tests of the light-emitting device 1, the light-emitting device 3, and the light-emitting device 6′, respectively. In these graphs showing reliability, the vertical axis represents normalized luminance (%) with an initial luminance of 100%, and the horizontal axis represents device driving time (h). As the reliability tests, a driving test at a constant current density of 50 mA/cm² was performed on each of the light-emitting device 1, the light-emitting device 3, and the light-emitting device 6′.

The above results indicate the following: the light-emitting device 1, the light-emitting device 3, and the light-emitting device 6′, each of which uses for the light-emitting layer 913 the composition for a light-emitting device (the premixed material) of one embodiment of the present invention, exhibit high reliability regardless of an increase in the number of samples.

In other words, this example suggests that with the use of the composition for a light-emitting device (the premixed material) of one embodiment of the present invention for the light-emitting layer, a highly productive light-emitting device can be fabricated while the device characteristics and reliability of the light-emitting device are maintained.

### Reference Synthesis Example

A method for synthesizing 9-(4-biphenyl)-9′-(1-naphthyl)-3,3′-bi-9H-carbazole (abbreviation: αNCCBP) (Structural Formula (300)), which was used in Example 2, will be described. The structure of αNCCBP is shown below.

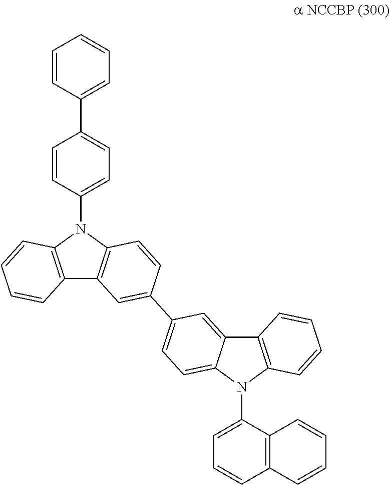 [SMILES: c1ccc(-c2ccc(-n3c4ccccc4c4cc(-c5ccc6c(c5)c5ccccc5n6-c5cccc6ccccc56)ccc43)cc2)cc1]

### Step 1: Synthesis of 9-(4-biphenyl)-3,3′-bi-9H-carbazole

First, 15 g (38 mmol) of 9-(4-biphenyl)-3-bromocarbazole, 12 g (42 mmol) of 3-(4,4,5,5-tetramethyl-1,3,2-dioxaborolan-2-yl)carbazole, 12 g (83 mmol) of potassium carbonate, 1.1 g (3.8 mmol) of tris(o-tolyl)phosphine, 150 mL of toluene, 30 mL of ethanol, and a 30 mL of water were put into a 500-mL three-neck flask, the air in the flask was replaced with nitrogen, and the mixture was degassed by being stirred while the pressure in the flask was reduced.

After the degassing, 0.43 g (1.9 mmol) of palladium(II) acetate was added, and the mixture was stirred under a nitrogen stream at 80° C. for 14.5 hours. After a predetermined time elapsed, water was added to the obtained reaction mixture, and the mixture was suction-filtered. The obtained residue was washed with ethanol. Then, the resulting solid was dissolved in toluene, followed by suction filtration through Celite. The obtained filtrate was concentrated to give a solid. The obtained solid was suction-filtered to give 17 g of a white solid in a yield of 94%. Note that the obtained white solid was identified as 9-(4-biphenyl)-3,3′-bi-9H-carbazole by nuclear magnetic resonance (NMR) spectroscopy. The synthesis scheme in Step 1 is shown in Formula (a-1) below.

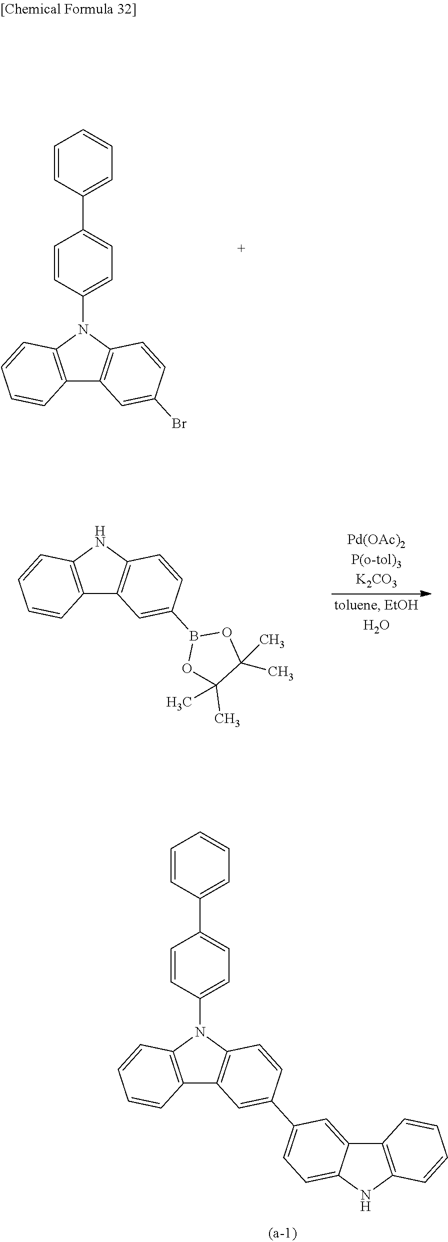 [SMILES: Brc1ccc2c(c1)c1ccccc1n2-c1ccc(-c2ccccc2)cc1 ; CC1(C)OB(c2ccc3[nH]c4ccccc4c3c2)OC1(C)C ; c1ccc(-c2ccc(-n3c4ccccc4c4cc(-c5ccc6[nH]c7ccccc7c6c5)ccc43)cc2)cc1]

### Step 2: Synthesis of αNCCBP

Then, 3.0 g (6.2 mmol) of 9-(4-biphenyl)-3,3′-bi-9H-carbazole synthesized in Step 1, 1.9 g (9.3 mmol) of 1-bromonaphthalene, 1.8 g (19 mmol) of sodium tert-butoxide, 0.15 g (0.37 mmol) of 2-dicyclohexylphosphino-2′,6′-dimethoxybiphenyl (S-phos), and 50 mL of xylene were put into a 200-mL three-neck flask, the air in the flask was replaced with nitrogen, and the mixture was degassed by being stirred while the pressure in the flask was reduced.

After the degassing, 0.17 g (0.19 mmol) of tris(dibenzylideneacetone)dipalladium(0) was added, and the mixture was stirred under a nitrogen stream at 140° C. for 26 hours. After a predetermined time elapsed, the resulting reaction mixture was suction-filtered through a filter aid in which Celite, Florisil, and alumina were stacked in this order. The obtained filtrate was concentrated to give a solid. The obtained solid was purified by silica column chromatography. As a developing solvent, a mixed solvent of hexane:ethyl acetate=10:1 was used.

The obtained fraction was concentrated to give a target solid. The resulting solid was recrystallized with ethyl acetate to give 2.4 g of a solid in a yield of 63%. By a train sublimation method, 2.4 g of the obtained solid was sublimated and purified by heating at 310° C. for 17 hours under the conditions where the pressure was 2.7 Pa and the argon flow rate was 10 mL/min. After the sublimation purification, 1.8 g of a solid was obtained at a collection rate of 77%. The synthesis scheme in Step 2 is shown in Formula (a-2) below.

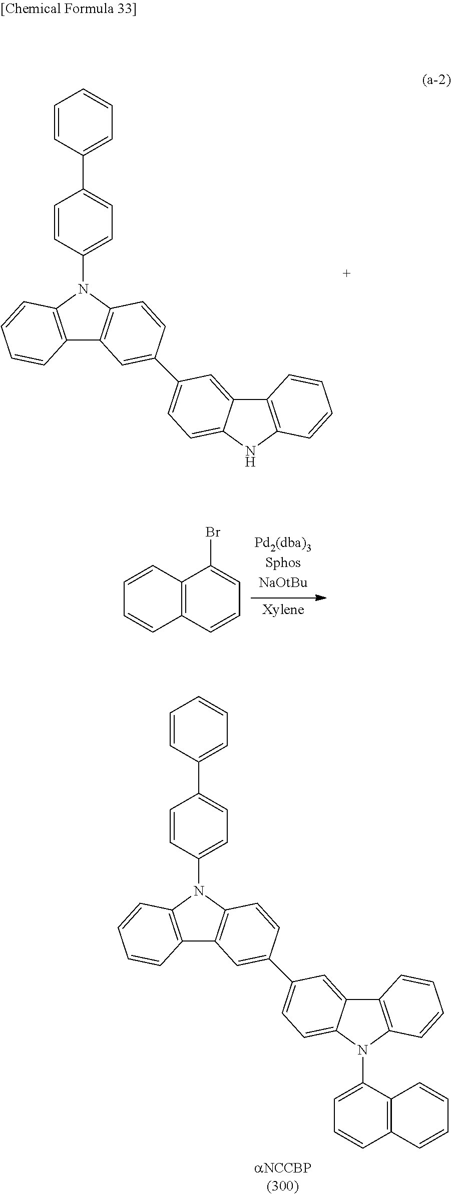 [SMILES: c1ccc(-c2ccc(-n3c4ccccc4c4cc(-c5ccc6[nH]c7ccccc7c6c5)ccc43)cc2)cc1 ; Brc1cccc2ccccc12 ; c1ccc(-c2ccc(-n3c4ccccc4c4cc(-c5ccc6c(c5)c5ccccc5n6-c5cccc6ccccc56)ccc43)cc2)cc1]

Note that the results of analysis by nuclear magnetic resonance (¹H-NMR) spectroscopy of the white solid obtained in Step 2 above are shown below. These results reveal that αNCCBP represented by Structural Formula (300) was obtained.

¹H-NMR. 6 (CDCl₃): 7.05 (d, 1H), 7.12 (d, 1H), 7.47-7.32 (m, 7H), 7.51-7.51 (m, 5H), 7.69-7.73 (m, 7H), 7.81 (d, 1H), 7.84-7.86 (m, 2H), 8.04-8.10 (m, 2H), 8.25 (d, 1H), 8.31 (d, 1H), 8.48 (s, 1H), 8.53 (s, 1H).

### REFERENCE NUMERALS

1: first electrode, 102: second electrode, 103: EL layer, 103a, 103b: EL layer, 104: charge-generation layer, 111, 111a, 111b: hole-injection layer, 112, 112a, 112b: hole-transport layer, 113, 113a, 113b: light-emitting layer, 114, 114a, 114b: electron-transport layer, 115, 115a, 115b: electron-injection layer, 200R, 200G, 200B: optical path length, 201: first substrate, 202: transistor (FET), 203R, 203G, 203B, 203W: light-emitting device, 204: EL layer, 205: second substrate, 206R, 206G, 206B: color filter, 206R′, 206G′, 206B′: color filter, 207: first electrode, 208: second electrode, 209: black layer (black matrix), 210R, 210G: conductive layer, 301: first substrate, 302: pixel portion, 303: driver circuit portion (source line driver circuit), 304a, 304b: driver circuit portion (gate line driver circuit), 305: sealant, 306: second substrate, 307: lead wiring, 308: FPC, 309: FET, 310: FET, 311: FET, 312: FET, 313: first electrode, 314: insulator, 315: EL layer, 316: second electrode, 317: light-emitting device, 318: space, 400: substrate, 401: first organic compound, 402: second organic compound, 403: light-emitting substance, 404: composition for light-emitting device, 405: light-emitting substance, 900: substrate, 901: first electrode, 902: EL layer, 903: second electrode, 911: hole-injection layer, 912: hole-transport layer, 913: light-emitting layer, 914: electron-transport layer, 915: electron-injection layer, 4000: lighting device, 4001: substrate, 4002: light-emitting device, 4003: substrate, 4004: first electrode, 4005: EL layer, 4006: second electrode, 4007: electrode, 4008: electrode, 4009: auxiliary wiring, 4010: insulating layer, 4011: sealing substrate, 4012: sealant, 4013: desiccant, 4200: lighting device, 4201: substrate, 4202: light-emitting device, 4204: first electrode, 4205: EL layer, 4206: second electrode, 4207: electrode, 4208: electrode, 4209: auxiliary wiring, 4210: insulating layer, 4211: sealing substrate, 4212: sealant, 4213: barrier film, 4214: planarization film, 5101: light, 5102: wheel, 5103: door, 5104: display portion, 5105: steering wheel, 5106: shifter, 5107: seat, 5108: inner rearview mirror, 5109: windshield, 7000: housing, 7001: display portion, 7002: second display portion, 7003: speaker, 7004: LED lamp, 7005: operation key, 7006: connection terminal, 7007: sensor, 7008: microphone, 7009: switch, 7010: infrared port, 7011: recording medium reading portion, 7014: antenna, 7015: shutter button, 7016: image receiving portion, 7018: stand, 7022, 7023: operation button, 7024: connection terminal, 7025: band, 7026: microphone, 7029: sensor, 7030: speaker, 7052, 7053, 7054: information, 9310: portable information terminal, 9311: display portion, 9312: display region, 9313: hinge, 9315: housing

1. A composition for a light-emitting device formed by mixing a first organic compound having a benzofuropyrimidine skeleton, and a second organic compound represented by General Formula (Q1): 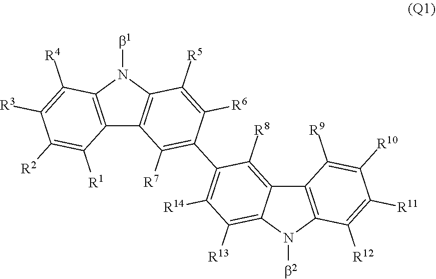
wherein, in the General Formula (Q1), R¹ to R¹⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted β-naphthyl group, an unsubstituted biphenyl group, and an unsubstituted terphenyl group, and
wherein at least one of β¹ and β² is an unsubstituted β-naphthyl group.

2. A composition for a light-emitting device formed by mixing a first organic compound having a benzofuropyrimidine skeleton, and a second organic compound represented by General Formula (Q2): 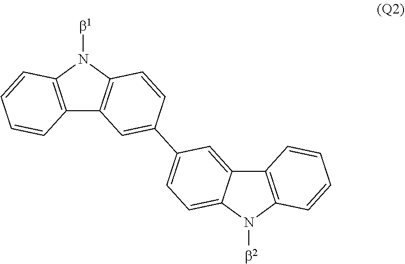
wherein, in the General Formula (Q2), β¹ and β² each represent any of an unsubstituted β-naphthyl group, an unsubstituted biphenyl group, and an unsubstituted terphenyl group, and
wherein at least one of β¹ and β² is an unsubstituted β-naphthyl group.

3. A composition for a light-emitting device formed by mixing a first organic compound represented by General Formula (G1), and a second organic compound represented by General Formula (Q1): 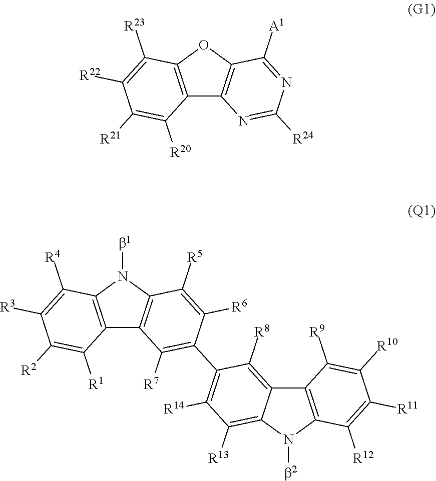
wherein, in the General Formulae (G1) and (Q1), A¹ represents an aryl group having 6 to 100 carbon atoms,
wherein R¹ to R¹⁴ and R²⁰ to R²⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted β-naphthyl group, an unsubstituted biphenyl group, and an unsubstituted terphenyl group, and
wherein at least one of β¹ and β² is an unsubstituted β-naphthyl group.

4. A composition for a light-emitting device formed by mixing a first organic compound represented by General Formula (G1), and a second organic compound represented by General Formula (Q2): 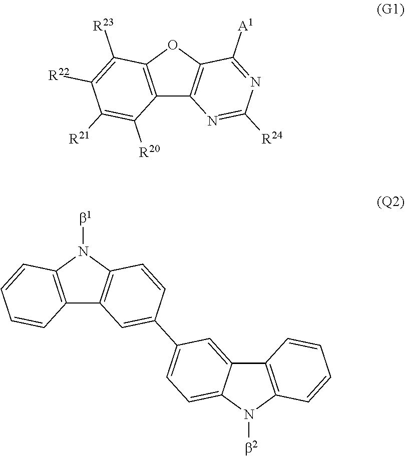
wherein, in the General Formulae (G1) and (Q2), A¹ represents an aryl group having 6 to 100 carbon atoms,
wherein R²⁰ to R²⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted β-naphthyl group, an unsubstituted biphenyl group, and an unsubstituted terphenyl group, and
wherein at least one of β¹ and β² is an unsubstituted β-naphthyl group.

5. A composition for a light-emitting device formed by mixing a first organic compound represented by General Formula (G2), and a second organic compound represented by General Formula (Q1): 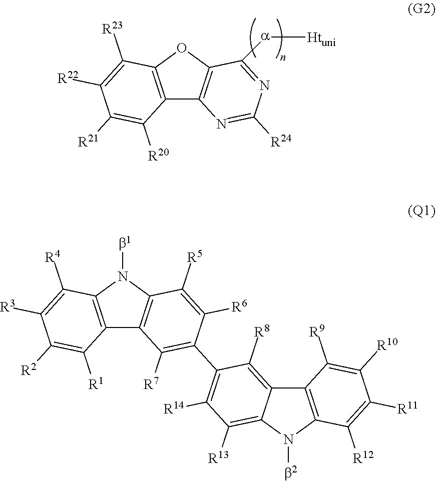
wherein, in the General Formulae (G2) and (Q1), α represents a substituted or unsubstituted phenylene group,
wherein n is an integer of 0 to 4,
wherein Htᵤₙᵢ represents any one of a substituted or unsubstituted dibenzothiophenyl group, a substituted or unsubstituted dibenzofuranyl group, and a substituted or unsubstituted carbazolyl group,
wherein R¹ to R¹⁴ and R²⁰ to R²⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted p-naphthyl group, an unsubstituted biphenyl group, and an unsubstituted terphenyl group, and
wherein at least one of β¹ and β² is an unsubstituted p-naphthyl group.

6. A composition for a light-emitting device formed by mixing a first organic compound represented by General Formula (G2), and a second organic compound represented by General Formula (Q2): 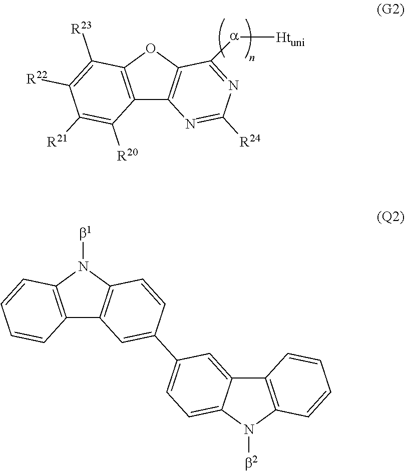
wherein, in the General Formulae (G2) and (Q2), α represents a substituted or unsubstituted phenylene group,
wherein n is an integer of 0 to 4,
wherein Htᵤₙᵢ represents any one of a substituted or unsubstituted dibenzothiophenyl group, a substituted or unsubstituted dibenzofuranyl group, and a substituted or unsubstituted carbazolyl group,
R²⁰ to R²⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted p-naphthyl group, an unsubstituted biphenyl group, and an unsubstituted terphenyl group, and
wherein at least one of β¹ and β² is an unsubstituted p-naphthyl group.

7. A composition for a light-emitting device formed by mixing a first organic compound represented by General Formula (G3), and a second organic compound represented by General Formula (Q1): 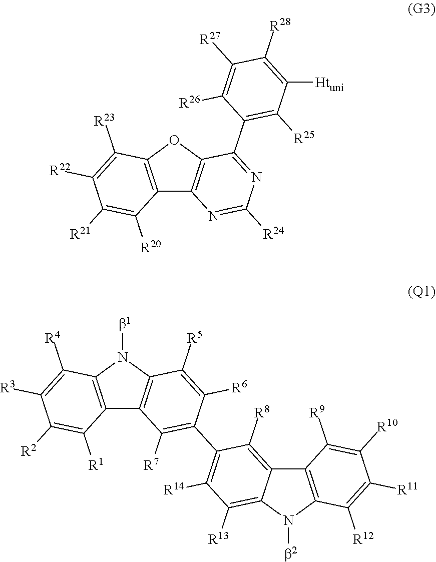
wherein, in the General Formulae (G3) and (Q1), Htᵤₙᵢ represents any one of a substituted or unsubstituted dibenzothiophenyl group, a substituted or unsubstituted dibenzofuranyl group, and a substituted or unsubstituted carbazolyl group,
wherein R¹ to R¹⁴ and R²⁰ to R²⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted β-naphthyl group, an unsubstituted biphenyl group, and an unsubstituted terphenyl group, and
wherein at least one of β¹ and β² is an unsubstituted β-naphthyl group.

8. A composition for a light-emitting device formed by mixing a first organic compound represented by General Formula (G3), and a second organic compound represented by General Formula (Q2): 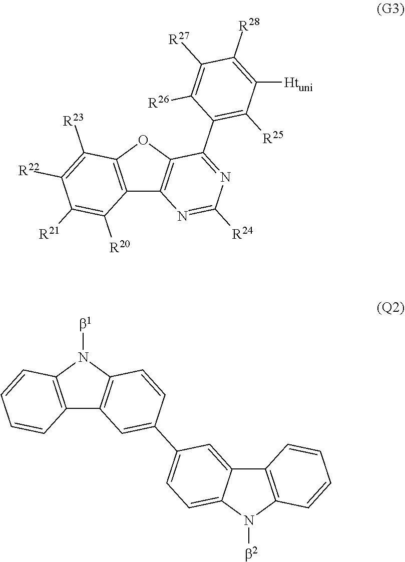
wherein, in the General Formulae (G3) and (Q2), Htᵤₙᵢ represents any one of a substituted or unsubstituted dibenzothiophenyl group, a substituted or unsubstituted dibenzofuranyl group, and a substituted or unsubstituted carbazolyl group,
wherein R²⁰ to R²⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted β-naphthyl group, an unsubstituted biphenyl group, and an unsubstituted terphenyl group, and
wherein at least one of β¹ and β² is an unsubstituted β-naphthyl group.

9. The composition for a light-emitting device according to claim 1,
wherein only one of β¹ and β² in General Formula (Q1) is an unsubstituted β-naphthyl group.

10. The composition for a light-emitting device according to claim 5,
wherein Htᵤₙᵢ in General Formula (G2) is any one of General Formulae (Ht-1) to (Ht-6): 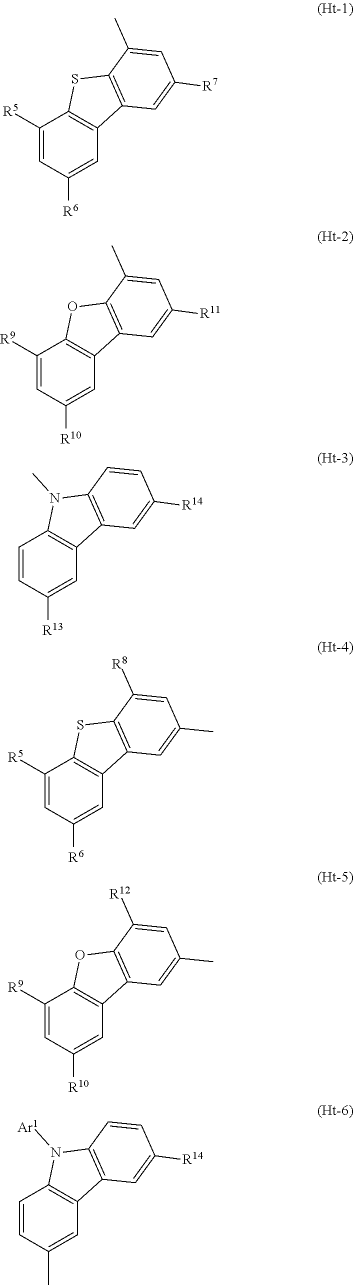
wherein, in the General Formulae (Ht-1) to (Ht-6), R⁵ to R¹⁴ each independently represent any one of hydrogen, an alkyl group having 1 to 6 carbon atoms, and a substituted or unsubstituted phenyl group, and
wherein Ar¹ represents any of an alkyl group having 1 to 6 carbon atoms and a substituted or unsubstituted phenyl group.

11. The composition for a light-emitting device according to claim 1,
wherein a combination of the first organic compound and the second organic compound forms an exciplex.

12. The composition for a light-emitting device according to claim 1,
wherein the first organic compound is mixed in a larger proportion than the second organic compound.

13. The composition for a light-emitting device according to claim 1,
wherein a molecular weight of the first organic compound is smaller than a molecular weight of the second organic compound, and
wherein a difference in molecular weight of the first organic compound and the second organic compound is less than or equal to 200.

14. A light-emitting device comprising an EL layer between a pair of electrodes,
wherein the EL layer comprises:
a first organic compound having a benzofuropyrimidine skeleton;
a second organic compound represented by General Formula (Q1); and
a light-emitting substance: 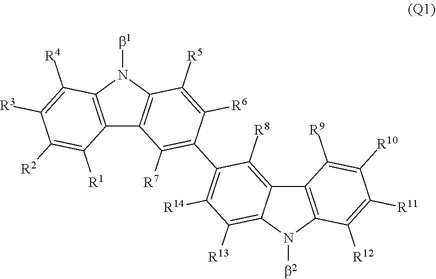
wherein, in the General Formula (Q1), R¹ to R¹⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted β-naphthyl group, an unsubstituted biphenyl group, and an unsubstituted terphenyl group, and
wherein at least one of β¹ and β² is an unsubstituted β-naphthyl group.

15. A light-emitting device comprising an EL layer between a pair of electrodes,
wherein the EL layer comprises:
a first organic compound represented by General Formula (G1);
a second organic compound represented by General Formula (Q1); and
a light-emitting substance: 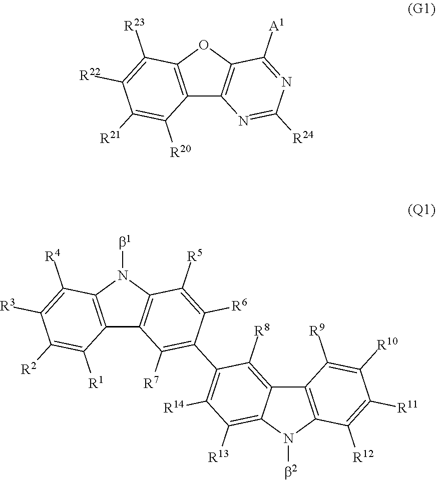
wherein, in the General Formulae (G1) and (Q1), A¹ represents an aryl group having 6 to 100 carbon atoms,
wherein R¹ to R¹⁴ and R²⁰ to R²⁴ each independently represent hydrogen, an alkyl group having 1 to 6 carbon atoms, a substituted or unsubstituted monocyclic saturated hydrocarbon having 5 to 7 carbon atoms in a ring, a substituted or unsubstituted polycyclic saturated hydrocarbon having 7 to 10 carbon atoms in a ring, a substituted or unsubstituted aryl group having 6 to 13 carbon atoms in a ring, or a substituted or unsubstituted heteroaryl group having 3 to 20 carbon atoms in a ring,
wherein β¹ and β² each represent any of an unsubstituted β-naphthyl group, an unsubstituted biphenyl group, and an unsubstituted terphenyl group, and
wherein at least one of β¹ and β² is an unsubstituted β-naphthyl group.

16. The light-emitting device according to claim 14,
wherein the first organic compound, the second organic compound, and the light-emitting substance are included in a light-emitting layer in the EL layer.

17. The light-emitting device according to claim 14,
wherein only one of β¹ and β² in General Formula (Q1) is an unsubstituted β-naphthyl group.

18. A light-emitting apparatus comprising:
the light-emitting device according to claim 14; and
at least one of a transistor and a substrate.

19. An electronic device comprising:
the light-emitting apparatus according to claim 18; and
at least one of a microphone, a camera, an operation button, an external connection portion, and a speaker.

20. A lighting device comprising:
the light-emitting device according to claim 14; and
at least one of a housing, a cover, and a support base.
